(19) United States
(12) Patent Application Publication
(10) Pub. No.: US 2023/0161246 A1
(43) Pub. Date: May 25, 2023

(54) RESIST UNDERLAYER FILM-FORMING COMPOSITION

(71) Applicant: NISSAN CHEMICAL CORPORATION, Tokyo (JP)

(72) Inventors: Hikaru TOKUNAGA, Toyama-shi (JP); Yutaro KURAMOTO, Toyama-shi (JP); Makoto NAKAJIMA, Toyama-shi (JP); Satoshi HAMADA, Funabashi-shi (JP); Katsuya MIURA, Funabashi-shi (JP)

(73) Assignee: NISSAN CHEMICAL CORPORATION, Tokyo (JP)

(21) Appl. No.: 17/795,061

(22) PCT Filed: Feb. 22, 2021
(86) PCT No.: PCT/JP2021/006710

§ 371 Date: Feb. 8, 2023

(30) Foreign Application Priority Data
Feb. 28, 2020 (JP) 2020-033333

(51) Int. Cl. G03F 7/004; G03F 7/09; G03F 7/16; G03F 7/038; G03F 7/20; G03F 7/32; G03F 7/00; H01L 21/027

(52) U.S. Cl. CPC G03F 7/0048; G03F 7/091; G03F 7/168; G03F 7/0381; G03F 7/2004; G03F 7/322; G03F 7/0002; H01L 21/0274

(57) ABSTRACT

Provided is a novel composition for forming a resist underlayer film. This composition for forming a resist underlayer film includes a polymer (X) and a solvent, the polymer (X) containing: a plurality of structural units which are the same as or different from each other and have a methoxymethyl group and a ROCH2- group (R is a monovalent organic group, a hydrogen atom, or a mixture thereof) other than the methoxymethyl group; and a linking group that links the more than one structural unit.

### TECHNICAL FIELD

The present invention relates to a resist underlayer film-forming composition, a resist underlayer film, which is a baked product of a coating film formed of the composition, and a method of manufacturing a semiconductor device using the composition.

### BACKGROUND ART

In the manufacture of a semiconductor device, micromachining by a lithography process is performed. It is known that in the lithography process, when a resist layer formed on a substrate is exposed to an ultraviolet laser such as a KrF excimer laser or an ArF excimer laser, a resist pattern having a desired shape is not formed due to the influence of a standing wave generated attributable to the reflection of the ultraviolet laser on a surface of the substrate. In order to solve the problem, it is adopted to provide a resist underlayer film (anti-reflective film) between the substrate and the resist layer. Also, it is known that a novolac resin is used as a composition for forming a resist underlayer film.

Also, a lithography process, in which at least two layers of resist underlayer film are formed and the resist underlayer film is used as a mask material in order to reduce a thickness of a resist layer required according to refinement of a resist pattern is also known. Examples of the material for forming the at least two layers include an organic resin (for example, an acrylic resin or a novolac resin), a silicon resin (for example, organopolysiloxane), and an inorganic silicon compound (for example, SiON or SiO₂). When dry etching is performed using a pattern formed from the organic resin layer as a mask, it is required for the pattern to have an etching resistance to the etching gas (for example, fluorocarbon).

As a composition for forming such a resist underlayer film, for example, Patent Literature 1 discloses a resist underlayer film-forming composition containing: a polymer having a structural unit represented by the following Formula (1):

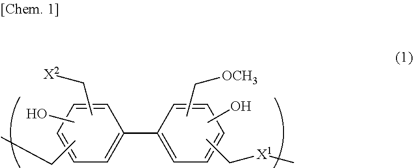

wherein, X¹ represents a divalent organic group having 6 to 20 carbon atoms having at least one aromatic ring, which may be substituted with a halogen group, a nitro group, an amino group, or a hydroxy group; and X² represents an organic group having 6 to 20 carbon atoms having at least one aromatic ring, which may be substituted with a halogen atom, a nitro group, an amino group, or a hydroxy group, or a methoxy group; and a solvent.

### CITATION LIST

### Patent Literature

Patent Literature 1: WO 2014/171326 A1

### SUMMARY OF INVENTION

### Technical Problem

However, the conventional resist underlayer film-forming compositions have still been insufficient in terms of requirements such as improvement of solubility in PGME or PGMEA, which is a solvent commonly used in the semiconductor industry, a reduction in amount of a sublimate that contaminates a device, improvement of coating flatness for a stepped substrate and the like, and high hardness of the obtained resist underlayer film. Also, it is also important to maintain or improve characteristics such as no use of a harmful chemical substance in preparation of a resin, no elution in a resist solvent, obtaining of a desired optical constant, and following of irregular patterns that occur as a pattern width narrows.

### Solution to Problem

The present invention is intended to solve the above problems. That is, the present invention encompasses the followings.

[1] A resist underlayer film-forming composition comprising: a solvent and a polymer (X) containing the same or different more than one structural unit and a linking group that links the more than one structural unit, each of the more than one structural unit having a methoxymethyl group and an ROCH₂— group other than the methoxymethyl group, in which R is a monovalent organic group, a hydrogen atom, or a mixture thereof.
[2] The resist underlayer film-forming composition according to [1], wherein R is a hydrogen atom, a saturated or unsaturated, linear or branched C₂-C₂₀ aliphatic hydrocarbon or C₃-C₂₀ alicyclic hydrocarbon group optionally substituted with a phenyl group, a naphthyl group, or an anthracenyl group and optionally interrupted by an oxygen atom or a carbonyl group, or a mixture thereof.
[3] The resist underlayer film-forming composition according to [1] or [2], wherein the linking group includes an alkylene group, an ether group, or a carbonyl group.
[4] The resist underlayer film-forming composition according to any one of [1] to [3], wherein the more than one structural unit has an aromatic ring, a heterocyclic ring, or a fused ring, which optionally have a phenolic hydroxy group and optionally have a substituted or unsubstituted amino group.
[5] The resist underlayer film-forming composition according to any one of [1] to [4], further comprising a film material (Y) capable of undergoing a crosslinking reaction with the polymer (X).
[6] The resist underlayer film-forming composition according to any one of [1] to [5], further comprising a crosslinking agent.
[7] The resist underlayer film-forming composition according to any one of [1] to [6], further comprising an acid and/or an acid generator.
[8] The resist underlayer film-forming composition according to any one of [1] to [7], further comprising a surfactant.
[9] The resist underlayer film-forming composition according to any one of [1] to [8], wherein the solvent includes a solvent having a boiling point of 160° C. or higher.
[10] A resist underlayer film, which is a baked product of a coating film formed of the composition according to any one of [1] to [9].
[11] A method of manufacturing a semiconductor device, the method comprising:

forming a resist underlayer film using the composition according to any one of [1] to [9] on a semiconductor substrate;

forming a resist film on the formed resist underlayer film;

irradiating the formed resist film with a light or electron beam and developing the resist film to form a resist pattern;

etching and patterning the resist underlayer film through the formed resist pattern; and

processing the semiconductor substrate through the patterned resist underlayer film.

[12] A method of manufacturing a semiconductor device, the method comprising:

forming a resist underlayer film using the composition according to any one of [1] to [9] on a semiconductor substrate;

forming a hard mask on the formed resist underlayer film;

forming a resist film on the formed hard mask;

irradiating the formed resist film with a light or electron beam and developing the resist film to form a resist pattern;

etching and patterning the hard mask through the formed resist pattern;

etching and patterning the resist underlayer film through the patterned hard mask; and

processing the semiconductor substrate through the patterned resist underlayer film.

[13] The method of manufacturing a semiconductor device according to [11] or [12], wherein the forming of the resist underlayer film is performed by a nanoimprint method.

### Advantageous Effects of Invention

According to the present invention, there is provided a novel resist underlayer film-forming composition that does not use a harmful chemical substance in preparation of a resin, meets requirements such as improvement of solubility in PGME or PGMEA, a reduction in amount of a sublimate that contaminates a device, improvement of coating flatness for a stepped substrate and the like, and high hardness of the obtained resist underlayer film, and maintains other desirable properties.

### DESCRIPTION OF EMBODIMENTS

A resist underlayer film-forming composition according to the present invention comprising: a solvent and a polymer (X) containing the same or different more than one structural unit and a linking group that links the more than one structural unit, each of the more than one structural unit having a methoxymethyl group and an ROCH₂— group other than the methoxymethyl group, in which R is a monovalent organic group, a hydrogen atom, or a mixture thereof.

[Polymer (X)]

The polymer (X) contains the same or different more than one structural unit and a linking group that links the more than one structural unit, each of the more than one structural unit having a methoxymethyl group and an ROCH₂— group other than the methoxymethyl group, in which R is a monovalent organic group, a hydrogen atom, or a mixture thereof.

R, which is a monovalent organic group, is preferably a saturated or unsaturated and linear or branched C₂-C₂₀ aliphatic hydrocarbon or C₃-C₂₀ alicyclic hydrocarbon group optionally substituted with a phenyl group, a naphthyl group, or an anthracenyl group and optionally interrupted by an oxygen atom or a carbonyl group, a hydrogen atom, or a mixture thereof. The “mixture” means that a plurality of ROCH₂-groups present in a single structural unit may be different, and also means that the ROCH₂— group in each of two or more structural units may be different.

Typical saturated aliphatic hydrocarbon group includes a linear or branched alkyl group having 2 to 20 carbon atoms. Examples thereof include an ethyl group, an n-propyl group, an i-propyl group, an n-butyl group, an i-butyl group, an s-butyl group, a t-butyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, n-hexyl, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, and a 1-methoxy-2-propyl group.

Also, a cyclic alkyl group may also be used. Examples of cyclic alkyl group having 3 to 20 carbon atoms include a cyclopropyl group, a cyclobutyl group, a 1-methyl-cyclopropyl group, a 2-methyl-cyclopropyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, and a 2-ethyl-3-methyl-cyclopropyl group.

Typical unsaturated aliphatic hydrocarbon group includes an alkenyl group having 2 to 20 carbon atoms. Examples thereof include an ethenyl group, a 1-propenyl group, a 2-propenyl group, a 1-methyl-1-ethenyl group, a 1-butenyl group, a 2-butenyl group, a 3-butenyl group, a 2-methyl-1-propenyl group, a 2-methyl-2-propenyl group, a 1-ethylethenyl group, a 1-methyl-1-propenyl group, a 1-methyl-2-propenyl group, a 1-pentenyl group, a 2-pentenyl group, a 3-pentenyl group, a 4-pentenyl group, a 1-n-propylethenyl group, a 1-methyl-1-butenyl group, a 1-methyl-2-butenyl group, a 1-methyl-3-butenyl group, a 2-ethyl-2-propenyl group, a 2-methyl-1-butenyl group, a 2-methyl-2-butenyl group, a 2-methyl-3-butenyl group, a 3-methyl-1-butenyl group, a 3-methyl-2-butenyl group, a 3-methyl-3-butenyl group, a 1,1-dimethyl-2-propenyl group, a 1-i-propylethenyl group, a 1,2-dimethyl-1-propenyl group, a 1,2-dimethyl-2-propenyl group, a 1-cyclopentenyl group, a 2-cyclopentenyl group, a 3-cyclopentenyl group, a 1-hexenyl group, a 2-hexenyl group, a 3-hexenyl group, a 4-hexenyl group, a 5-hexenyl group, a 1-methyl-1-pentenyl group, a 1-methyl-2-pentenyl group, a 1-methyl-3-pentenyl group, a 1-methyl-4-pentenyl group, a 1-n-butylethenyl group, a 2-methyl-1-pentenyl group, a 2-methyl-2-pentenyl group, a 2-methyl-3-pentenyl group, a 2-methyl-4-pentenyl group, a 2-n-propyl-2-propenyl group, a 3-methyl-1-pentenyl group, a 3-methyl-2-pentenyl group, a 3-methyl-3-pentenyl group, a 3-methyl-4-pentenyl group, a 3-ethyl-3-butenyl group, a 4-methyl-1-pentenyl group, a 4-methyl-2-pentenyl group, a 4-methyl-3-pentenyl group, a 4-methyl-4-pentenyl group, a 1,1-dimethyl-2-butenyl group, a 1,1-dimethyl-3-butenyl group, a 1,2-dimethyl-1-butenyl group, a 1,2-dimethyl-2-butenyl group, a 1,2-dimethyl-3-butenyl group, a 1-methyl-2-ethyl-2-propenyl group, a 1-s-butylethenyl group, a 1,3-dimethyl-1-butenyl group, a 1,3-dimethyl-2-butenyl group, a 1,3-dimethyl-3-butenyl group, a 1-i-butylethenyl group, a 2,2-dimethyl-3-butenyl group, a 2,3-dimethyl-1-butenyl group, a 2,3-dimethyl-2-butenyl group, a 2,3-dimethyl-3-butenyl group, a 2-i-propyl-2-propenyl group, a 3,3-dimethyl-1-butenyl group, a 1-ethyl-1-butenyl group, a 1-ethyl-2-butenyl group, a 1-ethyl-3-butenyl group, a 1-n-propyl-1-propenyl group, a 1-n-propyl-2-propenyl group, a 2-ethyl-1-butenyl group, a 2-ethyl-2-butenyl group, a 2-ethyl-3-butenyl group, a 1,1,2-trimethyl-2-propenyl group, a 1-t-butylethenyl group, a 1-methyl-1-ethyl-2-propenyl group, a 1-ethyl-2-methyl-1-propenyl group, a 1-ethyl-2-methyl-2-propenyl group, a 1-i-propyl-1-propenyl group, a 1-i-propyl-2-propenyl group, a 1-methyl-2-cyclopentenyl group, a 1-methyl-3-cyclopentenyl group, a 2-methyl-1-cyclopentenyl group, a 2-methyl-2-cyclopentenyl group, a 2-methyl-3-cyclopentenyl group, a 2-methyl-4-cyclopentenyl group, a 2-methyl-5-cyclopentenyl group, a 2-methylene-cyclopentyl group, a 3-methyl-1-cyclopentenyl group, a 3-methyl-2-cyclopentenyl group, a 3-methyl-3-cyclopentenyl group, a 3-methyl-4-cyclopentenyl group, a 3-methyl-5-cyclopentenyl group, a 3-methylene-cyclopentyl group, a 1-cyclohexenyl group, a 2-cyclohexenyl group, and a 3-cyclohexenyl group.

The saturated aliphatic hydrocarbon group, the unsaturated aliphatic hydrocarbon group, and the cyclic alkyl group may be interrupted once or twice or more by an oxygen atom and/or a carbonyl group. Particularly preferably, R is a —CH₂CH₂CH₂CH₃ group and a —CH(CH₃)CH₂OCH₃ group.

The polymer (X) can be synthesized by subjecting a compound optionally having a methoxymethyl group and optionally having a phenolic hydroxy group, a compound that reacts with the methoxymethyl group to provide an ROCH₂— group other than the methoxymethyl group, in which R is a monovalent organic group, a hydrogen atom, or a mixture thereof, and, if necessary, a compound having a functional group that is to form a linking group (for example, aldehyde, ketone, and ROCH₂—Ar—CH₂OR, in which R is a monovalent organic group, a hydrogen atom, or a mixture thereof) to a polymerization reaction, in the presence of an acid catalyst (for example, a sulfonic acid compound).

An example of the compound, which is used for synthesis of the polymer (X), has a methoxymethyl group, and optionally have a phenolic hydroxy group, includes 3,3′,5,5′-tetramethoxymethyl-4,4′-dihydroxybiphenyl.

An organic compound having a non-phenolic hydroxy group in the molecule is preferred as the compound that reacts with a methoxymethyl group used for the synthesis of polymer (X) to provide an ROCH₂— group other than the methoxymethyl group, in which R is a monovalent organic group, a hydrogen atom, or a mixture thereof.

Even when it does not have a non-phenolic hydroxy group in the molecule, the compound may be an organic compound having a functional group that can be chemically changed into a non-phenolic hydroxy group, such as, an alkoxy group (—OR), an aldehyde group (—CHO), a carboxyl group (—COOH), an ester group (—COOR), or a ketone group (—COR). The number of the non-phenolic hydroxy group or functional group that can be chemically changed into a non-phenolic hydroxy group may be one or two or more in the molecule. The organic compound may be an aliphatic hydrocarbon (preferably having 10 or fewer carbon atoms), an alicyclic hydrocarbon (preferably having 20 or fewer carbon atoms), or an aromatic hydrocarbon (for example, α-carbon has at least one aliphatic hydroxy group). Examples thereof include propylene glycol monomethyl ether, propylene glycol monomethyl ether acetate, an aliphatic alcohol (example, n-butanol), a compound represented by Ar—CH₂OH (Ar is, for example, benzene, naphthalene, anthracene, pyrene, fluorene, or m-terphenyl), aldehyde, ketone, and a methylol compound. Note that use of dioxane is preferably avoided, because dioxane is not a compound that provides an ROCH₂— group (R is a monovalent organic group, a hydrogen atom, or a mixture thereof) other than the methoxymethyl group, and is also a substance harmful to a human body.

Examples of the organic compound having an aldehyde group include aliphatic aldehydes such as formaldehyde, paraformaldehyde, butyraldehyde, and crotonaldehyde, and aromatic aldehydes such as furfural, pyridinecarboxyaldehyde, benzaldehyde, naphthylaldehyde, anthraldehyde, phenanthrylaldehyde, salicylaldehyde, phenylacetaldehyde, biphenyl aldehyde, 3-phenylpropionaldehyde, tolylaldehyde, (N,N-dimethylamino)benzaldehyde, acetoxybenzaldehyde, 1-pyrenecarboxaldehyde, and anisaldehyde.

Examples of the organic compound having a ketone group include diaryl ketones such as diphenyl ketone, phenyl naphthyl ketone, dinaphthyl ketone, phenyltolyl ketone, ditolyl ketone, 9-fluorenone, anthraquinone, and acenaphthaquinone; and spiroketones such as 11H-benzo[b]fluoren-11-one, 9H-tribenzo[a,f,l]trinden-9,14,15-trione, and indeno[1,2-b]fluoren-6,12-dione.

The structural unit of polymer (X) that can be obtained as described above preferably has an aromatic ring, a heterocyclic ring, or a fused ring optionally having a phenolic hydroxy group and optionally having a substituted or unsubstituted amino group. Also, the linking group that links more than one structural unit preferably includes an alkylene group, an ether group, or a carbonyl group.

The compound used for synthesis of polymer (X) is not limited to a single compound, and two or more compounds may be used in combination. Therefore, the more than one structural unit having a methoxymethyl group and an ROCH₂— group (R is a monovalent organic group, a hydrogen atom, or a mixture thereof) other than the methoxymethyl group may be the same as or different from each other.

The weight average molecular weight of polymer (X) contained in the resist underlayer film-forming composition of the present invention is not particularly limited. The weight average molecular weight of polymer (X) is, for example, 1,000 or more or 2,000 or more, and for example, 500,000 or less or 100,000 or less, in terms of standard polystyrene.

[Solvent]

The resist underlayer film-forming composition of the present invention may be prepared by dissolving the respective components in an appropriate solvent, and is used in a uniform solution state.

Examples of such a solvent include ethylene glycol monomethyl ether, ethylene glycol monoethyl ether, diethylene glycol monomethyl ether, diethylene glycol monoethyl ether, propylene glycol, propylene glycol monomethyl ether, propylene glycol monopropyl ether, propylene glycol monomethyl ether acetate, propropylene glycol propyl ether acetate, methyl cellosolve acetate, ethyl cellosolve acetate, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, N,N-dimethylformamide, N,N-dimethylacetamide, and N-methylpyrrolidone.

Moreover, a high-boiling point solvent having a boiling point of 180° C. or higher may be used. Specific examples of the high-boiling point solvent include 1-octanol, 2-ethylhexanol, 1-nonanol, 1-decanol, 1-undecanol, ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, glycerin, n-nonyl acetate, ethylene glycol monohexyl ether, ethylene glycol mono-2-ethylhexyl ether, ethylene glycol monophenyl ether, ethylene glycol monobenzyl ether, diethylene glycol monoethyl ether, diethylene glycol monoisopropyl ether, diethylene glycol mono-n-butyl ether, diethylene glycol monoisobutyl ether, diethylene glycol monohexyl ether, diethylene glycol monophenyl ether, diethylene glycol monobenzyl ether, diethylene glycol diethyl ether, diethylene glycol dibutyl ether, diethylene glycol butylmethyl ether, triethylene glycol dimethyl ether, triethylene glycol monomethyl ether, triethylene glycol-n-butyl ether, triethylene glycol butylmethyl ether, triethylene glycol diacetate, tetraethylene glycol dimethyl ether, dipropylene glycol monomethyl ether, dipropylene glycol mono-n-propyl ether, dipropylene glycol mono-n-butyl ether, tripropylene glycol dimethyl ether, tripropylene glycol monomethyl ether, tripropylene glycol mono-n-propyl ether, tripropylene glycol mono-n-butyl ether, ethylene glycol monoethyl ether acetate, ethylene glycol monobutyl ether acetate, diethylene glycol monomethyl ether acetate, diethylene glycol monoethyl ether acetate, diethylene glycol monobutyl ether acetate, triacetin, propylene glycol diacetate, dipropylene glycol monomethyl ether acetate, dipropylene glycol methyl-n-propyl ether, dipropylene glycol methyl ether acetate, 1,4-butanediol diacetate, 1,3-butylene glycol diacetate, 1,6-hexanediol diacetate, triethylene glycol diacetate, γ-butyrolactone, dihexyl malonate, diethyl succinate, dipropyl succinate, dibutyl succinate, dihexyl succinate, dimethyl adipate, diethyl adipate, and dibutyl adipate.

These solvents may be used each alone or in combination of two or more thereof. The proportion of solid content resulting from removing the organic solvent from the composition is, for example, within the range of 0.5% by mass to 30% by mass and preferably 0.8% by mass to 15% by mass.

Also, the following compound described in WO 2018/131562 A1 may be used.

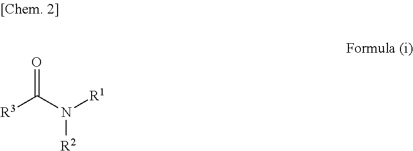

R¹, R², and R³ in Formula (i) each represents an alkyl group having 1 to 20 carbon atoms, which may be interrupted by a hydrogen atom, an oxygen atom, a sulfur atom, or an amide bond, may be the same as or different from each other, and may be bonded to each other to form a ring structure.

An example of the alkyl group having 1 to 20 carbon atoms includes a linear or branched alkyl group which may have or may not have a substituent. Examples thereof include a methyl group, an ethyl group, an n-propyl group, an isopropyl group, an n-butyl group, a sec-butyl group, a tert-butyl group, an n-pentyl group, an isopentyl group, a neopentyl group, an n-hexyl group, an isohexyl group, an n-heptyl group, an n-octyl group, a cyclohexyl group, a 2-ethylhexyl group, an n-nonyl group, an isononyl group, a p-tert-butylcyclohexyl group, an n-decyl group, an n-dodecylnonyl group, an undecyl group, a dodecyl group, a tridecylic group, a tetradecyl group, a pentadecyl group, a hexadecyl group, a heptadecyl group, an octadecyl group, a nonadecyl group, and an eicosyl group. The alkyl group is preferably an alkyl group having 1 to 12 carbon atoms, more preferably an alkyl group having 1 to 8 carbon atoms, and still more preferably an alkyl group having 1 to 4 carbon atoms.

Examples of the alkyl group having 1 to 20 carbon atoms which may be interrupted by an oxygen atom, a sulfur atom, or an amide bond includes alkyl groups containing a structural unit —CH₂—O—, —CH₂—S—, —CH₂—NHCO—, or —CH₂—CONH—. The alkyl group may contain one unit or two or more units of —O—, —S—, —NHCO—, or —CONH—. Specific examples of the alkyl group having 1 to 20 carbon atoms which is interrupted by an —O—, —S—, —NHCO—, or —CONH— unit include a methoxy group, an ethoxy group, a propoxy group, a butoxy group, a methylthio group, an ethylthio group, a propylthio group, a butylthio group, a methylcarbonylamino group, an ethylcarbonylamino group, a propylcarbonylamino group, a butylcarbonylamino group, a methylaminocarbonyl group, an ethylaminocarbonyl group, a propylaminocarbonyl group, and a butylaminocarbonyl group; and further include a methyl group, an ethyl group, a propyl group, a butyl group, a pentyl group, a hexyl group, a heptyl group, an octyl group, a nonyl group, a decyl group, a dodecyl group, and an octadecyl group, each of them being substituted with a methoxy group, an ethoxy group, a propoxy group, a butoxy group, a methylthio group, an ethylthio group, a propylthio group, a butylthio group, a methylcarbonylamino group, an ethylcarbonylamino group, a methylaminocarbonyl group, an ethylaminocarbonyl group, or the like. The alkyl group is preferably a methoxy group, an ethoxy group, a methylthio group, or an ethylthio group, and more preferably a methoxy group or an ethoxy group.

Because these solvents have a relatively high boiling point, the solvents are also effective for imparting a high embedding and flattening properties to the resist underlayer film-forming composition.

Specific examples of a preferred compound represented by Formula (i) are shown below.

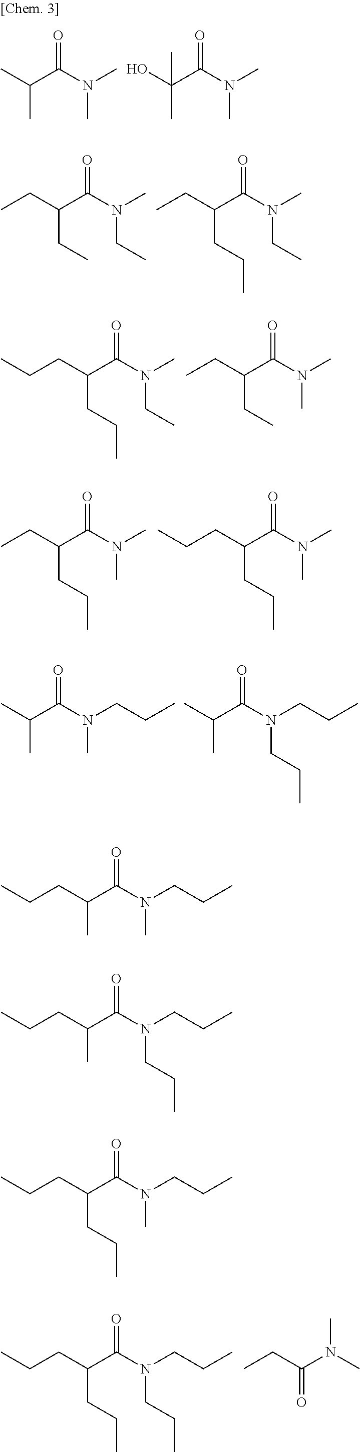

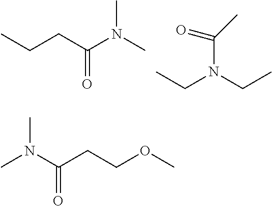

Of these, 3-methoxy-N,N-dimethylpropionamide, N,N-dimethylisobutylamide, and a compound represented by the following formula:

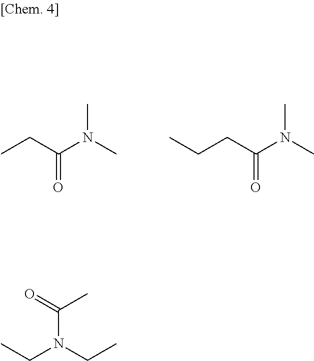

are preferred. And a particularly preferred compound represented by Formula (i) is 3-methoxy-N,N-dimethylpropionamide or N,N-dimethylisobutylamide.

These solvents may be used each alone or in combination of two or more thereof. Of these solvents, a solvent having a boiling point of 160° C. or higher is preferred, and propylene glycol monomethyl ether, propylene glycol monomethyl ether acetate, ethyl lactate, butyl lactate, cyclohexanone, 3-methoxy-N,N-dimethylpropionamide, N,N-dimethylisobutylamide, 2,5-dimethylhexan-1,6-diyldiacetate (DAH, cas, 89182-68-3), 1,6-diacetoxyhexane (cas, 6222-17-9), and the like are preferred. In particular, propylene glycol monomethyl ether, propylene glycol monomethyl ether acetate, and N,N-dimethylisobutylamide are preferred.

[Optional Component]

The resist underlayer film-forming composition of the present invention may further contain at least one of a crosslinking agent, an acid and/or an acid generator, a thermal acid generator, and a surfactant, as an optional component.

(Crosslinking Agent)

The resist underlayer film-forming composition of the present invention may further contain a crosslinking agent. As the crosslinking agent, a crosslinkable compound having at least two crosslink-forming substituents is preferably used.

Examples thereof include a melamine-based compound, a substituted urea-based compound, a phenol-based compound having a crosslink-forming substituent such as a methylol group or a methoxymethyl group, and a polymer-based crosslinkable compound thereof. Specifically, the crosslinking agent is a compound such as methoxymethylated glycoluril, butoxymethylated glycoluril, methoxymethylated melamine, butoxymethylated melamine, methoxymethylated benzoguanamine, or butoxymethylated benzoguanamine, and examples thereof include tetramethoxymethyl glycoluril, tetrabutoxymethyl glycoluril, and hexamethoxymethylmelamine. Furthermore, the substituted urea-based compound is methoxymethylated urea, butoxymethylated urea, or methoxymethylated thiourea, and examples thereof include tetramethoxymethyl urea and tetrabutoxymethyl urea. Also, condensates of these compounds may also be used. Examples of the phenol-based compound include tetrahydroxymethylbiphenol, tetramethoxymethylbiphenol, tetrahydroxymethylbisphenol, tetramethoxymethylbisphenol, and compounds represented by the following formulas.

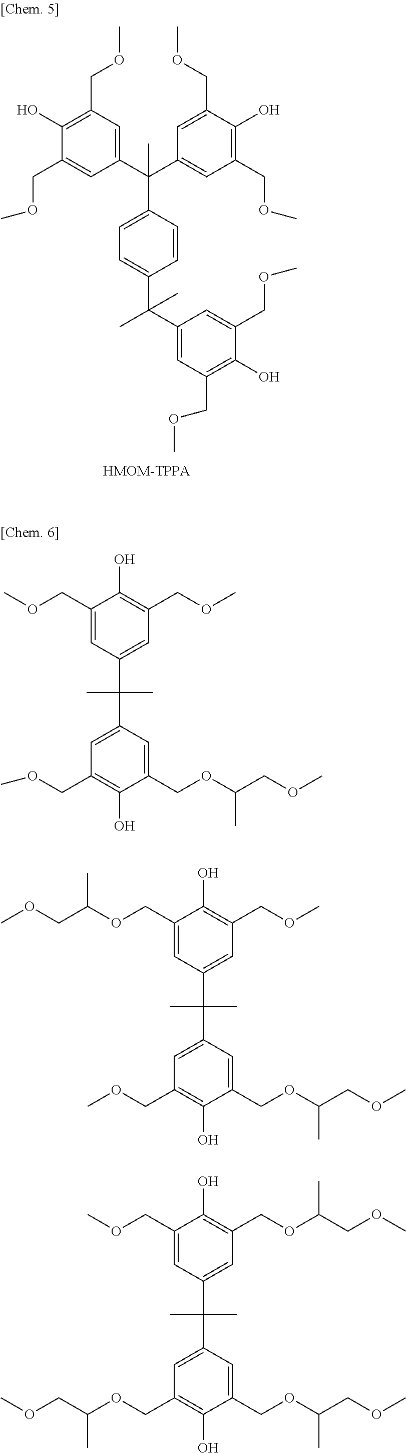

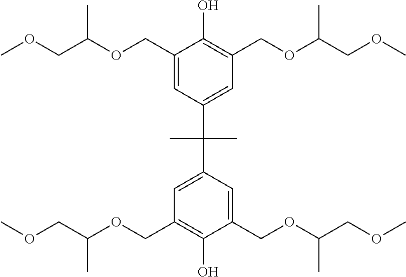

Also, as the crosslinking agent, a compound having at least two epoxy groups may also be used. Examples of such a compound include tris(2,3-epoxypropyl)isocyanurate, 1,4-butanediol diglycidyl ether, 1,2-epoxy-4-(epoxyethyl)cyclohexane, glycerol triglycidyl ether, diethylene glycol diglycidyl ether, 2,6-diglycidyl phenyl glycidyl ether, 1,1,3-tris[p-(2,3-epoxypropoxy)phenyl]propane, 1,2-cyclohexanedicarboxylic acid diglycidyl ester, 4,4′-methylenebis(N,N-diglycidylaniline), 3,4-epoxycyclohexylmethyl-3,4-epoxycyclohexane carboxylate, trimethylolethane triglycidyl ether, bisphenol-A-diglycidyl ether, EPOLEAD [registered trademark] GT-401, GT-403, GT-301, and GT-302 and CELLOXIDE [registered trademark] 2021 and 3000, manufactured by Daicel Corporation; 1001, 1002, 1003, 1004, 1007, 1009, 1010, 828, 807, 152, 154, 180S75, 871, and 872, manufactured by Mitsubishi Chemical Corporation, EPPN 201 and 202, EOCN-102, 103S, 104S, 1020, 1025, and 1027, manufactured by Nippon Kayaku Co., Ltd., Denacol [registered trademark] EX-252, EX-611, EX-612, EX-614, EX-622, EX-411, EX-512, EX-522, EX-421, EX-313, EX-314, and EX-321, manufactured by Nagase ChemteX Corporation, CY175, CY177, CY179, CY182, CY184, and CY192, manufactured by BASF Japan Ltd., and EPICLON 200, 400, 7015, 835LV, and 850CRP, manufactured by DIC Corporation.

Also, as the compound having at least two epoxy groups, an epoxy resin having an amino group may also be used. Examples of the epoxy resin include YH-434 and YH-434L (manufactured by NIPPON STEEL Epoxy Manufacturing Co., Ltd.).

Also, as the crosslinking agent, a compound having at least two block isocyanate groups can also be used. Examples of such a compound include TAKENATE [registered trademark] B-830 and B-870N, manufactured by Mitsui Chemicals, Inc. and VESTANAT [registered trademark] B1358/100, manufactured by Evonik Degussa GmbH.

Also, as the crosslinking agent, a compound having at least two vinyl ether groups may also be used. Examples of such a compound include bis(4-(vinyloxymethyl)cyclohexylmethyl)glutarate, tri(ethyleneglycol)divinyl ether, adipic acid divinyl ester, diethylene glycol divinyl ether, 1,2,4-tris(4-vinyloxybutyl)trimellitate, 1,3,5-tris(4-vinyloxybutyl)trimellitate, bis(4-(vinyloxy)butyl)terephthalate, bis(4-(vinyloxy)butyl)isophthalate, ethylene glycol divinyl ether, 1,4-butanediol divinyl ether, tetramethylene glycol divinyl ether, tetraethylene glycol divinyl ether, neopentyl glycol divinyl ether, trimethylolpropane trivinyl ether, trimethylolethane trivinyl ether, hexanediol divinyl ether, 1,4-cyclohexanediol divinyl ether, tetraethylene glycol divinyl ether, pentaerythritol divinyl ether, pentaerythritol trivinyl ether, and cyclohexanedimethanol divinyl ether.

Also, as the crosslinking agent, a crosslinking agent having a high heat resistance may be used. As the crosslinking agent having a high heat resistance, a compound having a crosslink-forming substituent having an aromatic ring (for example, a benzene ring or a naphthalene ring) in the molecule may be preferably used.

Examples of the compound include a compound having a partial structure of the following Formula (4) and a polymer or an oligomer having a repeating unit of the following Formula (5).

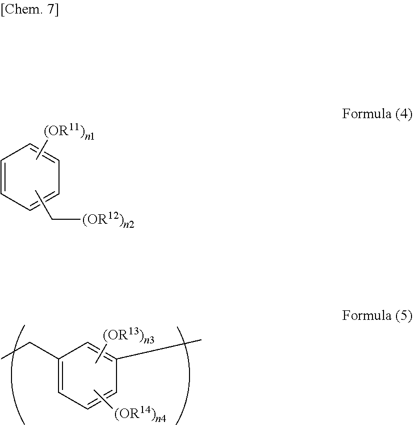

Each of R¹¹, R¹², R¹³, and R¹⁴ is a hydrogen atom or an alkyl group having 1 to 10 carbon atoms, and the examples mentioned above may be used for these alkyl groups. n1 is an integer of 1 to 4, n2 is an integer of 1 to (5−n1), and (n1+n2) represents an integer of 2 to 5. n3 is an integer of 1 to 4, n4 is 0 to (4−n3), and (n3+n4) represents an integer of 1 to 4. The oligomer and polymer may be used with a number of repeating unit within the range of 2 to 100 or 2 to 50.

Examples of the compound, the polymer, and the oligomer of Formulas (4) and (5) include the followings.

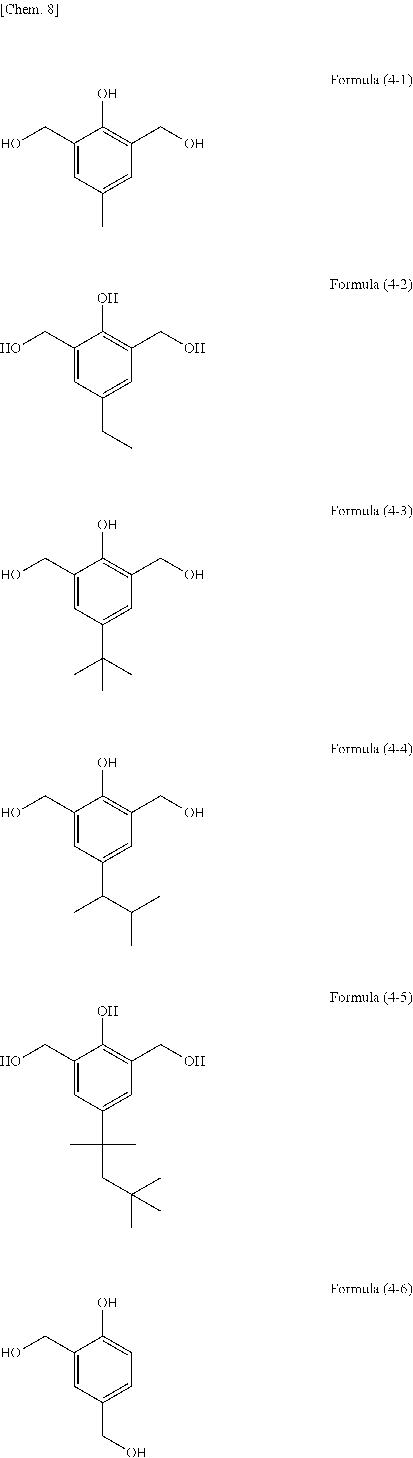 [SMILES: Cc1cc(CO)c(O)c(CO)c1 ; CCc1cc(CO)c(O)c(CO)c1 ; CC(C)(C)c1cc(CO)c(O)c(CO)c1 ; CC(C)C(C)c1cc(CO)c(O)c(CO)c1 ; CC(C)(C)CC(C)(C)c1cc(CO)c(O)c(CO)c1 ; OCc1ccc(O)c(CO)c1]

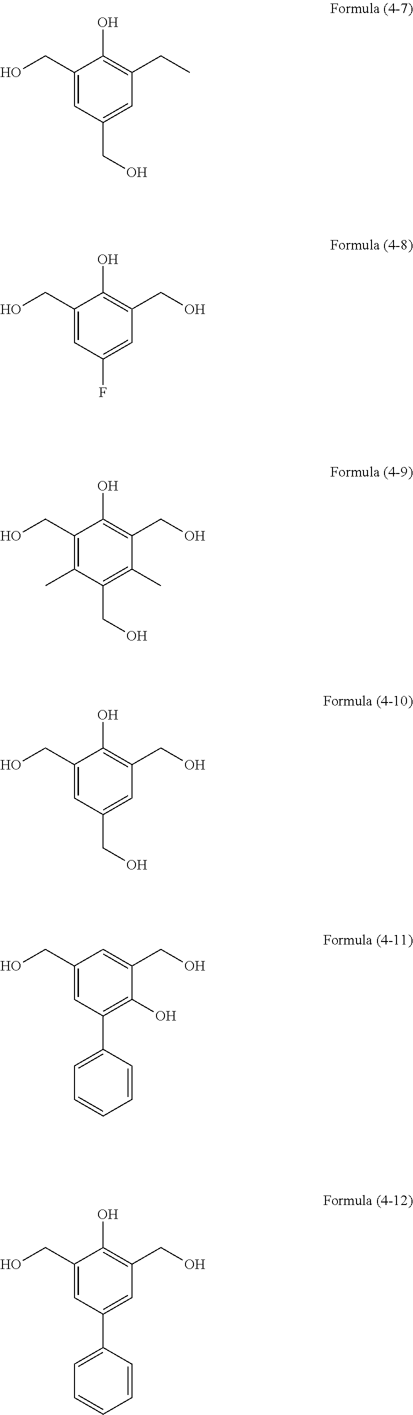 [SMILES: CCc1cc(CO)cc(CO)c1O ; OCc1cc(F)cc(CO)c1O ; Cc1c(CO)c(C)c(CO)c(O)c1CO ; OCc1cc(CO)c(O)c(CO)c1 ; OCc1cc(CO)c(O)c(-c2ccccc2)c1 ; OCc1cc(-c2ccccc2)cc(CO)c1O]

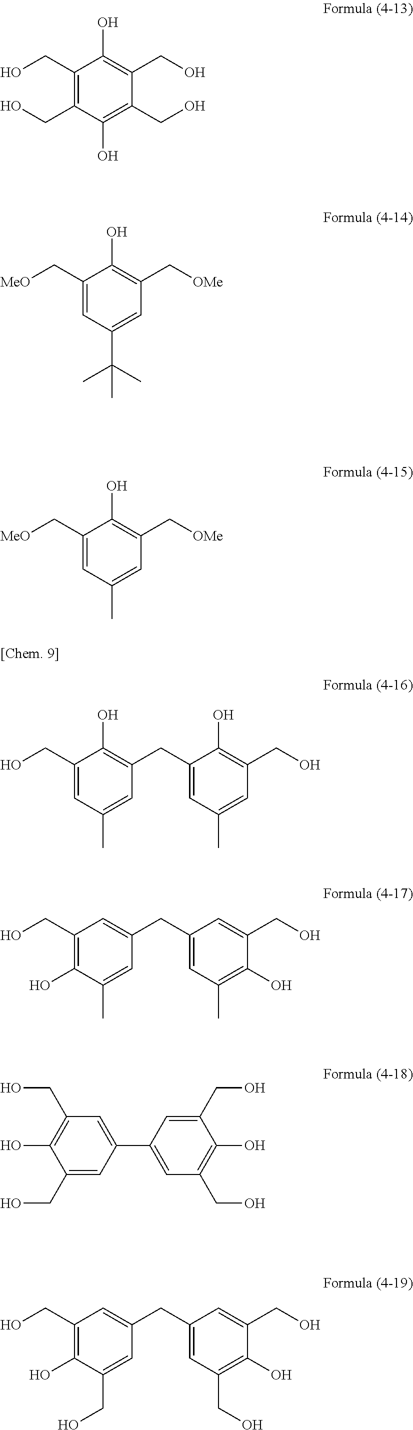

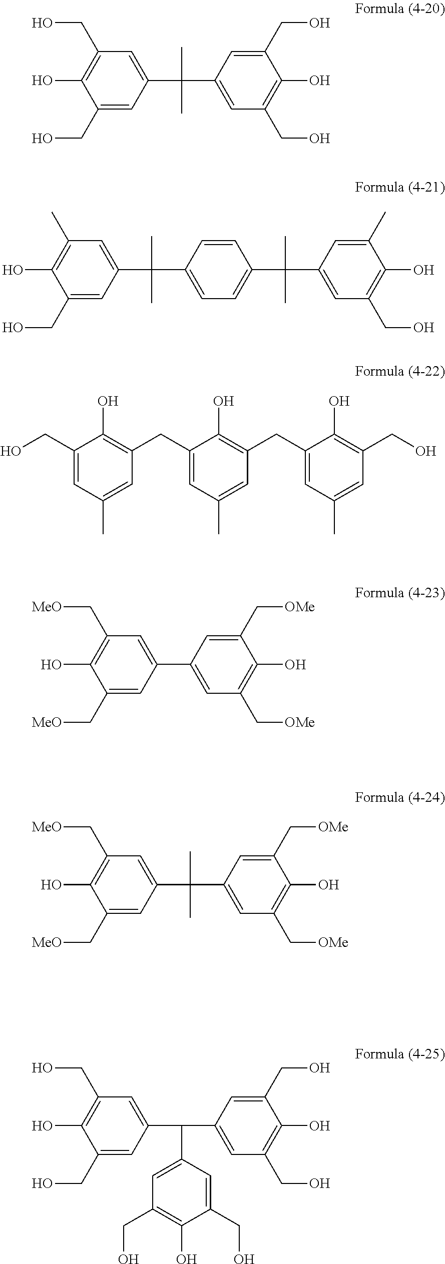 [SMILES: CC(C)(c1cc(CO)c(O)c(CO)c1)c1cc(CO)c(O)c(CO)c1 ; Cc1cc(C(C)(C)c2ccc(C(C)(C)c3cc(C)c(O)c(CO)c3)cc2)cc(CO)c1O ; Cc1cc(CO)c(O)c(Cc2cc(C)cc(Cc3cc(C)cc(CO)c3O)c2O)c1 ; COCc1cc(-c2cc(COC)c(O)c(COC)c2)cc(COC)c1O ; COCc1cc(C(C)(C)c2cc(COC)c(O)c(COC)c2)cc(COC)c1O ; OCc1cc(C(c2cc(CO)c(O)c(CO)c2)c2cc(CO)c(O)c(CO)c2)cc(CO)c1O]

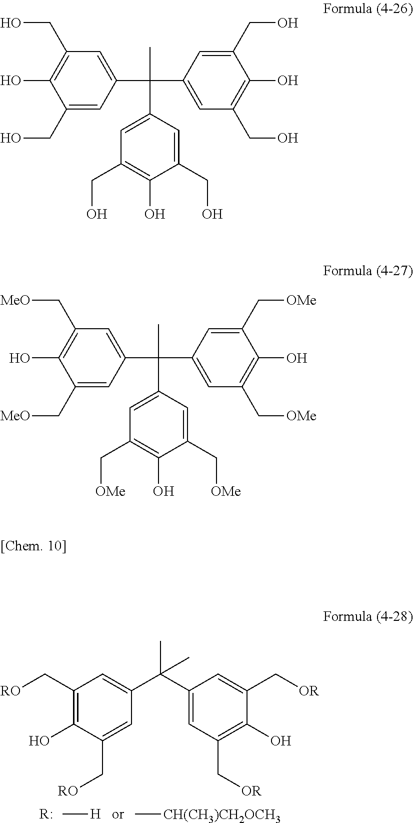

The above compounds are available as products from ASAHI YUKIZAI CORPORATION and Honshu Chemical Industry Co., Ltd. Of the crosslinking agents, the compound of Formula (4-23) is available as TMOM-BP (trade name) from Honshu Chemical Industry Co., Ltd., the compound of Formula (4-24) is available as TM-BIP-A (trade name) from ASAHI YUKIZAI CORPORATION, and the compound of Formula (4-28) is available as PGME-BIP-A (trade name) from Japan Finechem Company, Inc., for example.

The amount of crosslinking agent added varies depending on an application solvent to be used, a substrate to be used, a solution viscosity to be required, a film shape to be required, or the like. The amount of crosslinking agent added is 0.001% by mass or more, 0.01% by mass or more, 0.05% by mass or more, 0.5% by mass or more, or 1.0% by mass or more, and 80% by mass or less, 50% by mass or less, 40% by mass or less, 20% by mass or less, or 10% by mass or less, with respect to the total solid content. The crosslinking agent may cause a crosslinking reaction due to self-condensation. However, in a case where a crosslinkable substituent is present in the polymer of the present invention, the crosslinking agent may cause crosslinking reaction with the crosslinkable substituent.

One crosslinking agent selected from these crosslinking agents may be added, and a combination of two or more crosslinking agents may be added.

(Acid and/or Acid Generator)

The resist underlayer film-forming composition according to the present invention may contain an acid and/or an acid generator.

Examples of the acid include carboxylic acid compounds such as p-toluene sulfonic acid, trifluoromethane sulfonic acid, pyridinium p-toluene sulfonic acid, pyridinium phenol sulfonic acid, salicylic acid, 5-sulfosalicylic acid, 4-phenol sulfonic acid, camphor sulfonic acid, 4-chlorobenzene sulfonic acid, benzene disulfonic acid, 1-naphthalen sulfonic acid, citric acid, benzoic acid, hydroxy benzoic acid, and naphthalene carboxylic acid; and inorganic acids such as hydrochloric acid, sulfuric acid, nitric acid, and phosphoric acid.

As the acid, only one species of acid may be used, or two or more species of acid may be used in combination. The blending proportion is usually within the range of 0.0001 to 20% by mass, preferably 0.0005 to 10% by mass, and more preferably 0.01 to 5% by mass, with respect to the total solid content.

Examples of the acid generator include a thermal acid generator and a photoacid generator.

Examples of the thermal acid generator include 2,4,4,6-tetrabromocyclohexadienone, benzoin tosylate, 2-nitrobenzyl tosylate, K-PURE [registered trademark] CXC-1612, CXC-1614, TAG-2172, TAG-2179, TAG-2678, TAG2689, and TAG2700 (manufactured by King Industries Inc.), SI-45, SI-60, SI-80, SI-100, SI-110, and SI-150 (manufactured by SANSHIN CHEMICAL INDUSTRY CO., LTD.), quaternary ammonium salts of trifluoroacetate, and organic sulfonic acid alkyl esters.

Examples of the onium salt compound include iodonium salt compounds such as diphenyliodoniumhexafluorophosphate, diphenyliodoniumtrifluoromethanesulfonate, diphenyliodoniumnonafluoro n-butane sulfonate, diphenyliodoniumperfluoro n-octane sulfonate, diphenyliodoniumcamphorsulfonate, bis(4-tert-butylphenyl)iodoniumcamphorsulfonate, and bis(4-tert-butylphenyl)iodoniumtrifluoromethanesulfonate; and sulfonium salt compounds such as triphenylsulfoniumhexafluoroantimonate, triphenylsulfoniumnonafluoro n-butane sulfonate, triphenylsulfoniumcamphorsulfonate, and triphenylsulfoniumtrifluoromethanesulfonate.

Examples of the sulfonimide compound include N-(trifluoromethanesulfonyloxy)succinimide, N-(nonafluoro n-butanesulfonyloxy)succinimide, N-(camphorsulfonyloxy)succinimide, and N-(trifluoromethanesulfonyloxy)naphthalimide.

Examples of the disulfonyldiazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

As the acid generator, only one species of acid generator may be used, or two or more species of acid generator may be used in combination.

In case where an acid generator is used, the proportion thereof is within the range of 0.01 to 10 parts by mass, 0.1 to 8 parts by mass, or 0.5 to 5 parts by mass, with respect to 100 parts by mass of the solid content of the resist underlayer film-forming composition.

(Surfactant)

The resist underlayer film-forming composition of the present invention may further contain a surfactant. Examples of the surfactant include nonionic surfactants such as polyoxyethylene alkyl ethers such as polyoxyethylene lauryl ether, polyoxyethylene stearyl ether, polyoxyethylene cetyl ether, and polyoxyethylene oleyl ether, polyoxyethylene alkylallyl ethers such as polyoxyethylene octylphenyl ether and polyoxyethylene nonylphenyl ether, polyoxyethylene-polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-based surfactants such as EFTOP [registered trademark] EF301, EF303, and EF352 (manufactured by Mitsubishi Materials Electronic Chemicals Co., Ltd.), MEGAFACE [registered trademark] F171, F173, R-30, R-30-N, R-40, and R-40-LM (manufactured by DIC Corporation), Fluorad FC430 and FC431 (manufactured by Sumitomo 3M Limited), AsahiGuard [registered trademark] AG710 and Surflon [registered trademark] S-382, SC101, SC102, SC103, SC104, SC105, and SC106 (manufactured by AGC Inc.); and Organosiloxane polymer KP341 (manufactured by Shin-Etsu Chemical Co., Ltd.). One surfactant selected from these crosslinking agents may be added, and a combination of two or more crosslinking agents may be added. The proportion of the surfactant is, for example, within the range of 0.01% by mass to 5% by mass with respect to the solid content resulting from removing a solvent mentioned below from the resist underlayer film-forming composition of the present invention.

[Film Material (Y)]

The polymer (X) according to the present invention may be used as a crosslinking agent of the film material (Y). That is, the resist underlayer film-forming composition according to the present invention further contains a film material (Y) capable of undergoing a crosslinking reaction with the polymer (X). It can be said that the film material (Y) is a film material capable of undergoing a crosslinking reaction with the polymer (X).

The film material (Y) optionally used in the present invention can be used without particular limitation as long as it is a material capable of undergoing a crosslinking reaction with the polymer (X). The film material may be a polymer, an oligomer, or a low-molecular-weight compound having a molecular weight of 1,000 or less. Examples of a crosslink-forming group present in the film material include a hydroxy group, a carboxyl group, an amino group, and an alkoxy group, but are not limited thereto.

An example of a film material (a) capable of undergoing a crosslinking reaction includes an alicyclic epoxy polymer having a repeating structural unit represented by the following Formula (1) as disclosed in WO 2011/021555 A1.

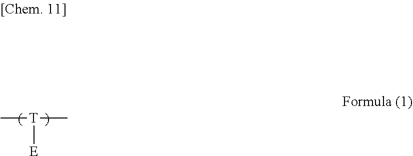

T represents a repeating unit structure having an aliphatic ring in the main chain of the polymer, and E represents an epoxy group or an organic group having an epoxy group.

E is a substituent for the aliphatic ring, and an epoxy group may be directly bonded to the aliphatic group, or an organic group (for example, a glycidyl group) having an epoxy group may be bonded to the aliphatic group.

The aliphatic ring is, for example, a ring containing 4 to 10 carbon atoms linked in a cyclic form, and particularly, a ring containing 6 carbon atoms linked in a cyclic form. The aliphatic ring may have a substituent other than the substituent E (an epoxy group or an organic group having an epoxy group). Examples of such a substituent include an alkyl group having 1 to 10 carbon atoms, an aryl group having 6 to 20 carbon atoms, a halogen atom, a nitro group, and an amino group.

The weight average molecular weight of the alicyclic epoxy polymer represented by Formula (1) is within the range of 600 to 1,000,000 and preferably 1,000 to 200,000. The number of repeating unit of the alicyclic epoxy polymer (A) represented by Formula (1) is within the range of 2 to 3,000 or 3 to 600.

Examples thereof include the following polymers.

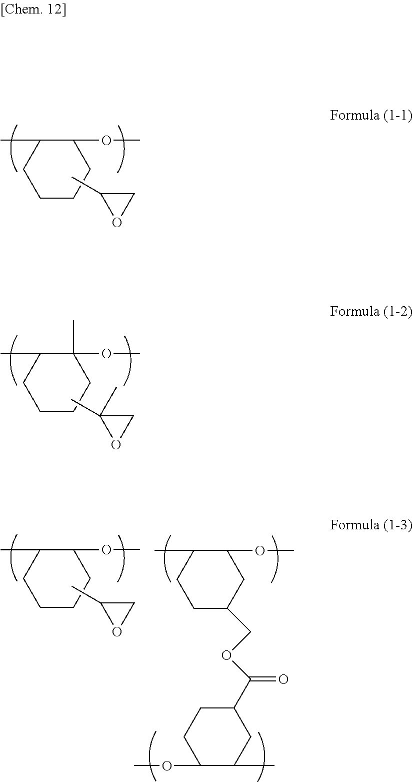

An example of a film material (b) capable of undergoing a crosslinking reaction includes a polymer having one or two or more repeating structural units represented by the following Formulas (1a), (1b), and (1c) as disclosed in WO 2014/024836 A1:

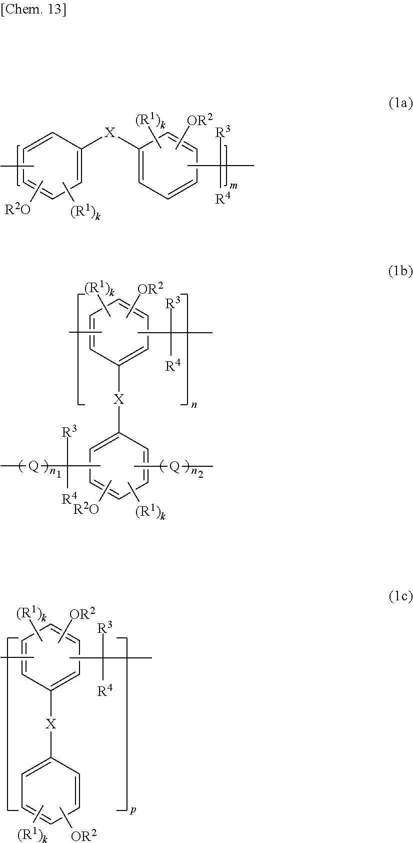

wherein, two les each independently represent an alkyl group having 1 to 10 carbon atoms, an alkenyl group having 2 to 6 carbon atoms, an aromatic hydrocarbon group, a halogen atom, a nitro group, or an amino group; two R^{e}s each independently represent a hydrogen atom, an alkyl group having 1 to 10 carbon atoms, an alkenyl group having 2 to 6 carbon atoms, an acetal group, an acyl group, or a glycidyl group; R³ represents an aromatic hydrocarbon group which may have a substituent; R⁴ represents a hydrogen atom, a phenyl group, or a naphthyl group; when R³ and R⁴ bonded to the same carbon atom each represent a phenyl group, R³ and R⁴ may be bonded to each other to form a fluorene ring; and in Formula (1b), the groups represented by two R³s and the atoms or groups represented by two R⁴s may be different from each other; two ks each independently represent 0 or 1; m represents an integer of 3 to 500; each of n, n₁, and n₂ represents an integer of 2 to 500; p represents an integer of 3 to 500; X represents a single bond or a heteroatom; and two Qs each independently represent a structural unit represented by the following Formula (2):

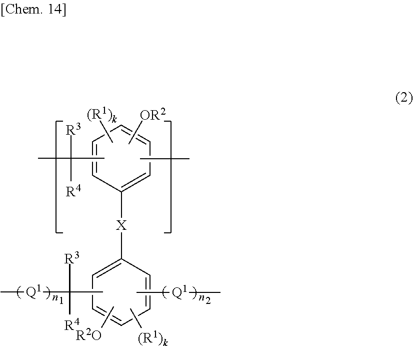

wherein, two R¹s, two R²s, two R³s, two R⁴s, two ks, n₁, n₂, and X are as defined in Formula (1b), and two Q¹s each independently represent a structural unit represented by Formula (2).

Preferably, the aromatic hydrocarbon group represented by R³ is a phenyl group, a naphthyl group, an anthryl group, or a pyrenyl group.

An example of a film material (c) capable of undergoing a crosslinking reaction includes a polymer having a unit structure represented by the following Formula (1) as disclosed in WO 2010/147155 A1:

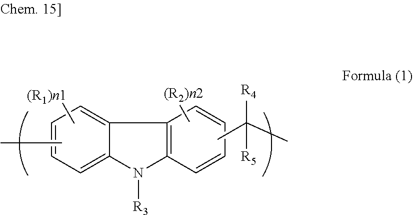

wherein,

each of R₁ and R₂ is selected from the group consisting of a hydrogen atom, a halogen group, a nitro group, an amino group, a hydroxy group, an alkyl group having 1 to 10 carbon atoms, an alkenyl group having 2 to 10 carbon atoms, an aryl group having 6 to 40 carbon atoms, and a combination thereof, in which the alkyl group, the alkenyl group, or the aryl group represents a group which may have an ether bond, a ketone bond, or an ester bond,

R₃ is selected from the group consisting of a hydrogen atom, an alkyl group having 1 to 10 carbon atoms, an alkenyl group having 2 to 10 carbon atoms, an aryl group having 6 to 40 carbon atoms, and a combination thereof, in which the alkyl group, the alkenyl group, or the aryl group represents a group which may have an ether bond, a ketone bond, or an ester bond,

R₄ represents an aryl group having 6 to 40 carbon atoms or a heterocyclic group which may be substituted with a halogen group, a nitro group, an amino group, or a hydroxy group,

R₅ represents a hydrogen atom, or an alkyl group having 1 to 10 carbon atoms, an aryl group having 6 to 40 carbon atoms, or a heterocyclic group which may be substituted with a halogen group, a nitro group, an amino group, or a hydroxy group,

R₄ and R₅ may be combined to form a ring together with a carbon atom bonded thereto, and

each of n1 and n2 is an integer of 1 to 3.

Preferably, the film material (c) is a polymer having a unit structure represented by Formula (1) in which each of R₁, R₂, R₃, and R₅ represents a hydrogen atom and R₄ represents a phenyl group or a naphthyl group.

Preferably, in Formula (1), each of R₁, R₂, and R₃ represents a hydrogen atom, and R₄ and R₅ are combined to form a fluorene ring together with a carbon atom bonded thereto. In this case, the film material (c) is a polymer according to claim 1, in which the carbon atom has a unit structure which is a carbon atom at the 9-position of the formed fluorene ring.

Preferably, the film material (c) is a polymer having a unit structure represented by the following Formula (2) and/or (3):

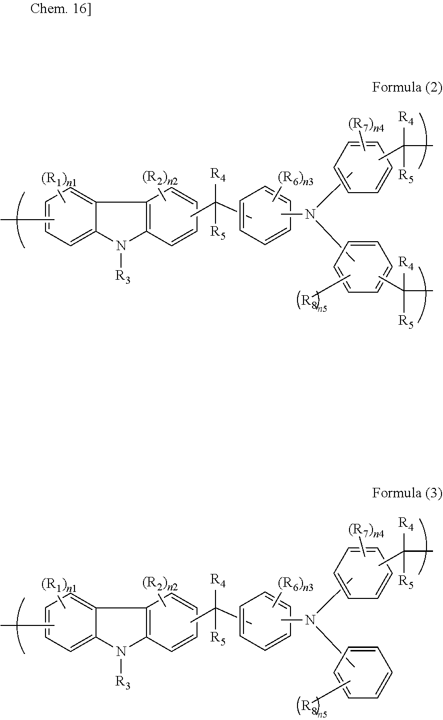

wherein,

each of R₁, R₂, R₆, R₇, and R₈ is selected from the group consisting of a hydrogen atom, a halogen group, a nitro group, an amino group, a hydroxy group, an alkyl group having 1 to 10 carbon atoms, an alkenyl group having 2 to 10 carbon atoms, an aryl group having 6 to 40 carbon atoms, and a combination thereof, in which the alkyl group, the alkenyl group, or the aryl group represents a group which may have an ether bond, a ketone bond, or an ester bond,

R₃ is selected from the group consisting of a hydrogen atom, an alkyl group having 1 to 10 carbon atoms, an alkenyl group having 2 to 10 carbon atoms, an aryl group having 6 to 40 carbon atoms, and a combination thereof, in which the alkyl group, the alkenyl group, or the aryl group represents a group which may have an ether bond, a ketone bond, or an ester bond,

R₄ represents an aryl group having 6 to 40 carbon atoms or a heterocyclic group which may be substituted with a halogen group, a nitro group, an amino group, or a hydroxy group,

R₅ represents a hydrogen atom, or an alkyl group having 1 to 10 carbon atoms, an aryl group having 6 to 40 carbon atoms, or a heterocyclic group which may be substituted with a halogen group, a nitro group, an amino group, or a hydroxy group,

R₄ and R₅ may be combined to form a ring together with a carbon atom bonded thereto,

each of n1 and n2 is an integer of 1 to 3, and

each of n3 to n5 is an integer of 1 to 4.

Preferably, the film material (c) is a polymer having a unit structure represented by Formula (2) and/or (3) in which each of R₁, R₂, R₃, R₅, R₆, R₇, and R₈ represents a hydrogen atom and R₄ represents a phenyl group or a naphthyl group.

An example of a film material (d) capable of undergoing a crosslinking reaction includes a polymer having a unit structure composed of a reaction product of a fused heterocyclic compound and a bicyclic compound as disclosed in WO 2013/005797 A1.

Preferably, the fused heterocyclic compound is a carbazole compound or a substituted carbazole compound.

Preferably, the bicyclic compound is dicyclopentadiene, substituted dicyclopentadiene, tetracyclo[4.4.0.1^{2,5}.1^{7,10}′¹⁰]dodeca-3,8-diene, or substituted tetracyclo[4.4.0.1^{2,5}0.1^{7,10}] dodeca-3,8-diene.

Preferably, the polymer is a polymer having a unit structure represented by the following Formula (1), a unit structure represented by the following Formula (2), a unit structure represented by the following Formula (3), or a combination thereof.

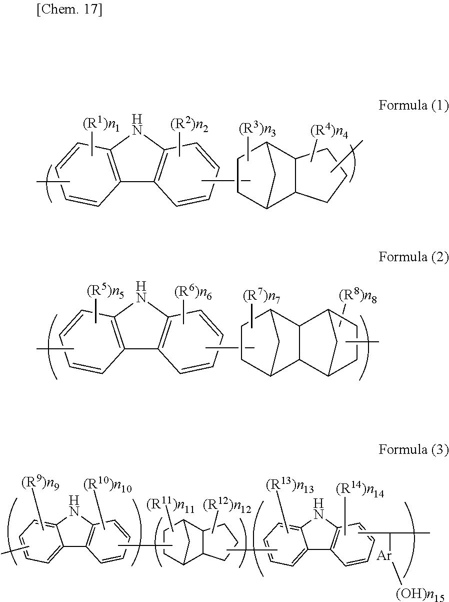

wherein, R¹ to R¹⁴ are substituents of hydrogen atoms and are each independently an alkyl group having 1 to 10 carbon atoms or an aryl group having 6 to 40 carbon atoms, which may be substituted with a halogen group, a nitro group, an amino group, a hydroxy group, or a group thereof, Ar is an aromatic ring group having 6 to 40 carbon atoms, each of n₁, n₂, n₅, n₆, n₉, n₁₀, n₁₃, n₁₄, and n₁₅ is an integer of 0 to 3, and each of n₃, n₄, n₇, n₈, n₁₁, and n₁₂ is an integer of 0 to 4.

Preferably, in Formula (3), Ar is a phenyl group or a naphthyl group.

An example of a film material (e) capable of undergoing a crosslinking reaction includes a polymer having a unit structure represented by Formula (1) as disclosed in WO 2012/176767 A1:

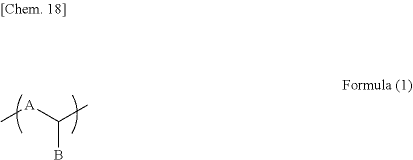

wherein, A is a hydroxy group-substituted phenylene group derived from polyhydroxybenzene, and B is a monovalent fused aromatic hydrocarbon ring group, in which 2 to 4 benzene rings are fused.

Preferably, A is a hydroxy group-substituted phenylene group derived from benzenediol or benzenetriol.

Preferably, A is a hydroxy group-substituted phenylene group derived from catechol, resorcinol, hydroquinone, pyrogallol, hydroxyquinol, or phloroglucinol.

Preferably, the fused aromatic hydrocarbon ring group of B is a naphthalene ring group, an anthracene ring group, or a pyrene ring group.

Preferably, the fused aromatic hydrocarbon ring group of B is a halogen group, a hydroxy group, a nitro group, an amino group, a carboxyl group, a carboxylic acid ester group, a ditolyl group, or a group having a combination thereof as a substituent.

An example of a film material (f) capable of undergoing a crosslinking reaction includes a polymer having a unit structure (A) represented by the following Formula (1) as disclosed in WO 2013/047516 A1:

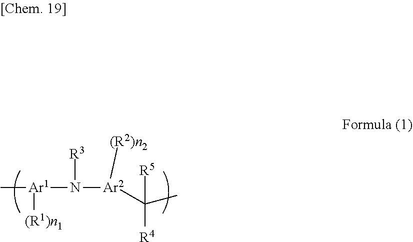

wherein, each of Ar¹ and Ar² represents a benzene ring or a naphthalene ring, each of R¹ and R² is a substituent of a hydrogen atom on the benzene ring or the naphthalene ring and is selected from the group consisting of a halogen group, a nitro group, an amino group, a hydroxy group, an alkyl group having 1 to 10 carbon atoms, an alkenyl group having 2 to 10 carbon atoms, an aryl group having 6 to 40 carbon atoms, and a combination thereof, in which each of the alkyl group, the alkenyl group, and the aryl group represents an organic group, which may have an ether bond, a ketone bond, or an ester bond,

R³ is selected from the group consisting of a hydrogen atom, an alkyl group having 1 to 10 carbon atoms, an alkenyl group having 2 to 10 carbon atoms, an aryl group having 6 to 40 carbon atoms, and a combination thereof, in which each of the alkyl group, the alkenyl group, and the aryl group represents an organic group which may have an ether bond, a ketone bond, or an ester bond,

R⁴ is selected from the group consisting of an aryl group having 6 to 40 carbon atoms and a heterocyclic group, in which each of the aryl group and the heterocyclic group represents an organic group, which may be substituted with a halogen group, a nitro group, an amino group, an alkyl group having 1 to 10 carbon atoms, an alkoxy group having 1 to 10 carbon atoms, an aryl group having 6 to 40 carbon atoms, a formyl group, a carboxyl group, or a hydroxy group,

R⁵ is selected from the group consisting of a hydrogen atom, an alkyl group having 1 to 10 carbon atoms, an aryl group having 6 to 40 carbon atoms, and a heterocyclic group, in which each of the alkyl group, the aryl group, and the heterocyclic group represents an organic group, which may be substituted with a halogen group, a nitro group, an amino group, or a hydroxy group,

R⁴ and R⁵ may be combined to form a ring together with a carbon atom bonded thereto, and each of n1 and n2 is an integer of 0 to 3.

Preferably, in Formula (1), R⁵ is a hydrogen atom, and R⁴ is a phenyl group, a naphthyl group, an anthryl group, or a pyrenyl group, which may be substituted.

Preferably, in Formula (1), R³ is a hydrogen atom or a phenyl group.

Preferably, the unit structure (A) includes a unit structure (a1), in which one of

Ar¹ and Ar² is a benzene ring and the other one of Ar¹ and Ar² is a naphthalene ring.

Preferably, the unit structure (A) includes a unit structure (a2), in which Ar¹ and Ar² form a benzene ring.

Preferably, the film material (f) is a copolymer having a unit structure (a1) and a unit structure (a2).

Preferably, the film material (f) is a copolymer having a unit structure (A) of

Formula (1) and a unit structure (B) of the following Formula (2):

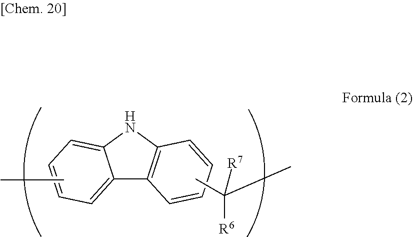

wherein, R⁶ is selected from the group consisting of an aryl group having 6 to 40 carbon atoms and a heterocyclic group, in which each of the aryl group and the heterocyclic group represents an organic group, which may be substituted with a halogen group, a nitro group, an amino group, an alkyl group having 1 to 10 carbon atoms, an alkoxy group having 1 to 10 carbon atoms, an aryl group having 6 to 40 carbon atoms, a formyl group, a carboxyl group, or a hydroxy group; R⁷ is selected from the group consisting of a hydrogen atom, an alkyl group having 1 to 10 carbon atoms, an aryl group having 6 to 40 carbon atoms, and a heterocyclic group, in which each of the alkyl group, the aryl group, and the heterocyclic group represents an organic group, which may be substituted with a halogen group, a nitro group, an amino group, or a hydroxy group; and R⁶ and R⁷ may be combined to form a ring together with a carbon atom bonded thereto.

Preferably, the film material (f) is a copolymer having a unit structure (a1) and a unit structure (B).

An example of a film material (g) capable of undergoing a crosslinking reaction includes a polymer having a unit structure represented by the following Formula (1) as disclosed in WO 2013/146670 A1:

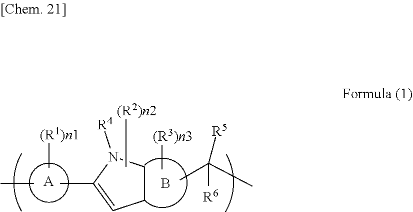

wherein, R¹, R², and R³ replace the hydrogen atoms on the rings and are each independently a halogen group, a nitro group, an amino group, a hydroxy group, an alkyl group having 1 to 10 carbon atoms, an alkenyl group having 2 to 10 carbon atoms, an aryl group having 6 to 40 carbon atoms, or a combination thereof, which may have an ether bond, a ketone bond, or an ester bond; R⁴ is a hydrogen atom, an alkyl group having 1 to 10 carbon atoms, an alkenyl group having 2 to 10 carbon atoms, an aryl group having 6 to 40 carbon atoms, or a combination thereof, which may have an ether bond, a ketone bond, or an ester bond; R⁵ is a hydrogen atom, or an aryl group having 6 to 40 carbon atoms or a heterocyclic group, which may be substituted with a halogen group, a nitro group, an amino group, a formyl group, a carboxyl group, a carboxylic acid alkyl ester group, a phenyl group, an alkoxy group having 1 to 10 carbon atoms, or a hydroxy group; R⁶ is a hydrogen atom, or an alkyl group having 1 to 10 carbon atoms, an aryl group having 6 to 40 carbon atoms, or a heterocyclic group which may be substituted with a halogen group, a nitro group, an amino group, a formyl group, a carboxyl group, a carboxylic acid alkyl ester group, or a hydroxy group; and R⁵ and R⁶ may be combined to form a ring together with a carbon atom bonded thereto; each of the ring A and the ring B represents a benzene ring, a naphthalene ring, or an anthracene ring; and each of n1, n2, and n3 is an integer of 0 or more up to the maximum number of substituents that can be on the ring.

Preferably, both the ring A and the ring B are benzene rings, each of n1, n2, and n3 is 0, and R⁴ is a hydrogen atom.

Preferably, R⁵ is a hydrogen atom, or a phenyl group, a naphthyl group, an anthryl group, or a pyrenyl group, which may be substituted with a halogen group, a nitro group, an amino group, a formyl group, a carboxyl group, a carboxylic acid alkyl ester group, a phenyl group, an alkoxy group having 1 to 10 carbon atoms, or a hydroxy group; and R⁶ is a hydrogen atom.

An example of a film material (h) capable of undergoing a crosslinking reaction includes a polymer having one or two or more repeating structural units represented by the following Formulas (1a), (1b), and (1c) as disclosed in WO 2014/129582 A1:

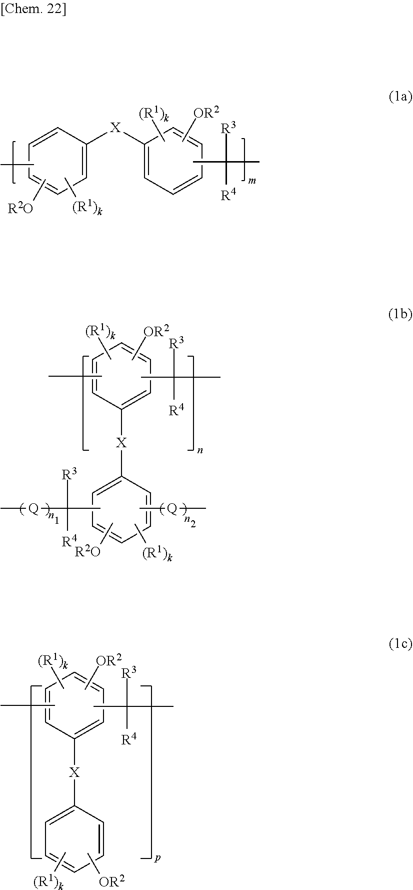

wherein, two R's each independently represent an alkyl group having 1 to 10 carbon atoms, an alkenyl group having 2 to 6 carbon atoms, an aromatic hydrocarbon group, a halogen atom, a nitro group, or an amino group; two R^{e}s each independently represent a hydrogen atom, an alkyl group having 1 to 10 carbon atoms, an alkenyl group having 2 to 6 carbon atoms, an acetal group, an acyl group, or a glycidyl group; R³ represents an aromatic hydrocarbon group which may have a substituent; R⁴ represents a hydrogen atom, a phenyl group, or a naphthyl group; when R³ and R⁴ bonded to the same carbon atom each represent a phenyl group, R³ and R⁴ may be bonded to each other to form a fluorene ring; and in Formula (1b), the groups represented by two R^{a}s and the atoms or groups represented by two R⁴s may be different from each other; two ks each independently represent 0 or 1; m represents an integer of 3 to 500; each of n, n₁, and n₂ represents an integer of 2 to 500; p represents an integer of 3 to 500; X represents a single bond or a heteroatom; and two Qs each independently represent a structural unit represented by the following Formula (2):

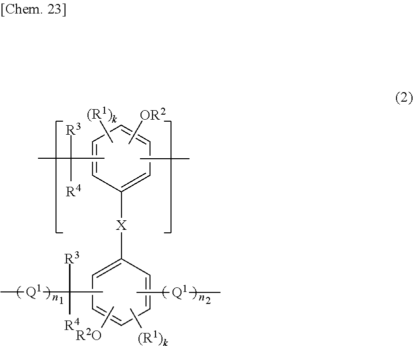

wherein, two R¹s, two R²s, two R³s, two R⁴s, two ks, n₁, n₂, and X are as defined in Formula (1b); and two Q¹s each independently represent a structural unit represented by Formula (2).

Preferably, the aromatic hydrocarbon group represented by R³ is a phenyl group, a naphthyl group, an anthryl group, or a pyrenyl group.

An example of a film material (i) capable of undergoing a crosslinking reaction includes a polymer having a unit structure represented by the following Formula (1) as disclosed in WO 2016/072316 A1:

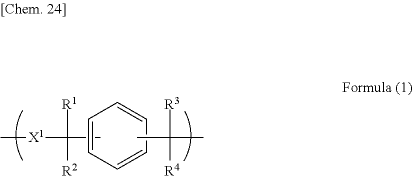

wherein, R¹ to R⁴ each independently represent a hydrogen atom or a methyl group; and X¹ represents a divalent organic group having at least one arylene group, which may be substituted with an alkyl group, an amino group, or a hydroxy group.

Preferably, in Formula (1), the arylene group in the definition of X¹ is a phenylene group, a biphenylene group, a terphenylene group, a fluorenylene group, a naphthylene group, an anthrylene group, a pyrenylene group, or a carbazolylene group.

Preferably, in Formula (1), X^{e} represents an organic group represented by Formula (2):

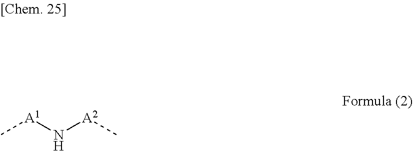

wherein, A¹ represents a phenylene group or a naphthylene group; A² represents a phenylene group, a naphthylene group, or an organic group substituted by Formula (3):

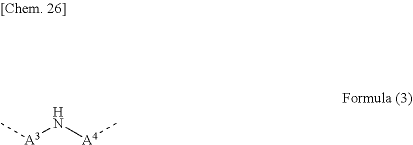

wherein, A³ and A⁴ each independently represent a phenylene group or a naphthylene group; and the dotted line represents a bond.

An example of a film material (j) capable of undergoing a crosslinking reaction includes a novolac resin obtained by reacting an aromatic compound (A) with an aldehyde (B) having a formyl group bonded to a secondary carbon atom or a tertiary carbon atom of an alkyl group having 2 to 26 carbon atoms, as disclosed in WO 2017/069063 A1.

Preferably, the novolac resin has a unit structure represented by the following Formula (1):

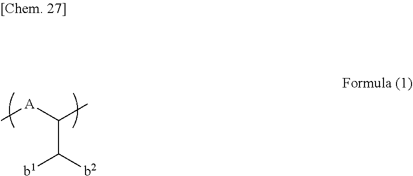

wherein, A represents a divalent group derived from an aromatic compound having 6 to 40 carbon atoms; b¹ represents an alkyl group having 1 to 16 carbon atoms; and b² represents a hydrogen atom or an alkyl group having 1 to 9 carbon atoms.

Preferably, A is a divalent group derived from an aromatic compound having an amino group, a hydroxy group, or both.

Preferably, A is a divalent group derived from an aromatic compound including an arylamine compound, a phenol compound, or both.

Preferably, A is divalent group derived from aniline, diphenylamine, phenylnaphthylamine, hydroxydiphenylamine, carbazole, phenol, N,N′-diphenylethylenediamine, N,N′-diphenyl-1,4-phenylenediamine, or polynuclear phenol.

Preferably, the polynuclear phenol is dihydroxybenzene, trihydroxybenzene, hydroxynaphthalene, dihydroxynaphthalene, trihydroxynaphthalene, tris(4-hydroxyphenyl)methane, tris(4-hydroxyphenyl)ethane, 2,2′-biphenol, or 1,1,2,2-tetrakis(4-hydroxyphenyl)ethane.

Preferably, the novolac resin has a unit structure represented by the following Formula (2):

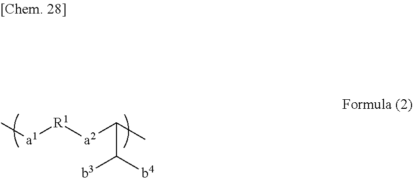

wherein, each of a¹ and a² represents a benzene ring or a naphthalene ring, which may be substituted; le represents a secondary amino group or a tertiary amino group, a divalent hydrocarbon group having 1 to 10 carbon atoms, which may be substituted, an arylene group, or a divalent group, which is a combination of these groups; b³ represents an alkyl group having 1 to 16 carbon atoms; and b⁴ represents a hydrogen atom or an alkyl group having 1 to 9 carbon atoms.

An example of a film material (k) capable of undergoing a crosslinking reaction includes a polymer having a repeating structural unit represented by the following Formula (1a) and/or (1b) as disclosed in WO 2017/199768 A1:

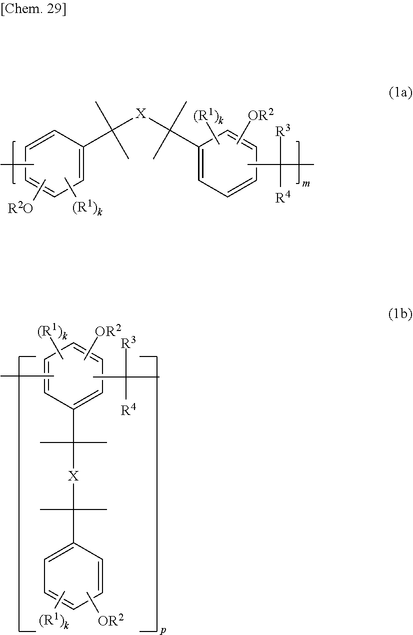

wherein, two les each independently represent an alkyl group having 1 to 10 carbon atoms, an alkenyl group having 2 to 6 carbon atoms, an aromatic hydrocarbon group, a halogen atom, a nitro group, or an amino group; two R^{e}s each independently represent a hydrogen atom, an alkyl group having 1 to 10 carbon atoms, an alkenyl group having 2 to 6 carbon atoms, an acetal group, an acyl group, or a glycidyl group; R³ represents an aromatic hydrocarbon group or a heterocyclic group, which may have a substituent; R⁴ represents a hydrogen atom, a phenyl group, or a naphthyl group; when R³ and R⁴ bonded to the same carbon atom each represent a phenyl group, R³ and R⁴ may be bonded to each other to form a fluorene ring; two ks each independently represent 0 or 1; m represents an integer of 3 to 500; p represents an integer of 3 to 500; X represents a benzene ring; and two —C(CH₃)₂— groups bonded to the benzene ring have a meta-position or para-position relationship.

Preferably, the polymer is a polymerization reaction product of at least one bisphenol compound and at least one aromatic aldehyde or aromatic ketone.

Preferably, the aromatic hydrocarbon group represented by R³ is a phenyl group, a naphthyl group, an anthryl group, or a pyrenyl group.

An example of a film material (1) capable of undergoing a crosslinking reaction includes a poly(epoxide) resin having an epoxy-functional value of greater than 2.0 and less than 10, as disclosed in JP 11-511194 A.

Preferably, the poly(epoxide) resin is selected from the group consisting of a bisphenol A-epichlorohydrin resin product, epoxy novolac, o-cresol epoxy novolac, polyglycidyl ether, polyglycidyl amine, alicyclic epoxide, and polyglycidyl ester.

Preferably, the poly(epoxide) resin has an epoxy-functional value of greater than 3.5.

Examples of a film material (m) capable of undergoing a crosslinking reaction or a novolac film material include a compound represented by the following Formula (1) and a novolac film material as disclosed in WO 2018/198960 A1.

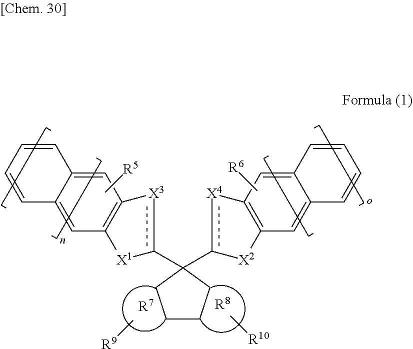

wherein,

### [Chem. 31]

[symbol]

represents a single bond or a double bond,

X¹ represents —N(R′)— or —CH(R′)—,

X² represents —N(R²)— or —CH(R²)—,

X³ represents —N═, —CH═, —N(R³)—, or —CH(R³)—,

X⁴ represents —N═, —CH═, —N(R⁴)—, or —CH(R⁴)—,

R¹, R², R³, and R⁴ are the same as each other or different from each other and each represent a hydrogen atom, a C1-20 linear, branched, or cyclic alkyl group, a C6-20 aryl group, a C2-10 alkenyl group, a C2-10 alkynyl group, a carboxyl group, or a cyano group, in which each of the alkyl group and the aryl group may be substituted with a C1-6 acyl group, a C1-6 alkoxy group, a C1-6 alkoxycarbonyl group, an amino group, a glycidyl group, or a hydroxy group and may be interrupted by an oxygen atom or a sulfur atom,

R⁵, R⁶, R⁹, and R¹⁰ are the same as each other or different from each other and each represent a hydrogen atom, a hydroxy group, a C1-6 acyl group, a C1-6 alkoxy group, a C1-6 alkoxycarbonyl group, a C1-10 linear, branched, or cyclic alkyl group, a C6-20 aryl group, a C2-20 alkenyl group, or a C2-10 alkynyl group, in which each of the acyl group, the alkoxy group, the alkoxycarbonyl group, the alkyl group, the aryl group, the alkenyl group, and the alkynyl group may have one or a plurality of groups selected from the group consisting of an amino group, a nitro group, a cyano group, a hydroxy group, a glycidyl group, and a carboxyl group,

R⁷ and R⁸ are the same as each other or different from each other and each represent a benzene ring or a naphthalene ring, and each of n and o is 0 or 1.

Preferably, in Formula (1), R′, R², R³, or R⁴ is a hydroxy group or a C1-20 linear, branched, or cyclic alkyl group which may be substituted with a hydroxy group and may be interrupted by an oxygen atom or a sulfur atom.

Preferably, the film material (m) is a compound having one or a plurality of units of repeating units a, b, c, d, e, f, g, h, and i represented by the following Formula (2).

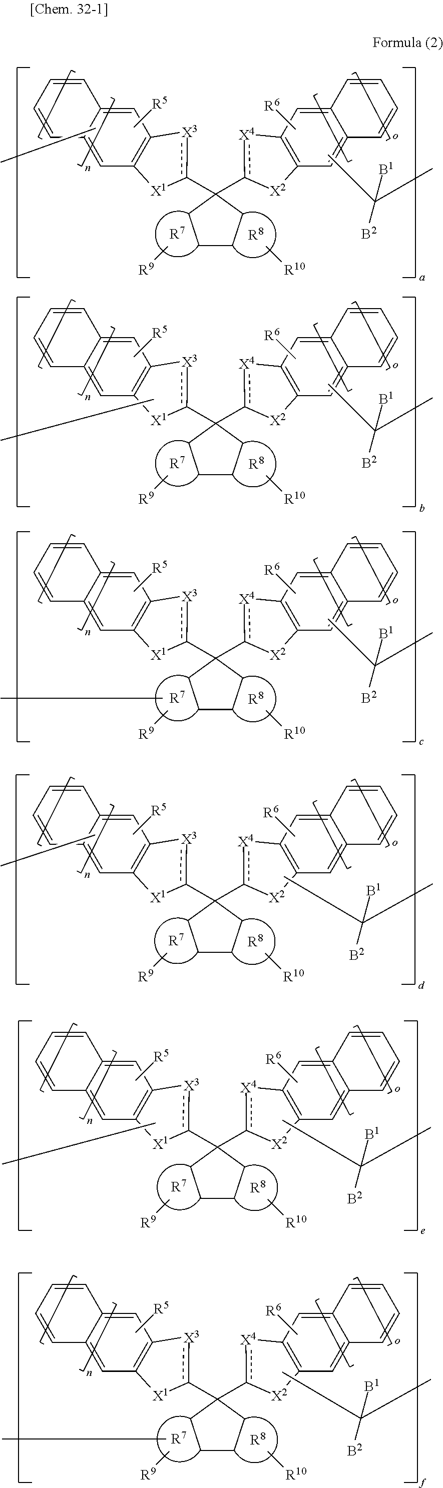

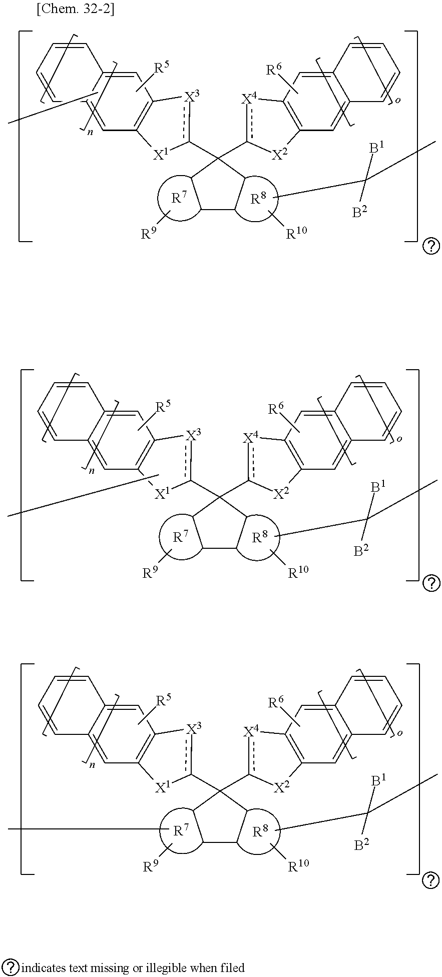

wherein,

### [Chem. 33]

[symbol]

represents a single bond or a double bond,

X¹ represents —N(R′)—, —CH(R′)—, —N<, or —CH<,

X² represents —N(R²)—, —CH(R²)—, —N<, or —CH<,

X³ represents —N═, —CH═, —N(R³)—, —CH(R³)—, —N<, or —CH<,

X⁴ represents —N═, —CH═, —N(R⁴)—, —CH(R⁴)—, —N<, or —CH<,

R¹, R², R³, and R⁴ are the same as each other or different from each other and each represent a hydrogen atom, a C1-20 linear, branched, or cyclic alkyl group, a C6-20 aryl group, a C2-10 alkenyl group, a C2-10 alkynyl group, a carboxyl group, or a cyano group, in which each of the alkyl group and the aryl group may be substituted with a C1-6 acyl group, a C1-6 alkoxy group, a C1-6 alkoxycarbonyl group, an amino group, a glycidyl group, or a hydroxy group and may be interrupted by an oxygen atom or a sulfur atom,

R⁵, R⁶, R⁹, and R¹⁰ are the same as each other or different from each other and each represent a hydrogen atom, a hydroxy group, a C1-6 acyl group, a C1-6 alkoxy group, a C1-6 alkoxycarbonyl group, a C1-10 linear, branched, or cyclic alkyl group, a C6-20 aryl group, a C2-20 alkenyl group, or a C2-10 alkynyl group, in which each of the acyl group, the alkoxy group, the alkoxycarbonyl group, the alkyl group, the aryl group, the alkenyl group, and the alkynyl group may have one or a plurality of groups selected from the group consisting of an amino group, a nitro group, a cyano group, a hydroxy group, a glycidyl group, and a carboxyl group,

R⁷ and R⁸ are the same as each other or different from each other and each represent a benzene ring or a naphthalene ring,

each of n and o is 0 or 1, and

B¹ and B² are the same as each other or different from each other and each represent a group derived from an aromatic compound selected from the group consisting of a C1-20 linear, branched, or cyclic alkyl group or C6-40 aryl group, which may be interrupted by a hydrogen atom, an oxygen atom, or a sulfur atom and a C6-40 heterocyclic group; B¹ and B² may be combined to form a ring together with a carbon atom bonded thereto; and the hydrogen atom of the group derived from an aromatic compound may be replaced by a C1-20 alkyl group, a phenyl group, a fused ring group, a heterocyclic group, a hydroxy group, an amino group, an ether group, an alkoxy group, a cyano group, a nitro group, or a carboxyl group.

Preferably, the film material (m) is a compound having one or a plurality of units of repeating units j, k, l, m, r, s, t, u, v, and w represented by the following Formula (3).

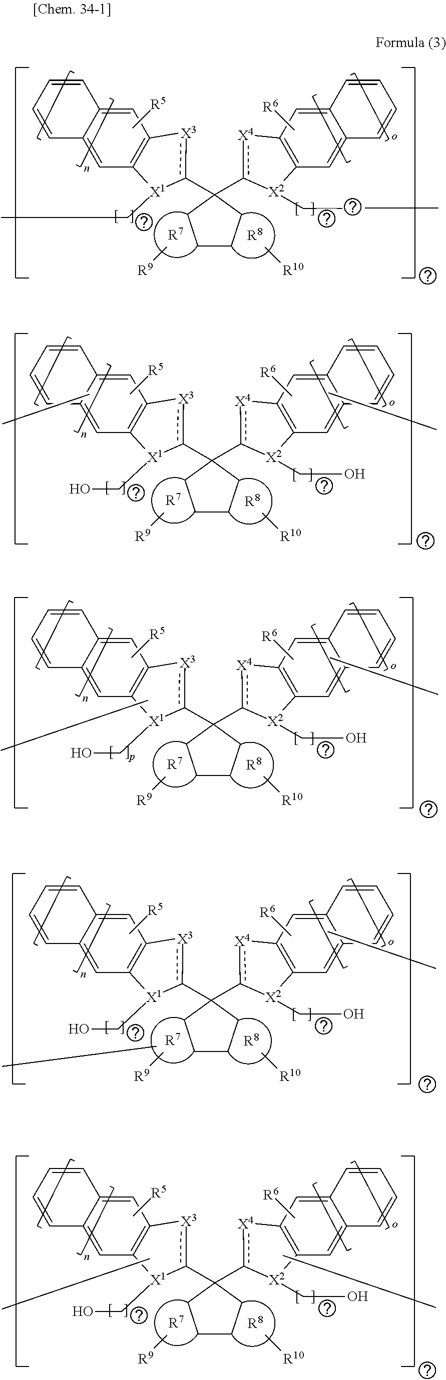

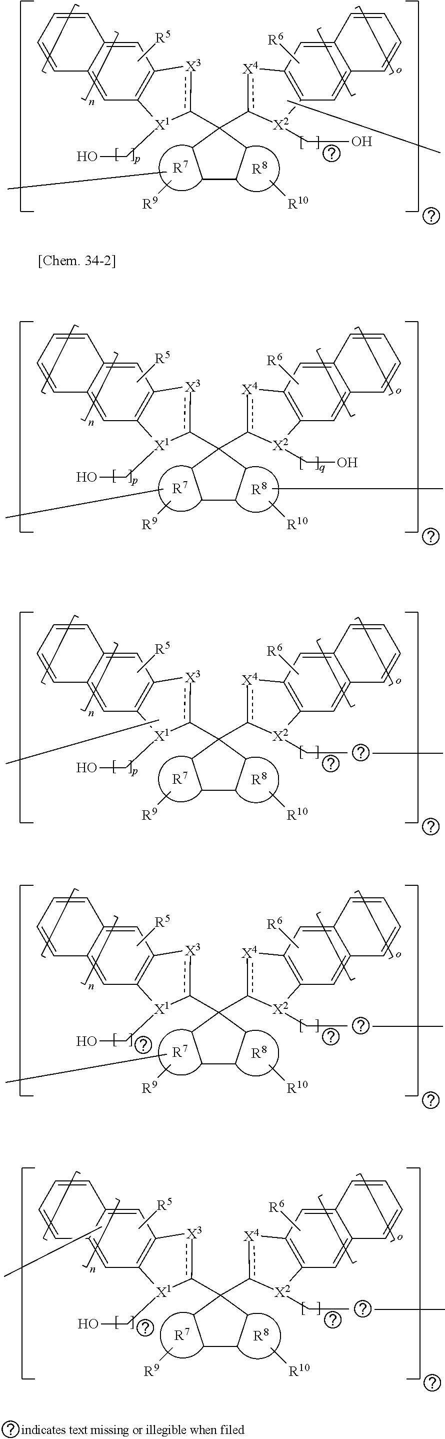

wherein,

### [Chem. 35]

[symbol]

represents a single bond or a double bond,

X¹ represents —N< or —CH<,

X² represents —N< or —CH<,

X³ represents —N═, —CH═, —N(R³)—, or —CH(R³)—,

X⁴ represents —N═, —CH═, —N(R⁴)—, or —CH(R⁴)—,

R³ and R⁴ are the same as each other or different from each other and each represent a hydrogen atom, a C1-20 linear, branched, or cyclic alkyl group, a C6-20 aryl group, a C2-10 alkenyl group, a C2-10 alkynyl group, a carboxyl group, or a cyano group, in which each of the alkyl group and the aryl group may be substituted with a C1-6 acyl group, a C1-6 alkoxy group, a C1-6 alkoxycarbonyl group, an amino group, a glycidyl group, or a hydroxy group and may be interrupted by an oxygen atom or a sulfur atom,

R⁵, R⁶, R⁹, and R¹⁰ are the same as each other or different from each other and each represent a hydrogen atom, a hydroxy group, a C1-6 acyl group, a C1-6 alkoxy group, a C1-6 alkoxycarbonyl group, a C1-10 linear, branched, or cyclic alkyl group, a C6-20 aryl group, a C2-20 alkenyl group, or a C2-10 alkynyl group, in which each of the acyl group, the alkoxy group, the alkoxycarbonyl group, the alkyl group, the aryl group, the alkenyl group, and the alkynyl group may have one or a plurality of groups selected from the group consisting of an amino group, a nitro group, a cyano group, a hydroxy group, a glycidyl group, and a carboxyl group,

R⁷ and R⁸ are the same as each other or different from each other and each represent a benzene ring or a naphthalene ring,

each of n and o is 0 or 1,

each of p and q is an integer of 0 to 20,

when each of the p quantity of methylene groups and q quantity of methylene groups is 2 or more, the methylene group may be interrupted by an oxygen atom or a sulfur group, and

B³ represents a direct bond, or a group derived from a C6-40 aromatic compound, which may be substituted with a C1-20 alkyl group, a phenyl group, a fused ring group, a heterocyclic group, a hydroxy group, an amino group, an ether group, an alkoxy group, a cyano group, a nitro group, or a carboxyl group.

Preferably, in Formula (1), R′, R², R³, or R⁴ is a hydroxy group or a C1-20 linear, branched, or cyclic alkyl group, which may be substituted with a hydroxy group and may be interrupted by an oxygen atom or a sulfur atom.

An example of a film material (n) capable of undergoing a crosslinking reaction includes an epoxy adduct formed by reacting an epoxy group-containing compound having at least two epoxy groups with an epoxy adduct-forming compound having one epoxy adduct-reactive group as disclosed in WO 2017/002653 A1.

Examples of such an epoxy adduct include the followings.

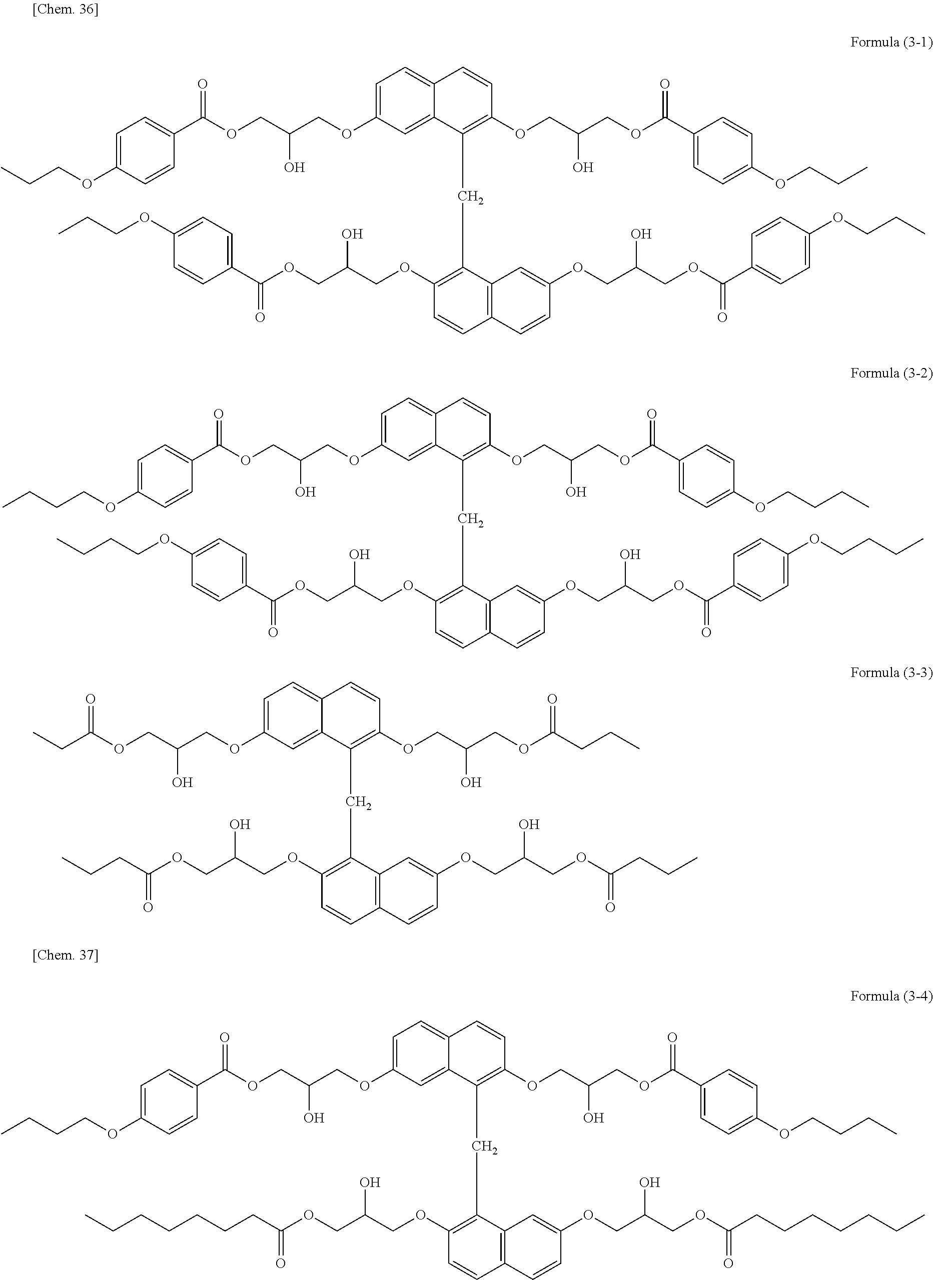

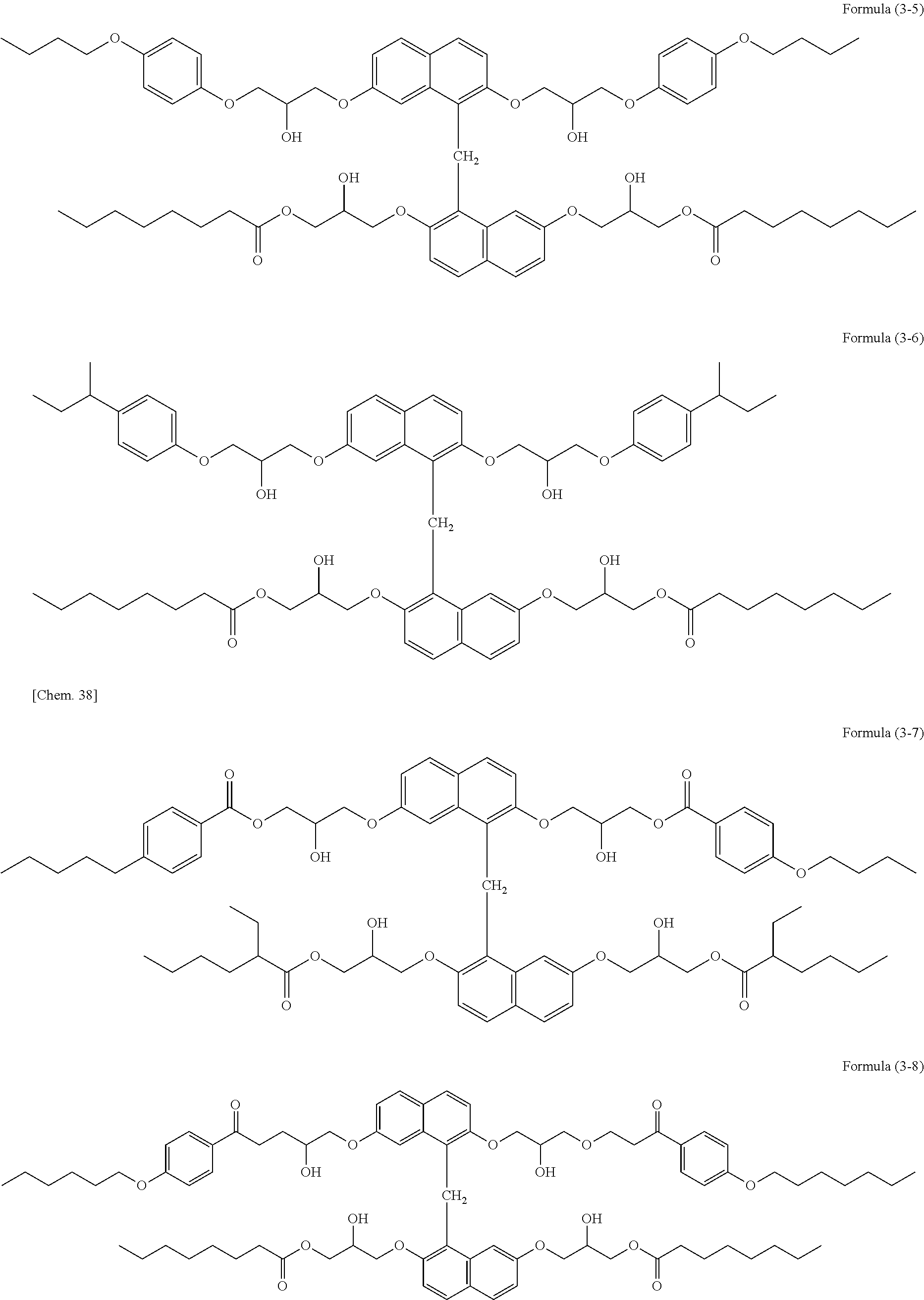

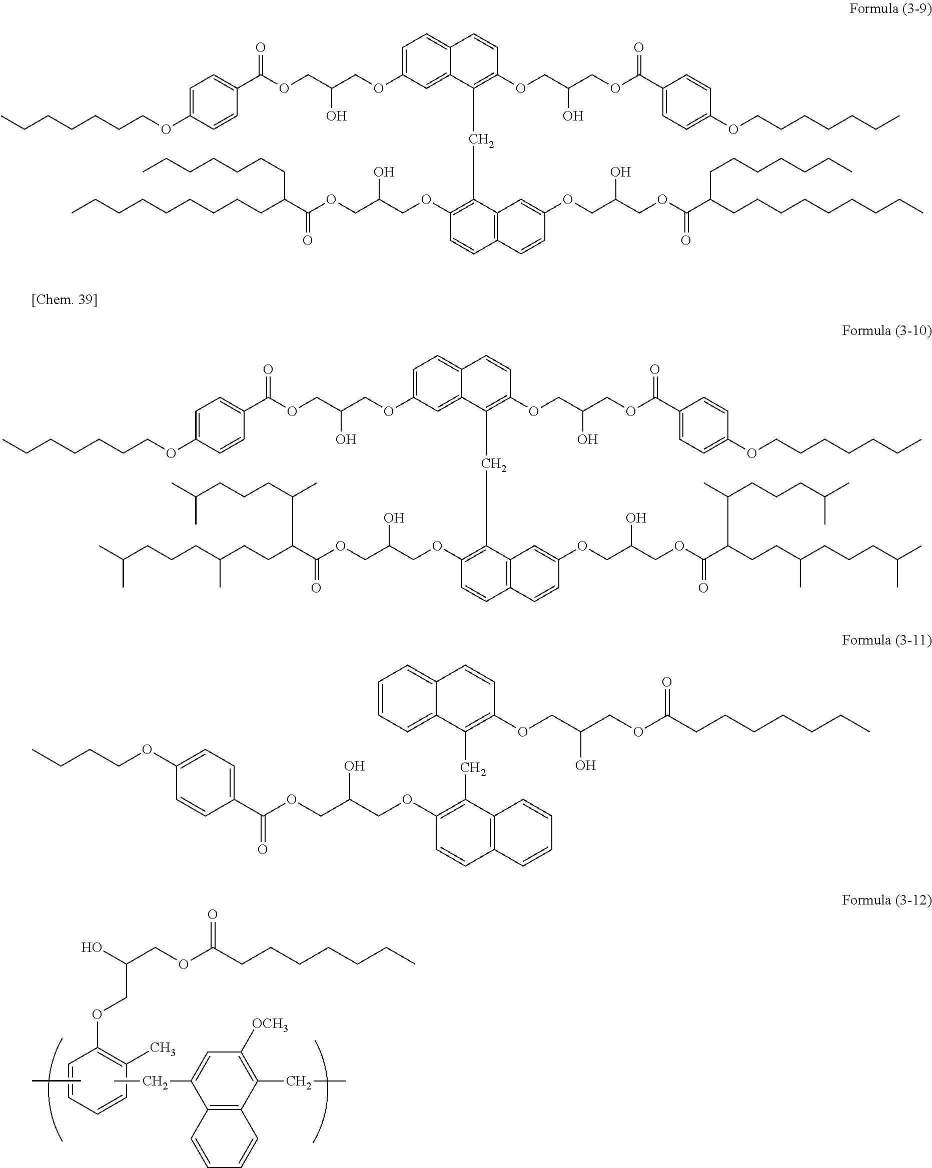

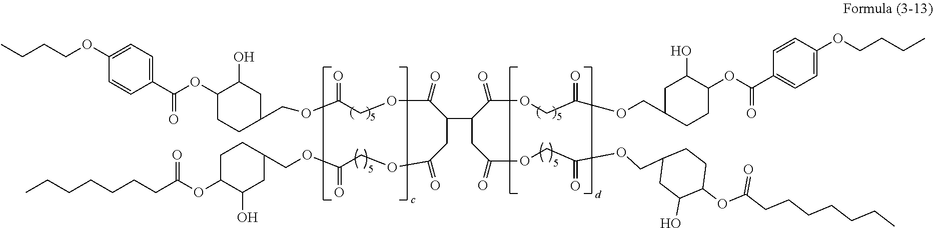

wherein, each of a, b, c, and d is 0 or 1 and a+b+c+d=1.

An example of a film material (o) capable of undergoing a crosslinking reaction includes a polymer having a structure represented by Formula (1) as disclosed in WO 2005/098542 A1:

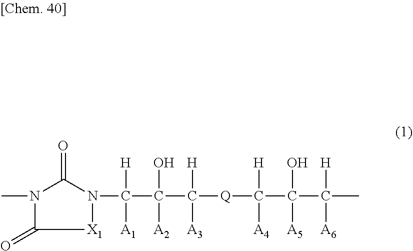

wherein, each of A₁, A₂, A₃, A₄, A₅, and A₆ represents a hydrogen atom, a methyl group, or an ethyl group; and X₁ represents Formula (2), (3), (4), or (5):

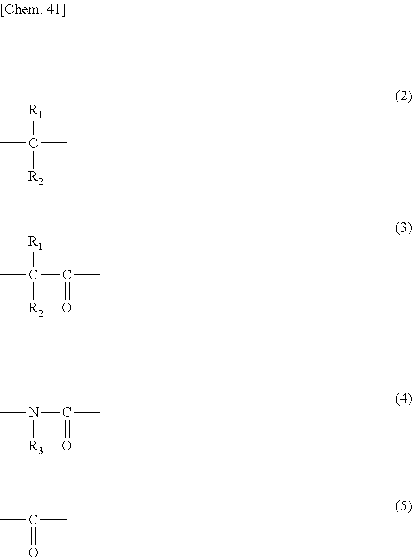

wherein, each of R₁ and R₂ represents a hydrogen atom, an alkyl group having 1 to 6 carbon atoms, an alkenyl group having 3 to 6 carbon atoms, a benzyl group, or a phenyl group, in which the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, and an alkylthio group having 1 to 6 carbon atoms; R₁ and R₂ may be bonded to each other to form a ring having 3 to 6 carbon atoms; R₃ represents an alkyl group having 1 to 6 carbon atoms, an alkenyl group having 3 to 6 carbon atoms, a benzyl group, or a phenyl group, in which the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, and an alkylthio group having 1 to 6 carbon atoms; and Q represents Formula (6) or (7):

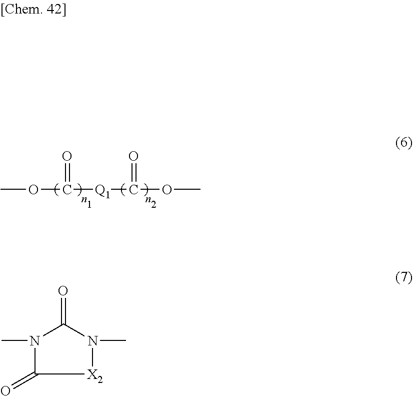

wherein, Q₁ represents an alkylene group having 1 to 10 carbon atoms, a phenylene group, a naphthylene group, or an anthrylene group, in which each of the phenylene group, the naphthylene group, and the anthrylene group may be substituted with a group selected from the group consisting of an alkyl group having 1 to 6 carbon atoms, a halogen atom, an alkoxy group having 1 to 6 carbon atoms, a nitro group, a cyano group, a hydroxy group, and an alkylthio group having 1 to 6 carbon atoms; each of n₁ and n₂ represents a number of 0 or 1; and X₂ represents Formula (2), (3), or (5).

Preferably, the structure represented by Formula (1) is a structure represented by Formula (12):

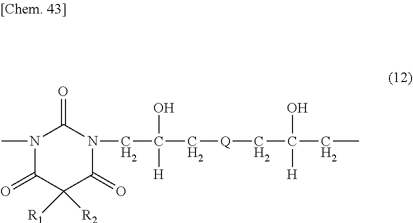

wherein, R₁, R₂, and Q are as defined above, or Formula (13):

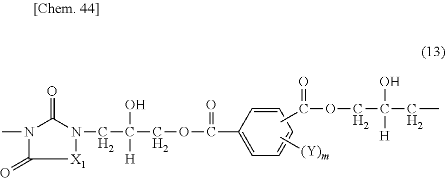

wherein, X₁ is as defined above; Y represents an alkyl group having 1 to 6 carbon atoms, a halogen atom, an alkoxy group having 1 to 6 carbon atoms, a nitro group, a cyano group, a hydroxy group, or an alkylthio group having 1 to 6 carbon atoms; m represents an integer of 0 to 4; and when m is 2 to 4, Ys may be the same as each other or different from each other.

An example of a film material (p) capable of undergoing a crosslinking reaction includes a polymer having a repeating unit structure represented by Formula (1) or (2) as disclosed in WO 2006/115074 A1:

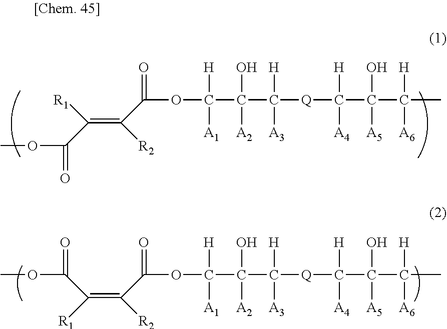

wherein, each of R₁ and R₂ represents a hydrogen atom, a methyl group, an ethyl group, or a halogen atom; each of A₁, A₂, A₃, A₄, A₅, and A₆ represents a hydrogen atom, a methyl group, or an ethyl group; and Q represents Formula (3) or (4):

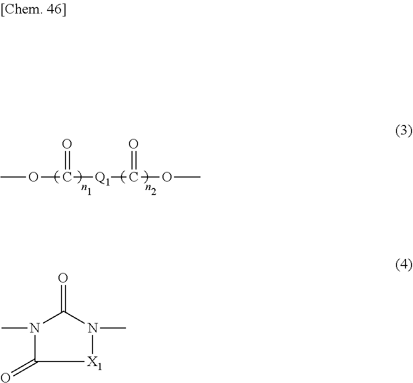

wherein, Q₁ represents an alkylene group having 1 to 15 carbon atoms, a phenylene group, a naphthylene group, or an anthrylene group, in which each of the phenylene group, the naphthylene group, and the anthrylene group may be substituted with a group selected from the group consisting of an alkyl group having 1 to 6 carbon atoms, a halogen atom, an alkoxy group having 1 to 6 carbon atoms, a nitro group, a cyano group, a hydroxy group, and an alkylthio group having 1 to 6 carbon atoms; each of n₁ and n₂ represents a number of 0 or 1; and X₁ represents Formula (5), (6), or (7),

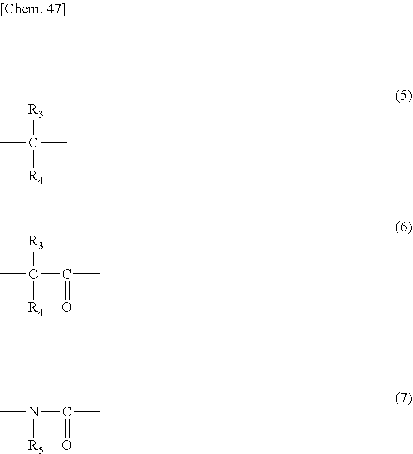

wherein, each of R₃ and R₄ represents a hydrogen atom, an alkyl group having 1 to 6 carbon atoms, an alkenyl group having 3 to 6 carbon atoms, a benzyl group, or a phenyl group, in which the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, and an alkylthio group having 1 to 6 carbon atoms; and R₃ and R₄ may be bonded to each other to form a ring having 3 to 6 carbon atoms; and R₅ represents an alkyl group having 1 to 6 carbon atoms, an alkenyl group having 3 to 6 carbon atoms, a benzyl group, or a phenyl group, in which the phenyl group may be substituted with a group selected from the group consisting of an alkyl group having 1 to 6 carbon atoms, a halogen atom, an alkoxy group having 1 to 6 carbon atoms, a nitro group, a cyano group, a hydroxy group, and an alkylthio group having 1 to 6 carbon atoms.

Preferably, the polymer is a polymer having a repeating unit structure represented by Formula (12):

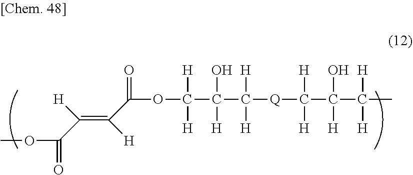

wherein, Q is as defined above.

Preferably, the polymer is a polymer having a repeating unit structure represented by Formula (13) or (14):

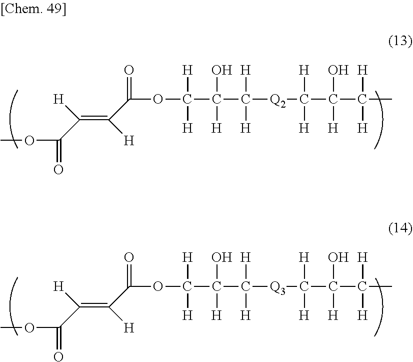

wherein, Q₂ represents Formula (15), (16), or (17):

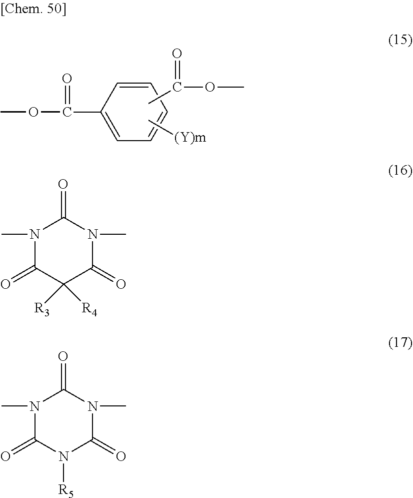

wherein, Y, m, R₃, R₄, and R₅ are as defined above; and Q₃ represents Formula (18):

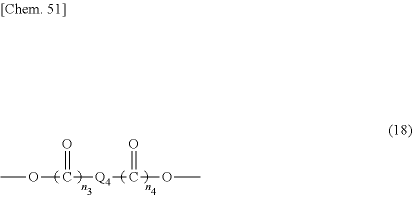

wherein, Q₄ represents an alkylene group having 1 to 15 carbon atoms; and

each of n₃ and n₄ represents a number of 0 or 1.

Examples of a film material (q) capable of undergoing a crosslinking reaction include polymers having at least one unit structure selected from the group consisting of unit structures represented by the following Formulas (1), (2), and (3) as disclosed in

WO 2008/069047 A1 and a combination thereof:

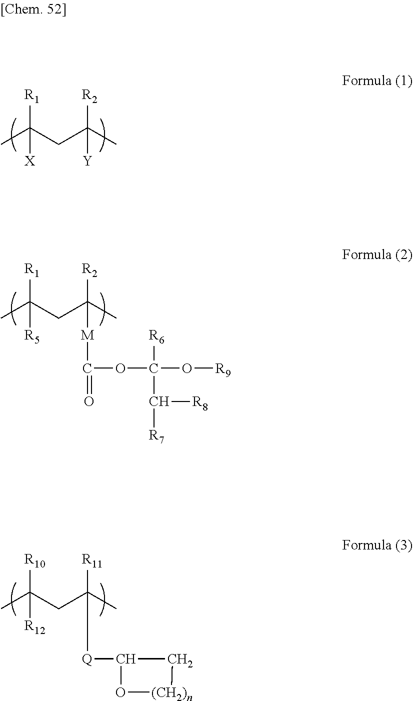

wherein,

X represents a hydrogen atom or an aromatic fused ring,

Y represents an aromatic fused ring, X and Y may be bonded to each other to form a fused ring,

each of R₁, R₂, R₃, R₄, R₅, R₁₀, R₁₁, and R₁₂ represents a hydrogen atom, a halogen atom, or an alkyl group having 1 to 3 carbon atoms,

each of R₆, R₇, and R₈ represents a hydrogen atom or a linear or cyclic alkyl group having 1 to 10 carbon atoms,

R₉ represents a linear or cyclic alkyl group having 1 to 10 carbon atoms or an aromatic group having 6 to 20 carbon atoms,

R₇ and R₈ may be bonded to each other to form a ring,

each of M and Q represents a direct bond or a linking group, and

n represents an integer of 0 or 1.

An example of the film material (q) includes a polymer, in which, when the total number of all unit structures constituting the polymer is 1.0, 0.3≤a≤0.95, 0.005≤b≤0.7, and 0≤c≤0.45, in which (a) is the proportion of the number of unit structures represented by Formula (1), (b) is the proportion of the number of unit structures represented by Formula (2), and (c) is the proportion of the number of unit structures represented by Formula (3).

Preferably, the polymer having unit structures represented by Formulas (1) and (2) is a polymer, in which, when the total number of all unit structures constituting the polymer is 1.0, 0.305≤a+b≤1, 0.3≤a≤0.95, and 0.005≤b≤0.7, in which (a) is the proportion of the number of unit structures represented by Formula (1) and (b) is the proportion of the number of unit structures represented by Formula (2).

Preferably, the polymer having unit structures represented by Formulas (1) and (3) is a polymer, in which, when the total number of all unit structures constituting the polymer is 1.0, 0.35≤a+c≤1, 0.3≤a≤0.95, and 0.05≤c≤0.7, in which (a) is the proportion of the number of unit structures represented by Formula (1) and (c) is the proportion the number of unit structures represented by Formula (3).

Preferably, the polymer having unit structures represented by Formulas (1), (2), and (3) is a polymer, in which, when the total number of all unit structures constituting the polymer is 1.0, 0.355≤a+b+c≤1, 0.3≤a≤0.9, 0.005≤b≤0.65, and 0.05≤c≤0.65, in which (a) is the proportion of the number of unit structures represented by Formula (1), (b) is the proportion of the number of unit structures represented by Formula (2), and (c) is the proportion of the number of unit structures represented by Formula (3).

Preferably, the unit structure represented by Formula (1) is a unit structure composed of vinylnaphthalene, acenaphthylene, vinylanthracene, vinylcarbazole, or derivatives thereof.

An example of a film material (r) capable of undergoing a crosslinking reaction includes compounds represented by the following Formula (2) as disclosed in WO 2018/203464 A1:

[Chem. 53]

Ar-Q-Ar (2)

wherein, two Ars each independently represent an aryl group, in which the aryl group has at least one hydroxy group as a substituent; and Q represents a divalent linking group having at least one benzene ring or naphthalene ring, a methylene group, or a single bond. The molecular weight thereof is, for example, within the range of 150 to 600.

Examples of the aryl group represented by Ar in Formula (2) include a phenyl group, a biphenylyl group, a naphthyl group, an anthryl group, and a phenanthryl group. Also, in a case where Q represents a divalent linking group having at least one benzene ring or naphthalene ring, examples of the divalent linking group include a divalent group, in which at least one of the two hydrogen atoms of a methylene group is substituted with a phenyl group, a biphenylyl group, or a naphthyl group; a divalent aromatic group selected from the group consisting of a phenylene group, a biphenylylene group, and a naphthylene group; and a divalent group having the divalent aromatic group and a methylene group, an ether group (—O— group), or a sulfide group (—S— group). Examples of the monomer include compounds represented by the following Formulas (2-1) to (2-6).

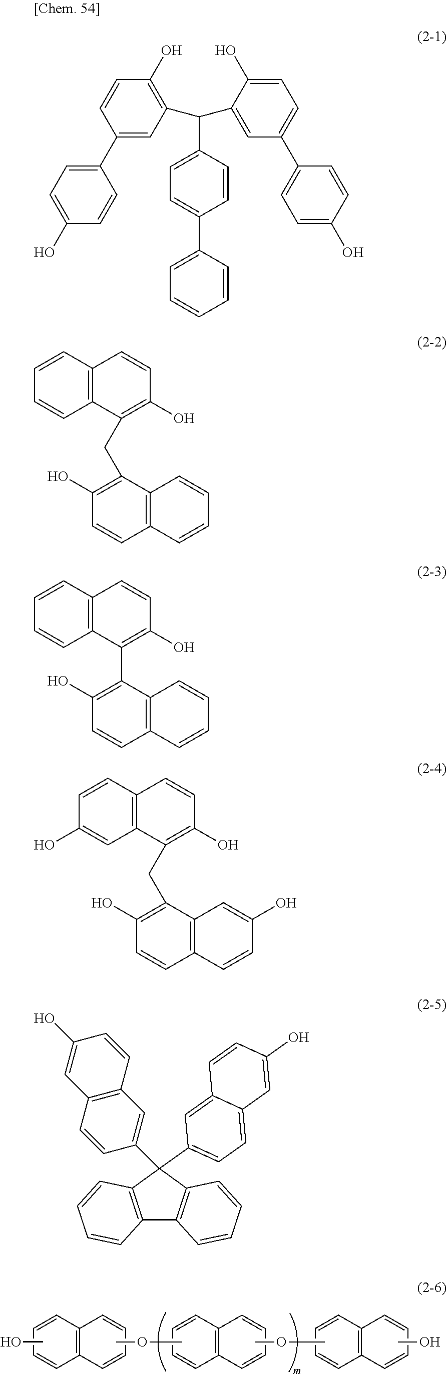

in Formula (2-6), m represents an integer of 0 to 3.

An example of a film material (s) capable of undergoing a crosslinking reaction includes a fullerene derivative, in which 1 to 6 molecules of malonic acid diester represented by the following Formula (1) are added to one fullerene molecule, as disclosed in WO 2011/108365 A1 and WO 2016/143436 A1:

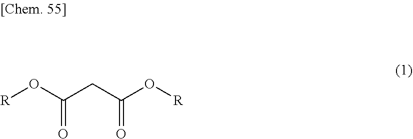

wherein, Rs each independently represent an alkyl group having 1 to 10 carbon atoms.

An example of a film material (t) capable of undergoing a crosslinking reaction includes a polyfunctional (meth)acrylate compound having a molecular weight of 300 to 10,000, which is in a liquid state at room temperature and atmospheric pressure, as disclosed in WO 2011/132640 A1.

Preferably, the compound is a compound having 2 to 20 (meth)acrylate groups in the molecule.

Preferably, the molecular weight of the compound is within the range of 300 to 2,300.

Examples of such a compound include the followings.

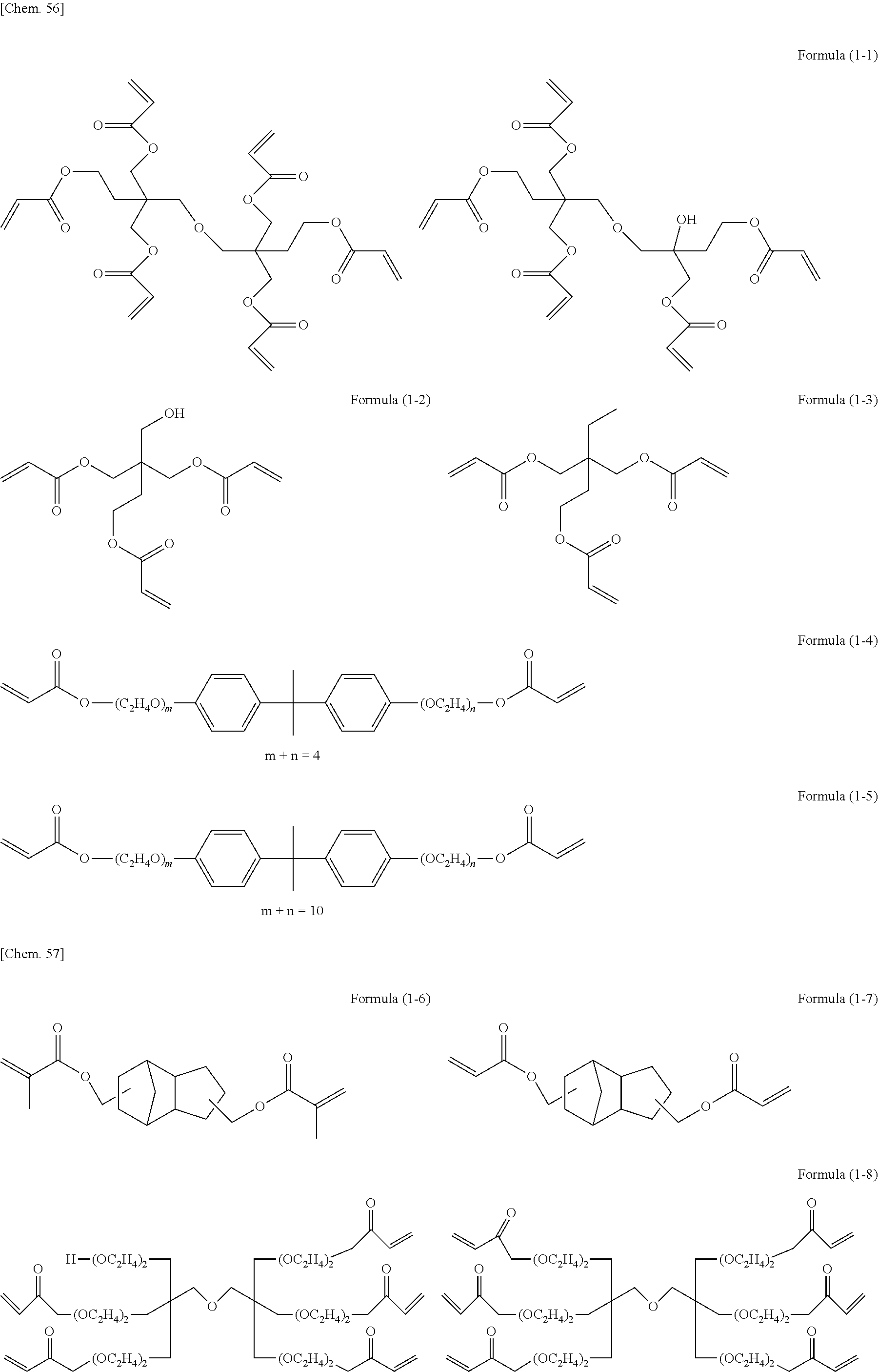

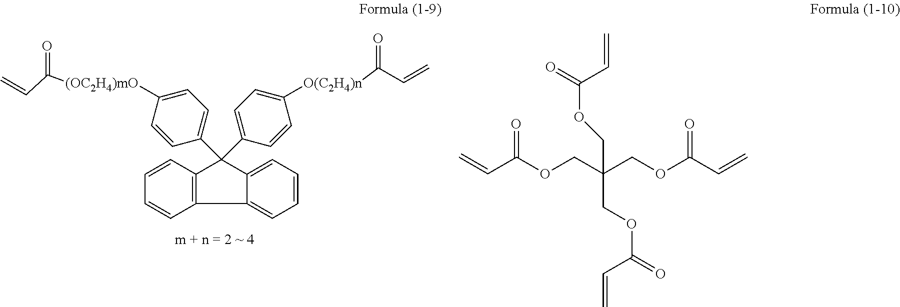

An example of a film material (u) capable of undergoing a crosslinking reaction includes a compound (E) having a partial structure (I) and a partial structure (II) as disclosed in WO 2017/154921 A1. The partial structure (II) has a hydroxy group generated by reacting an epoxy group with a proton-generating compound; the partial structure (I) is at least one partial structure selected from the group consisting of partial structures represented by the following Formulas (1-1) to (1-5), or a partial structure composed of a combination of a partial structure represented by Formula (1-6) and a partial structure represented by Formula (1-7) or (1-8); and the partial structure (II) is a partial structure represented by the following Formula (2-1) or (2-2).

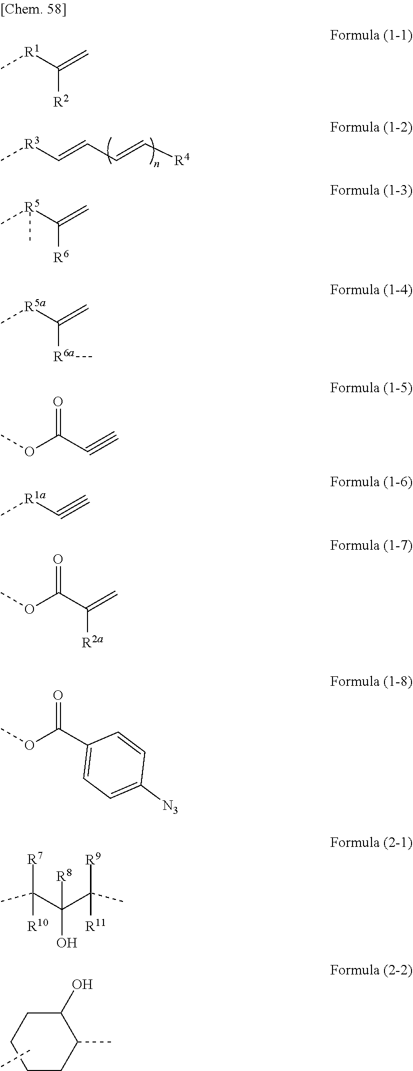

wherein, each of R¹, R^{1a}, R³, R⁵, R^{5a}, and R^{6a} represents a saturated hydrocarbon group having 1 to 10 carbon atoms, an aromatic hydrocarbon group having 6 to 40 carbon atoms, an oxygen atom, a carbonyl group, a sulfur atom, a nitrogen atom, an amide group, an amino group, or a group composed of a combination thereof; each of R², R^{2a}, R⁴, and R⁶ represents a hydrogen atom, a saturated hydrocarbon group having 1 to 10 carbon atoms, an unsaturated hydrocarbon group having 2 to 10 carbon atoms, an oxygen atom, a carbonyl group, an amide group, an amino group, or a group composed of a combination thereof; each of R², R^{2a}, R⁴, and R⁶ represents a monovalent group; each of R¹, R^{1a}, R³, R⁵, R^{5a}, and R^{6a} represents a divalent group; R⁵ represents a trivalent group; each of R⁷, R⁸, R⁹, R¹⁰, and R¹¹ represents a hydrogen atom or a saturated hydrocarbon group having 1 to 10 carbon atoms; n represents the number of repeating units of 1 to 10; and the dotted line represents a chemical bond to an adjacent atom.

Preferably, the compound (E) contains an epoxy group and a hydroxy group in a molar ratio, which meets 0≤(epoxy group)/(hydroxy group)≤0.5; and has a partial structure (II) in a molar ratio, which meets 0.01≤(partial structure (II))/(partial structure (I)+partial structure (II))≤0.8.

Preferably, the compound (E) is a compound having at least one partial structure (I) and at least one partial structure (II).

Preferably, each of R^{5a} and R^{6a} is an alkylene group having 1 to 10 carbon atoms, an arylene group having 6 to 40 carbon atoms, an oxygen atom, a carbonyl group, a sulfur atom, or a divalent group composed of a combination thereof.

Preferably, the compound (E) has the partial structure (I) and the partial structure (II) in a ratio of 1 to 1,000.

An example of a film material (v) capable of undergoing a crosslinking reaction includes a compound having at least one photodegradable nitrogen-containing structure and/or photodegradable sulfur-containing structure as well as a hydrocarbon structure, as disclosed in WO 2018/030198 A1.

Preferably, the compound is a compound having one or more photodegradable nitrogen-containing structures and/or photodegradable sulfur-containing structures in the molecule.

Preferably, the compound is a compound, in which a photodegradable nitrogen-containing nitrogen structure and/or a photodegradable sulfur-containing structure as well as a hydrocarbon structure are present in the same molecule, or a combination of different compounds, in which those structures are alotted in each of the molecules, respectively.

Preferably, the hydrocarbon structure is a saturated or unsaturated group having 1 to 40 carbon atoms and is a linear, branched, or cyclic hydrocarbon group.

Preferably, the photodegradable nitrogen-containing structure is a structure providing a reactive nitrogen-containing functional group or a reactive carbon functional group upon irradiated with ultraviolet rays, or a structure having a reactive nitrogen-containing functional group or a reactive carbon-containing functional group generated by irradiation of ultraviolet rays.

Preferably, the photodegradable nitrogen-containing structure is a photodegradable nitrogen-containing structure optionally containing a sulfur atom, which includes an azide structure, a tetrazole structure, a triazole structure, an imidazole structure, a pyrazole structure, an azole structure, a diazo structure, and a combination of these structures.

Preferably, the photodegradable sulfur-containing structure is a structure providing an organic sulfur radical or a carbon radical upon irradiated with ultraviolet rays, or a structure having an organic sulfur radical or a carbon radical generated by irradiation of ultraviolet rays.

Preferably, the photodegradable sulfur-containing structure is a photodegradable sulfur-containing structure optionally containing a nitrogen atom, which includes a trisulfide structure, a disulfide structure, a sulfide structure, a thioketone structure, a thiophene structure, a thiol structure, or a combination of these structures.

Preferably, examples of the film material (v) include the following compounds.

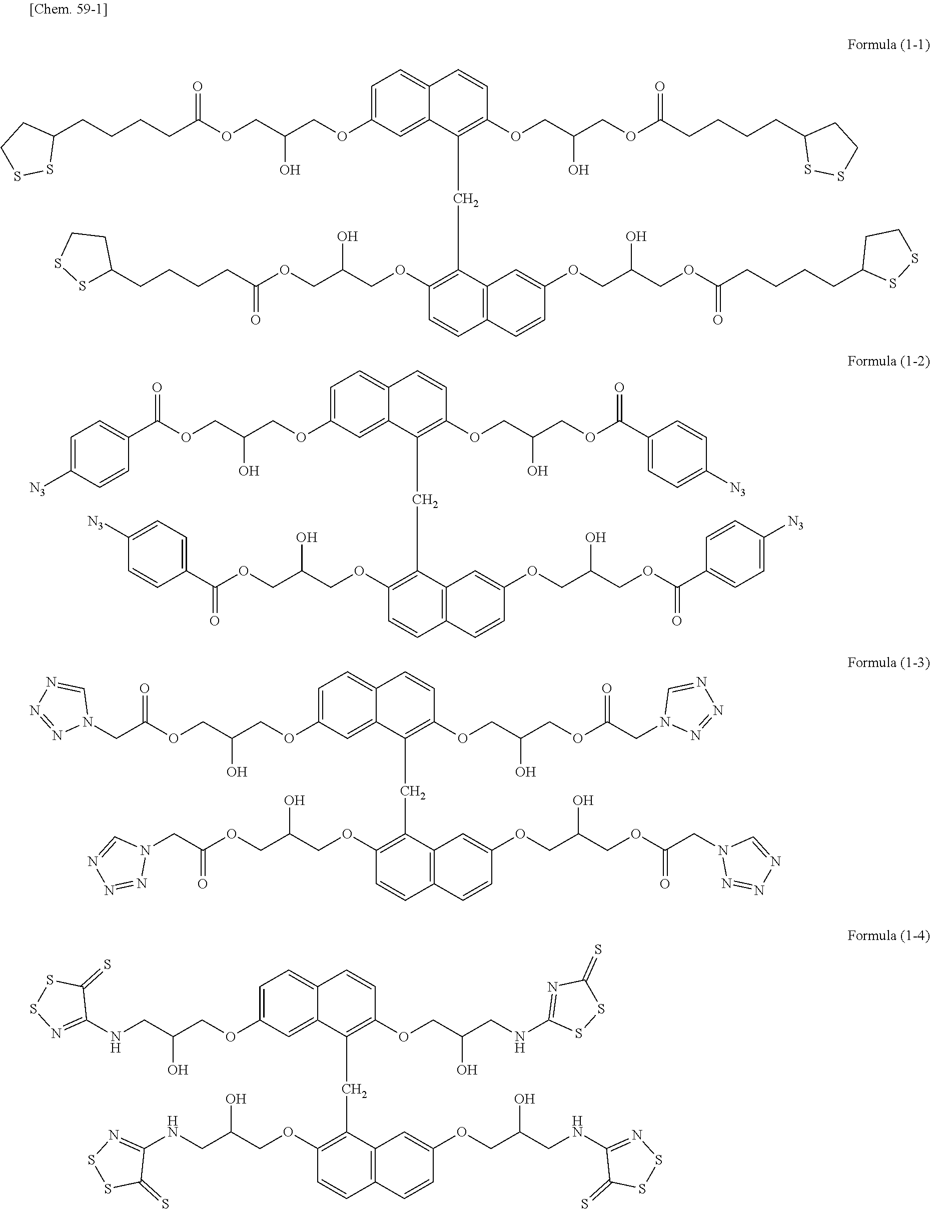

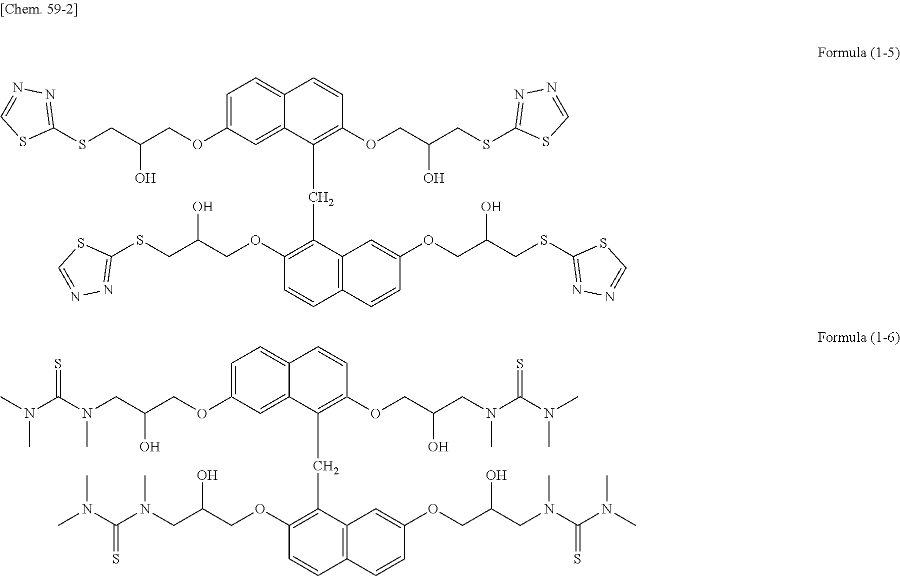

An example of a film material (w) capable of undergoing a crosslinking reaction includes a compound represented by the following Formula (1) as disclosed in WO 2019/013293 A1.

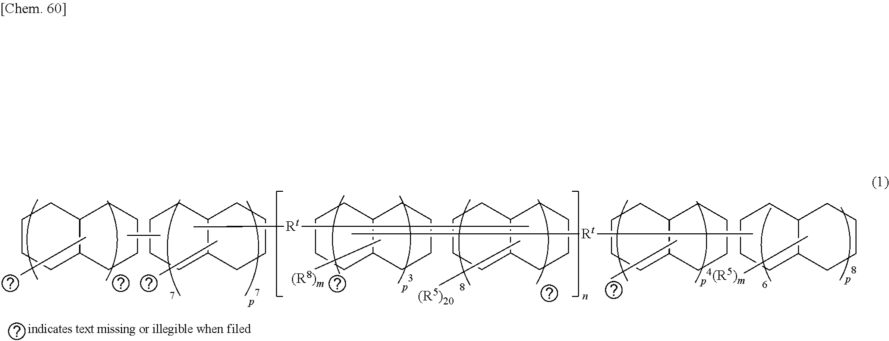

wherein, R¹s are each independently a divalent group having 1 to 30 carbon atoms; R² to R⁷ are each independently a linear, branched, or cyclic alkyl group having 1 to 10 carbon atoms, an aryl group having 6 to 10 carbon atoms, an alkenyl group having 2 to 10 carbon atoms, a thiol group, or a hydroxy group; at least one of R⁵s is a hydroxy group or a thiol group; m², m³, and m⁶ are each independently an integer of 0 to 9; m⁴ and m⁷ are each independently an integer of 0 to 8; m⁵ is an integer of 1 to 9; n is an integer of 0 to 4; and p² to p⁷ are each independently an integer of 0 to 2.

Preferably, examples of the film material (v) include the following compounds.

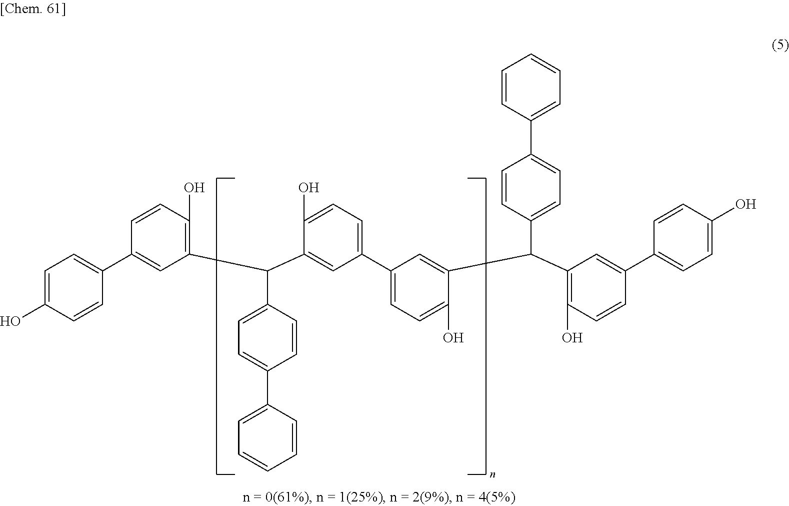

An example of a film material (x) capable of undergoing a crosslinking reaction includes a compound represented by the following General Formula (1) as disclosed in JP 2016-216367 A.

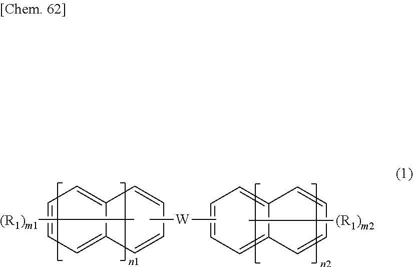

wherein, n1 and n2 each independently represent 0 or 1; W is a single bond or a structure represented by the following Formula (2); R₁ is a structure represented by the following General Formula (3); m1 and m2 each independently represent an integer of 0 to 7; and m1+m2 is 1 or more and 14 or less,

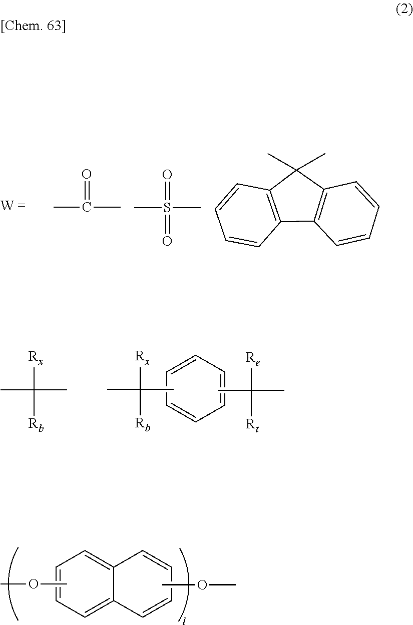

wherein, 1 represents an integer of 0 to 3; Rₐ to R_{f} each independently represent a hydrogen atom, or an alkyl group having 1 to 10 carbon atoms, a phenyl group, or a phenylethyl group which may be substituted with fluorine; and Rₐ and R_{b} may be bonded to form a cyclic compound,

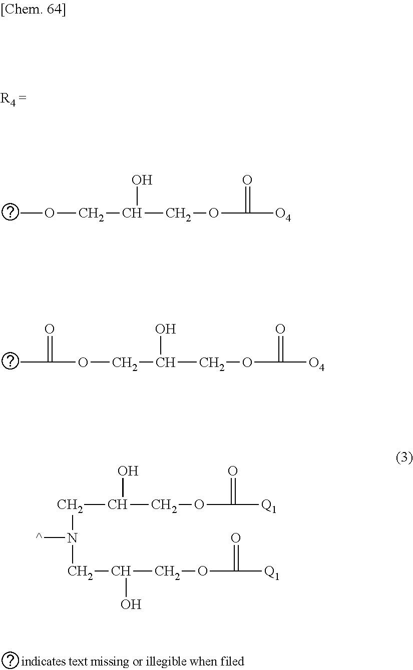

wherein, * represents a bonding site to an aromatic ring; Q₁ represents a linear or branched and saturated or unsaturated hydrocarbon group having 1 to 30 carbon atoms, an alicyclic group having 4 to 20 carbon atoms, or a substituted or unsubstituted phenyl group, naphthyl group, anthracenyl group, or pyrenyl group; and, in a case where Q₁ represents a linear or branched and saturated or unsaturated hydrocarbon group having 1 to 30 carbon atoms, a methylene group constituting Q₁ may be substituted with an oxygen atom or a carbonyl group.

Preferably, the compound represented by General Formula (1) is a compound represented by the following General Formula (4).

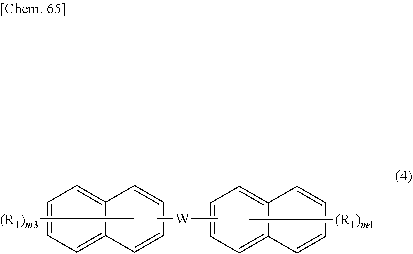

wherein, each of m3 and m4 represents 1 or 2; and W and R₁ are as defined above.

Preferably, W is a single bond or a structure represented by the following Formula (5).

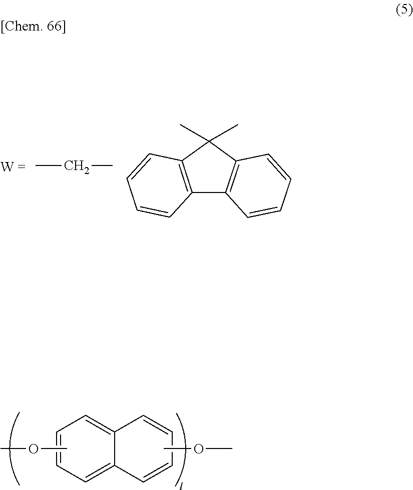

wherein, 1 is as defined above.

Preferably, the compound represented by General Formula (1) has two or more Q₁s in the molecule, and contains as Q₁ each of one or more structures represented by the following General Formula (6) and one or more structures represented by the following General Formula (7).

[Chem.67]

**—Rₕ (6)

wherein, ** represents a bonding site to a carbonyl group; Rₕ represents a linear or branched and saturated or unsaturated hydrocarbon group having 1 to 30 carbon atoms; and a methylene group constituting Rₕ may be substituted with an oxygen atom or a carbonyl group,

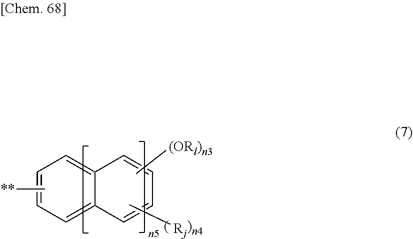

wherein, ** represents a bonding site to a carbonyl group; Rᵢ represents a hydrogen atom or a linear or branched hydrocarbon group having 1 to 10 carbon atoms; Rⱼ represents a linear or branched hydrocarbon group having 1 to 10 carbon atoms, a halogen atom, a nitro group, an amino group, a nitrile group, an alkoxycarbonyl group having 1 to 10 carbon atoms, or an alkanoyloxy group having 1 to 10 carbon atoms; each of n3 and n4 represents the number of substituents in the aromatic ring, and represents an integer of 0 to 7; n3+n4 is 0 or more and 7 or less; and n5 represents 0 to 2.

An example of a film material (y) capable of undergoing a crosslinking reaction includes a compound represented by the following General Formula (1A) as disclosed in JP 2017-119670 A.

[Chem.69]

R [symbol] R₁)₍ₘ₁₊ₘ₂₎ (1A)

wherein, in a case where R is a single bond, an organic group having 1 to 50 carbon atoms, an ether bond, a —SO— group, or a —SO₂— group, R₁ is a group represented by the following General Formula (1B); and each of m1 and m2 is an integer satisfying 1≤m1≤5, 1≤m2≤5, and 2≤m1+m2≤8;

[Chem.70]

—R₁=—X¹—X (1 B)

wherein, X¹ is a group represented by the following General Formula (1C); and X is a group represented by the following General Formula (1D),

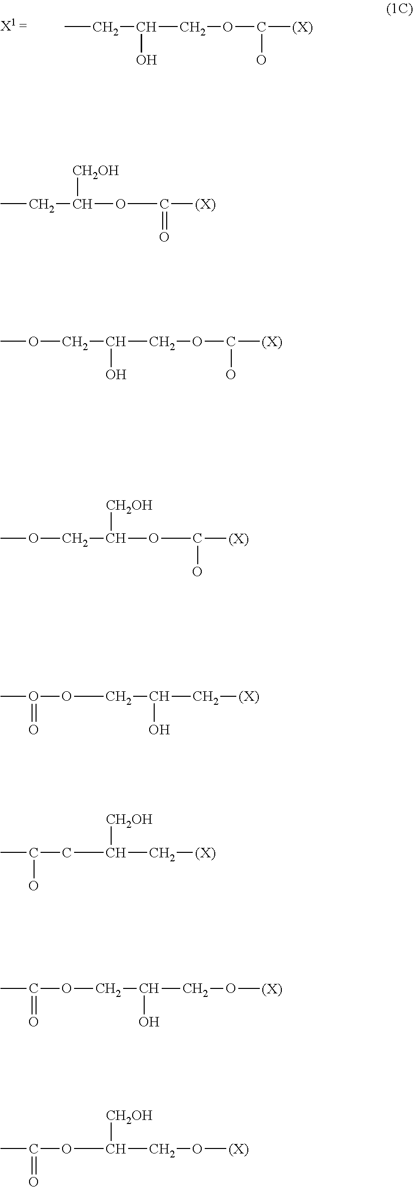

wherein, (X) represents a bonding site to X;

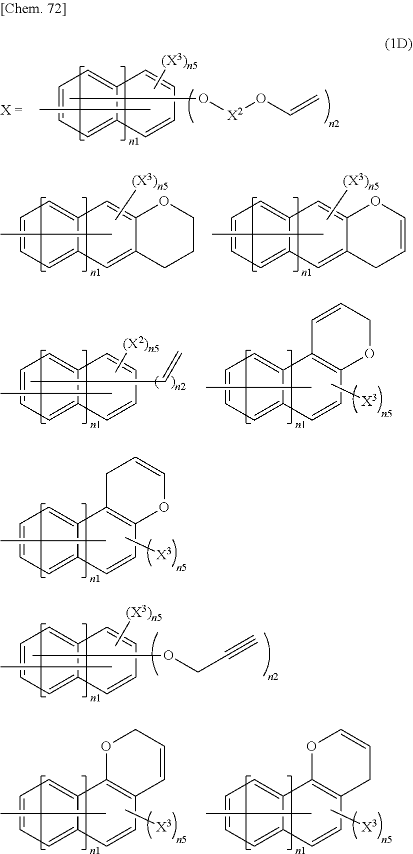

wherein, X² is a divalent organic group having 1 to 10 carbon atoms; n1 is 0 or 1; n2 is 1 or 2; X³ is a group represented by the following General Formula (1E); and n5 is 0, 1, or 2;

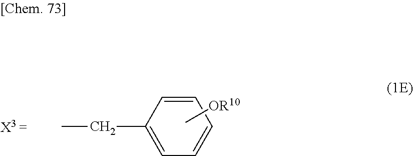

wherein, R¹⁰ is a hydrogen atom or a saturated or unsaturated hydrocarbon group having 1 to 10 carbon atoms, and the hydrogen atom in the benzene ring in the formula may be replaced by a methyl group or a methoxy group,

Preferably, the molecular weight of the compound is 2,500 or less.

Preferably, the compound is a compound represented by the following General Formula (2A) or a compound represented by the following General Formula (3A).

[Chem.74]

R [symbol] R₂)₍ₘ₃₊ₘ₄₎ (2 A)

wherein, in a case where R is a single bond, an organic group having 1 to 50 carbon atoms, an ether bond, a —SO— group, or a —SO₂— group, R₂ is a group represented by the following General Formula (2B); and each of m3 and m4 is an integer satisfying 1≤m3≤5, 1≤m4≤5, and 2≤m3+m4≤8;

[Chem.75]

—R₂=—X¹¹—X′ (2 B)

wherein, X¹¹ is a group represented by the following General Formula (2C); and X′ is a group represented by the following General Formula (2D),

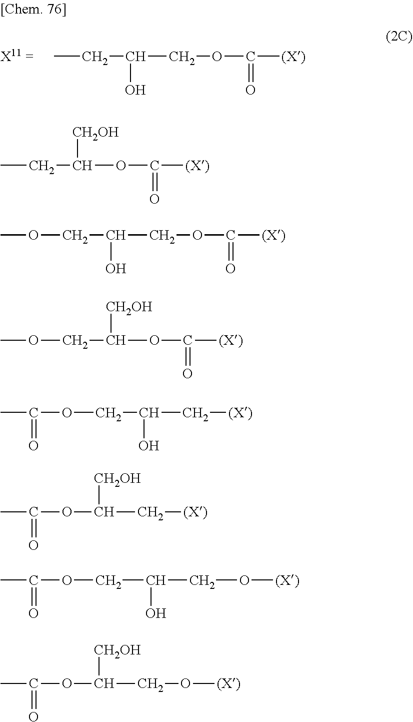

wherein, (X′) represents a bonding site to X′,

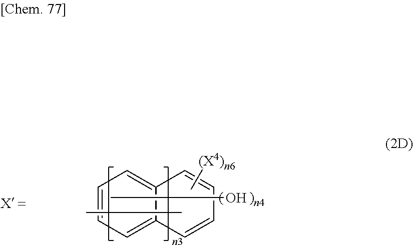

wherein, n3 is 0 or 1; n4 is 1 or 2; X⁴ is a group represented by the following General Formula (2E); and n6 is 0, 1, or 2;

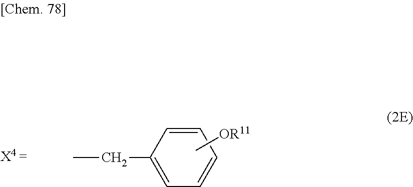

wherein, R¹¹ is a hydrogen atom or a saturated or unsaturated hydrocarbon group having 1 to 10 carbon atoms, and the hydrogen atom in the benzene ring in the formula may be substituted with a methyl group or a methoxy group,

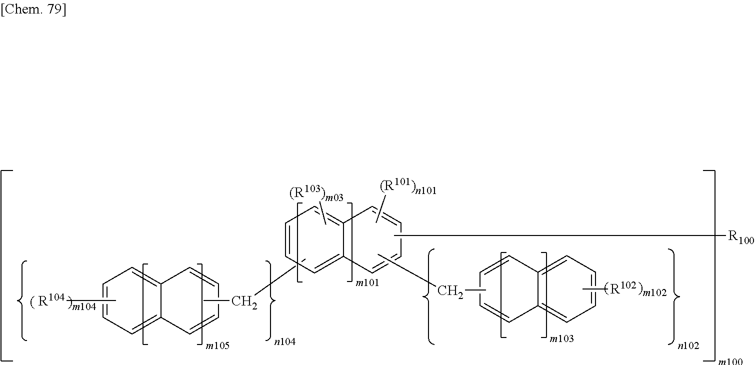

wherein, R¹⁰¹, R¹⁰², R¹⁰³ and R¹⁰⁴ are each independently a hydroxy group; m100 is 1, 2, or 3; R¹⁰⁰ is a hydrogen atom or a hydroxy group, when m100 is 1; R¹⁰⁰ is a single bond or a group represented by the following General Formula (3B), when m100 is 2; R¹⁰⁰ is a group represented by the following General Formula (3C), when m100 is 3; and the hydrogen atom in the aromatic ring in the formula may be replaced by a methyl group or a methoxy group; m101 is 0 or 1; m102 is 1 or 2; m103 is 0 or 1; m104 is 1 or 2; and m105 is 0 or 1; when m101 is 0, each of n101 and n102 is an integer satisfying 0≤n101≤3, 0≤n102≤3, and 1≤n101+n102≤4; and when m101 is 1, each of n101, n102, n103, and n104 is an integer satisfying 0≤n101≤2, 0≤n102≤2, ≤n103≤2, 0≤n104≤2, and 2≤n101+n102+n103+n104≤8;

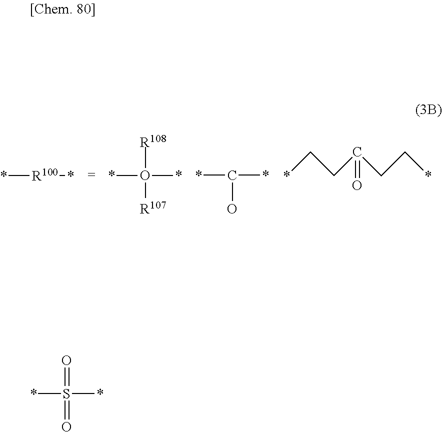

wherein, * represents a bonding site; each of R¹⁰⁶ and R¹⁰⁷ is a hydrogen atom or an organic group having 1 to 24 carbon atoms and containing no ester bond; and R′° 6 and R¹⁰⁷ may be bonded to form a cyclic structure,

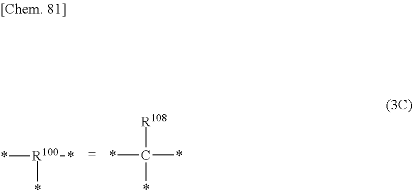

wherein, * represents a bonding site; and R¹⁰⁸ is a hydrogen atom or an organic group having 1 to 15 carbon atoms.

An example of a polyether film material (z) includes a polymer represented by the following General Formula (1) as disclosed in WO 2012/050064.

The polyether film material is a polymer having a unit structure represented by the following Formula (1):

[Chem.82]

[symbol]

O—Ar₁ [symbol] Formula (1)

wherein, Ar₁ represents an organic group having 6 to 50 carbon atoms and containing an arylene group or a heterocyclic group, a unit structure represented by the following Formula (2):

[Chem.83]

[symbol]

O—Ar₂—O—Ar₃−T−Ar₄ [symbol] Formula (2)

wherein, each of Ar₂, Ar₃, and Ar₄ represents an organic group having 6 to 50 carbon atoms and containing an arylene group or a heterocyclic group; and T represents a carbonyl group or a sulfonyl group; or a combination of a unit structure represented by Formula (1) and a unit structure represented by Formula (2).

The film material (Y) capable of undergoing a crosslinking reaction preferably includes at least one member selected from the group consisting of a film material (Y1) containing an aliphatic ring (for example, (a) and (m)), a novolac film material (Y2) (for example, (b), (c), (d), (e), (f), (g), (h), (i), (j), (k), and (1)), a polyether film material (Y3) (for example, (z)), a polyester film material (Y4) (for example, (o) and (p)), a compound (Y5) different from the crosslinkable compound (A) (for example, (m), (n), (r), (s), (t), (u), (v), (w), (x), and (y)), a film material containing an aromatic fused ring (Y6) (for example, (q)), an acrylic resin (Y7), and a methacrylic resin (Y8).

In a case where the resist underlayer film-forming composition according to the present invention contains a film material (Y) capable of undergoing a crosslinking reaction (a film material or a polymer), the content ratio of the film material (Y) capable of undergoing a crosslinking reaction is generally within the range of 1 to 99.9% by mass, preferably 50 to 99.9% by mass, more preferably 50 to 95% by mass, and still more preferably 50 to 90% by mass, with respect to the total solid content.

A light absorber, a rheology modifier, an adhesion assistant, or the like may be further added to the resist underlayer film-forming composition of the present invention. The rheology modifier is effective in improving the fluidity of the underlayer film-forming composition. The adhesion assistant is effective in improving the adhesion between the underlayer film and the semiconductor substrate or the resist.

(Light Absorber)

As the light absorber, commercially available light absorbers described in “Technique and Market of Industrial Pigments” (CMC Publishing Co., Ltd.) or “Dye Handbook” (edited by The Society of Synthetic Organic Chemistry, Japan), such as C. I. Disperse Yellow 1, 3, 4, 5, 7, 8, 13, 23, 31, 49, 50, 51, 54, 60, 64, 66, 68, 79, 82, 88, 90, 93, 102, 114 and 124; C. I. Disperse Orange 1, 5, 13, 25, 29, 30, 31, 44, 57, 72 and 73; C. I. Disperse Red 1, 5, 7, 13, 17, 19, 43, 50, 54, 58, 65, 72, 73, 88, 117, 137, 143, 199 and 210; C. I. Disperse Violet 43; C. I. Disperse Blue 96; C. I. Fluorescent Brightening Agent 112, 135 and 163; C. I. Solvent Orange 2 and 45; C. I. Solvent Red 1, 3, 8, 23, 24, 25, 27 and 49; C. I. Pigment Green 10; and C. I. Pigment Brown 2, may be suitably used. The light absorber is usually blended in a ratio of 10% by mass or less, and preferably 5% by mass or less, with respect to the total solid content of the resist underlayer film-forming composition.

(Rheology Modifier)

The rheology modifier is added mainly to improve the fluidity of the resist underlayer film-forming composition, and in particular, to improve the thickness uniformity of the resist underlayer film or to enhance filling property of the resist underlayer film-forming composition into holes during the baking step. Specific examples thereof include phthalic acid derivatives such as dimethyl phthalate, diethyl phthalate, diisobutyl phthalate, dihexyl phthalate, and butylisodecyl phthalate; adipic acid derivatives such as di-n-butyl adipate, diisobutyl adipate, diisooctyl adipate, and octyldecyl adipate; maleic acid derivatives such as di-n-butyl maleate, diethyl maleate, and dinonyl maleate; oleic acid derivatives such as methyl oleate, butyl oleate, and tetrahydrofurfuryl oleate; and stearic acid derivatives such as n-butyl stearate and glyceryl stearate. These rheology modifiers are usually blended in a ratio of less than 30% by mass with respect to the total solid content of the resist underlayer film-forming composition.

(Adhesion Assistant) The adhesion assistant is mainly added to improve the adhesion of the resist underlayer film-forming composition to a substrate or a resist, and in particular, to prevent peeling off of the resist during development. Specific examples thereof include chlorosilanes such as trimethylchlorosilane, dimethylmethylolchlorosilane, methyldiphenylchlorosilane, and chloromethyldimethylchlorosilane; alkoxysilanes such as trimethylmethoxysilane, dimethyldiethoxysilane, methyldimethoxysilane, dimethylmethylolethoxysilane, diphenyldimethoxysilane, and phenyltriethoxylsilane; silazanes such as hexamethyldisilazane, N,N′-bis(trimethylsilyl)urea, dimethyltrimethylsilylamine, and trimethylsilylimidazole; silanes such as methyloltrichlorosilane, γ-chloropropyltrimethoxysilane, γ-aminopropyltriethoxysilane, and γ-glycidoxypropyltrimethoxysilane; heterocyclic compounds such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine; and urea such as 1,1-dimethyl urea or 1,3-dimethyl urea or thiourea compounds. These adhesion assistants are usually blended in a ratio of less than 5% by mass, and preferably less than 2% by mass, with respect to the total solid content of the resist underlayer film-forming composition.

The solid content of the resist underlayer film-forming composition according to the present invention is usually within the range of 0.1 to 70% by mass and preferably 0.1 to 60% by mass. The solid content is a content ratio of all components excluding the solvent from the resist underlayer film-forming composition. The ratio of the polymer in the solid content is preferably in the order of 1 to 100% by mass, 1 to 99.9% by mass, 50 to 99.9% by mass, 50 to 95% by mass, and 50 to 90% by mass.

One of the measures for evaluating whether the resist underlayer film-forming composition is in a uniform solution state is to observe the passing property through a specific microfilter, and the resist underlayer film-forming composition according to the present invention passes through a microfilter having a pore size of 0.1 μm and exhibits a uniform solution state.

Examples of the material of the microfilter include fluorine-based resins such as polytetrafluoroethylene (PTFE) and a tetrafluoroethylene-perfluoroalkyl vinyl ether copolymer (PFA), polyethylene (PE), ultra high molecular weight polyethylene (UPE), polypropylene (PP), polysulfone (PSF), polyether sulfone (PES), and nylon; and a microfilter formed of polytetrafluoroethylene (PTFE) is preferred.

[Resist Underlayer Film]

A resist underlayer film may be formed as follows using the resist underlayer film-forming composition according to the present invention.

A resist underlayer film is formed by applying the resist underlayer film-forming composition of the present invention onto a substrate (for example, a silicon wafer substrate, a silicon/silicon dioxide coated substrate, a silicon nitride substrate, a glass substrate, an ITO substrate, a polyimide substrate, a low dielectric constant material (low-k material) coated substrate, or the like) used for the manufacture of a semiconductor device, and then baking the resist underlayer film-forming composition using a heating means such as a hot plate. The baking conditions are appropriately selected from a baking temperature of 80° C. to 600° C. and a baking time of 0.3 to 60 minutes. Preferably, the baking temperature is 150° C. to 350° C. and the baking time is 0.5 to 2 minutes. As the atmospheric gas during baking, air may be used, and an inert gas such as nitrogen or argon may also be used. Here, the thickness of the underlayer film to be formed is, for example, within the range of 10 to 1,000 nm, 20 to 500 nm, 30 to 400 nm, or 50 to 300 nm. Also, use of a quartz substrate as a substrate permits manufacture of a replica (mold replica) of a quartz imprint mold.

Also, an adhesive layer and/or a silicone layer containing 99% by mass or less or 50% by mass or less of Si may be formed on the resist underlayer film according to the present invention by coating or vapor deposition. For example, a Si-based inorganic material film may be formed by a CVD method or the like in addition to a method of forming an adhesive layer described in JP 2013-202982 A or JP 5827180 B2 and a silicon-containing resist underlayer film (inorganic resist underlayer film) forming composition by spin coating described in WO 2009/104552 A1.

Also, the resist underlayer film-forming composition according to the present invention is applied onto a semiconductor substrate (so-called stepped substrate) having a portion having steps and a portion having no step, and the resist underlayer film-forming composition is baked, such that a resist underlayer film, in which the difference between the portion having steps and the portion having no step is within a range of 3 to 70 nm, may be formed.

[Method of Manufacturing Semiconductor Device]

A method of manufacturing a semiconductor device according to the present invention includes:

forming a resist underlayer film using the resist underlayer film-forming composition according to the present invention;

forming a resist film on the formed resist underlayer film;

irradiating the formed resist film with a light or electron beam and developing the resist film to form a resist pattern;

etching and patterning the resist underlayer film through the formed resist pattern; and

processing the semiconductor substrate through the patterned resist underlayer film.

Also, a method of manufacturing a semiconductor device according to the present invention includes:

forming a resist underlayer film using the resist underlayer film-forming composition according to the present invention;

forming a hard mask on the formed resist underlayer film;

forming a resist film on the formed hard mask;

irradiating the formed resist film with a light or electron beam and developing the resist film to form a resist pattern;

etching and patterning the hard mask through the formed resist pattern;

etching and patterning the resist underlayer film through the patterned hard mask; and

processing the semiconductor substrate through the patterned resist underlayer film.

The step of forming the resist underlayer film using the resist underlayer film-forming composition according to the present invention is as described above.

An organopolysiloxane film may be formed as a second resist underlayer film on the resist underlayer film formed in the above step, and a resist pattern may be formed thereon. The second resist underlayer film may be a SiON film or a SiN film formed by a vapor deposition method such as CVD or PVD. Furthermore, an anti-reflective film (BARC) may be formed on the second resist underlayer film as a third resist underlayer film, and the third resist underlayer film may be a resist shape correction film having no anti-reflection ability.

In the step of forming the resist pattern, exposure is performed through a mask (reticle) for forming a predetermined pattern or by direct drawing. As an exposure light source, for example, a g-ray, an i-ray, a KrF excimer laser, an ArF excimer laser, EUV, or an electron beam may be used. After the exposure, post exposure bake may be performed, if necessary. Thereafter, development is performed with a developer (for example, 2.38% by mass of a tetramethylammonium hydroxide aqueous solution), and rinsing is further performed with a rinse solution or pure water to remove the used developer. Thereafter, post-baking is performed to dry the resist pattern and enhance the adhesion to the base.

The etching performed after the forming of the resist pattern is performed by dry etching. Examples of an etching gas used in the dry etching include CHF₃, CF₄, and C₂F₆ for the second resist underlayer film (organopolysiloxane film), include O₂, N₂O, and NO₂ for the first resist underlayer film formed using the resist underlayer film-forming composition of the present invention, and include CHF₃, CF₄, and C₂F₆ for a surface having a stepped or concave portion and/or a convex portion. Furthermore, argon, nitrogen, or carbon dioxide may be mixed with these gases and used.

[Forming Resist Underlayer Film by Nanoimprint Method]

The forming of the resist underlayer film may be performed by a nanoimprint method. The method includes:

applying a curable composition onto the formed resist underlayer film;

bringing the curable composition into contact with a mold;

irradiating the curable composition with a light or electron beam to form a cured film; and

separating the cured film and the mold from each other.

In a releasing step of an optical nanoimprint technology, the adhesion between the resist composition and the substrate is important. This is because, in a case where the adhesion between the resist composition the and the substrate is low, a pattern peeling defect may occur, when the mold is separated in the releasing step, in which part of the photocured product obtained by curing the resist composition is peeled off, while adhering to the mold. As a technology for improving the adhesion between the resist composition and the substrate, a technology for forming an adhesive layer that is a layer for adhesion of the resist composition to the substrate between the resist composition and the substrate has been proposed.

Also, a high etching-resistant layer may be used for forming a pattern in nanoimprinting. As a material of the high etching-resistant layer, an organic-based material and a silicone-based material are generally used. In addition, an adhesive layer or a silicone layer containing Si may be formed on the resist underlayer film for nanoimprint by coating or vapor deposition. In a case where the adhesive layer or the silicone layer containing Si is hydrophobic and has a high pure water contact angle, the underlayer film should also be hydrophobic and have a high pure water contact angle, then it is expected that the adhesion between the films is enhanced, and peeling is less likely to occur. On the contrary, in a case where the adhesive layer or the silicone layer is hydrophilic and has a low pure water contact angle, the underlayer film should also be hydrophilic and have a low pure water contact angle, then it is expected that the adhesion between the films is enhanced, and peeling is unlikely to occur.

Also, He, H₂, N₂, air, or the like may be used according to the characteristics of the adhesive film, the silicone layer, and the underlayer film.

The polymer (X) according to the present invention has a desired pure water contact angle not only during low-temperature baking but also during high-temperature baking. It also has a desired pure water contact angle, when it is mixed with a crosslinking agent, an acid catalyst, and a surfactant to be formed into a material. Therefore, it becomes possible to enhance adhesion to an upperlayer film, and it is also expected that permeability to gases such as He, H₂, N₂, and air is exhibited. Moreover, the polymer (X) according to the present invention exhibits excellent flatness, and it may be adjusted to provide an optical constant or an etching rate suitable for the process by changing the molecular skeleton.

(Curable Composition)

The photoresist formed on the resist underlayer film is not particularly limited as long as it is sensitive to the light used for exposure. Either a negative photoresist or a positive photoresist may be used. Examples of the photoresist include a positive photoresist consisting of a novolac resin and 1,2-naphthoquinonediazide sulfonic acid ester; a chemically amplified photoresist formed of a binder having a group degradable by an acid to increase an alkali dissolution rate and a photoacid generator; a chemically amplified photoresist formed of a low-molecular-weight compound degradable by an acid to increase an alkali dissolution rate of the photoresist, an alkali-soluble binder, and a photoacid generator; and a chemically amplified photoresist formed of a binder having a group degradable by an acid to increase an alkali dissolution rate, a low-molecular-weight compound degradable by an acid to increase an alkali dissolution rate of the photoresist, and a photoacid generator. Examples thereof include APEX-E (trade name) manufactured by Shipley Company L.L.C, PAR710 (trade name) manufactured by Sumitomo Chemical Co., Ltd., and SEPR430 (trade name) manufactured by Shin-Etsu Chemical Co., Ltd. Also, an example thereof includes a fluorine-containing atomic polymer-based photoresist as described in Proc. SPIE, Vol. 3999, 330-334 (2000), Proc. SPIE, Vol. 3999, 357-364 (2000), or Proc. SPIE, Vol. 3999, 365-374 (2000).

(Applying Curable Composition)

The present step is applying a curable composition onto the resist underlayer film formed by a method of manufacturing a resist underlayer film according to the present invention. As a method of applying the curable composition, for example, an inkjet method, a dip coating method, an air knife coating method, a curtain coating method, a wire bar coating method, a gravure coating method, an extrusion coating method, a spin coating method, a slit scanning method, or the like may be used. An inkjet method is suitable for applying the curable composition as droplets, and a spin coating method is suitable for applying the curable composition. In the present step, an adhesive layer and/or a silicone layer containing 99% by mass or less or 50% by mass or less of Si may be formed on the resist underlayer film by application or vapor deposition, and the curable composition may be applied thereon.

(Bringing Curable Composition into Contact with Mold)

In the present step, the curable composition is brought into contact with a mold. For example, when the curable composition that is a liquid is brought into contact with a mold having a base pattern for transferring a pattern shape, a liquid film, in which a concave portion of a fine pattern formed on a surface of the mold is filled with the curable composition, is formed.

It is recommended to use a mold using a light transparent material as a substrate in consideration of irradiation with a light or electron beam described below. Specifically, the mold substrate is preferably glass, quartz, PMMA, a light transparent resin such as a polycarbonate resin, a transparent metal deposited film, a flexible film such as polydimethylsiloxane, a photocurable film, a metal film, or the like. The mold substrate is more preferably quartz, because quartz has a small expansion coefficient and small pattern distortion.

The fine pattern formed on the surface of the mold preferably has a pattern height of 4 nm or more and 200 nm or less. A certain pattern height is required to increase the processing accuracy of the substrate; however, the lower the pattern height, the lower a force to peel off the mold from the cured film in the separating of the mold from the cured film to be described below, and the number of defects, in which the resist pattern is torn off and remains on the mask side, is thus reduced. In consideration of these factors, it is recommended to select and adopt an appropriately balanced pattern height.

Also, adjacent resist patterns may come into contact with each other due to elastic deformation of the resist patterns due to impact when the mold is peeled off, and the resist patterns may be adhered or damaged. This can be avoided by setting the pattern height to about two times or less the pattern width (aspect ratio of 2 or less).

In order to improve the peeling properties between the curable composition and the surface of the mold, the mold may be subjected to a surface treatment in advance. An example of the method of the surface treatment includes a method of applying a release agent to the surface of the mold to form a release agent layer. Examples of the release agent include a silicone-based release agent, a fluorine-based release agent, a hydrocarbon-based release agent, a polyethylene-based release agent, a polypropylene-based release agent, a paraffin-based release agent, a montan-based release agent, and a carnuba-based release agent. The release agent is preferably a fluorine-based release agent or a hydrocarbon-based release agent. An example of a commercially available product includes OPTOOL (registered trademark) DSX manufactured by Daikin Industries, Ltd. The release agents may be used each alone or in combination of two or more thereof.

In the present step, a pressure applied to the curable composition at the time of bringing the curable composition into contact with the mold is not particularly limited. A pressure of 0 MPa or more and 100 MPa or less is recommended. The pressure is preferably 0 MPa or more and 50 MPa or less, 30 MPa or less, or 20 MPa or less.

In a case where the pre-spread of droplets of the curable composition has proceeded in the pre-step (the applying of the curable composition), the spread of the curable composition in the present step is quickly completed. As a result, the time for bringing the curable composition into contact with the mold can be shortened. The contact time is not particularly limited, and is preferably 0.1 seconds or longer and 600 seconds or shorter, 3 seconds or shorter, or 1 second or shorter. When the contact time is too short, the spread and filling are insufficient, and a defect called unfilled defect may occur.

The present step may be performed under any conditions of an air atmosphere, a reduced pressure atmosphere, and an inert gas atmosphere; and it is preferably performed under a pressure of 0.0001 atm or more and 10 atm or less. In order to prevent the influence of oxygen or moisture on the curing reaction, it is recommended to perform the treatment under a reduced pressure atmosphere or an inert gas atmosphere. Specific examples of the inert gas that may be used to form an inert gas atmosphere include nitrogen, carbon dioxide, helium, argon, CFC, HCFC, HFC, and a mixed gas thereof.

The present step may be performed under an atmosphere containing a condensable gas (hereinafter, referred to as a “condensable gas atmosphere”). In the present description, the condensable gas refers to a gas that condenses and liquefies by capillary pressure generated at the time of filling when the curable composition is filled together with the curable composition in the concave portion of the fine pattern formed on the mold and a gap between the mold and the substrate. Note that the condensable gas is present as a gas in the atmosphere before the curable composition is brought into contact with the mold in the present step. When the present step is performed under a condensable gas atmosphere, the gas filled in the concave portion of the fine pattern is liquefied by the capillary pressure generated by the curable composition, such that air bubbles are eliminated, and thus, the filling properties are excellent. The condensable gas may be dissolved in the curable composition.

A boiling point of the condensable gas is not limited as long as it is equal to or lower than the atmospheric temperature in the present step, and is preferably −10° C. or higher or +10° C. or higher and +23° C. or lower.

The vapor pressure of the condensable gas at the atmospheric temperature in the present step is not particularly limited as long as it is equal to or lower than the mold pressure. The vapor pressure of the condensable gas is preferably within the range of 0.1 MPa to 0.4 MPa.

Specific examples of the condensable gas include chlorofluorocarbon (CFC) such as trichlorofluoromethane; hydrofluorocarbon (HFC) such as fluorocarbon (FC), hydrochlorofluorocarbon (HCFC), or 1,1,1,3,3-pentafluoropropane (CHF₂CH₂CF₃, HFC-245fa, or PFP); and hydrofluoroether (HFE) such as pentafluoroethyl methyl ether (CF₃CF₂OCH₃ or HFE-245mc).

The condensable gases may be used each alone or as a mixture of two or more thereof. Also, these condensable gases may be used by being mixed with a non-condensable gas such as air, nitrogen, carbon dioxide, helium, or argon. The non-condensable gas mixed with the condensable gas is preferably air or helium.

(Irradiating Curable Composition with Light or Electron Beam to Form Cured Film)

In the present step, the curable composition is irradiated with a light or electron beam to form a cured film. That is, the curable composition filled in the fine pattern of the mold is irradiated with a light or electron beam through the mold, and the curable composition filled in the fine pattern of the mold is cured as it is to form a cured film having a pattern shape.

The light or electron beam is selected according to the sensitive wavelength of the curable composition. Specifically, ultraviolet light having a wavelength of 150 nm or more and 400 nm or less, an X-ray, an electron beam, and the like may be appropriately selected and used. Examples of the light source of the light or electron beam include a high-pressure mercury lamp, an ultra-high-pressure mercury lamp, a low-pressure mercury lamp, a deep-UV lamp, a carbon arc lamp, a chemical lamp, a metal halide lamp, a xenon lamp, a KrF excimer laser, an ArF excimer laser, and an F2 excimer laser. The number of light sources may be one or more. The irradiation may be performed on the entire curable composition filled in the fine pattern of the mold, or may be performed on a partial region. The irradiation with a light may be intermittently performed on the entire region on the substrate more than once, or may be continuously performed on the entire region. Also, the first irradiation may be performed on a partial region on the substrate, and the second irradiation may be performed on the region different from the partial region.

The cured film obtained as described above preferably has a pattern having a size of 1 nm or more or 10 nm or more and 10 mm or less or 100 μm or less.

(Separating Cured Film and Mold)

In the present step, the cured film and the mold are separated. The cured film having a pattern shape and the mold are separated, and the cured film having a pattern shape that is an inverted pattern of the fine pattern formed on the mold is obtained in a self-standing state.

A method of separating the cured film having a pattern shape and the mold is not particularly limited as long as the method is a means for moving the cured film and the mold in a direction, in which the cured film and the mold are relatively separated and a part of the cured film having a pattern shape is not physically damaged, and various conditions and the like are also not particularly limited. For example, the substrate may be fixed and the mold may be moved away from the substrate to be peeled off, or the mold may be fixed and the substrate may be moved away from the mold to be peeled off. Alternatively, the substrate and the mold may be pulled and moved in opposite directions to be peeled off.

Note that in a case where the bringing of the curable composition into contact with the mold is performed under a condensable gas atmosphere, when the cured film and the mold are separated in the present step, the condensable gas vaporizes as the pressure at the interface at which the cured film and the mold come into contact with each other is decreased. Therefore, it is possible to reduce a release force that is a force required to separate the cured film and the mold.

By the above steps, a cured film having a desired irregularity pattern shape derived from the convex and concave shape of the mold at a desired position may be produced.

### EXAMPLES

Hereinafter, specific examples of the composition according to the present invention will be described using the following Examples and the like, but the present invention is not limited thereto.

An apparatus and the like used for measuring the weight average molecular weight of a reaction product obtained in each of the following Synthesis Examples are as follows.

Apparatus: HLC-8320 GPC, manufactured by Tosoh Corporation

GPC column: TSKgel Super-Multipore HZ—N(two columns)

Column temperature: 40° C.

Flow rate: 0.35 m1/min

Eluent: THF

Standard sample: polystyrene

The chemical structures (examples) and abbreviations of the typical starting materials used are as follows.

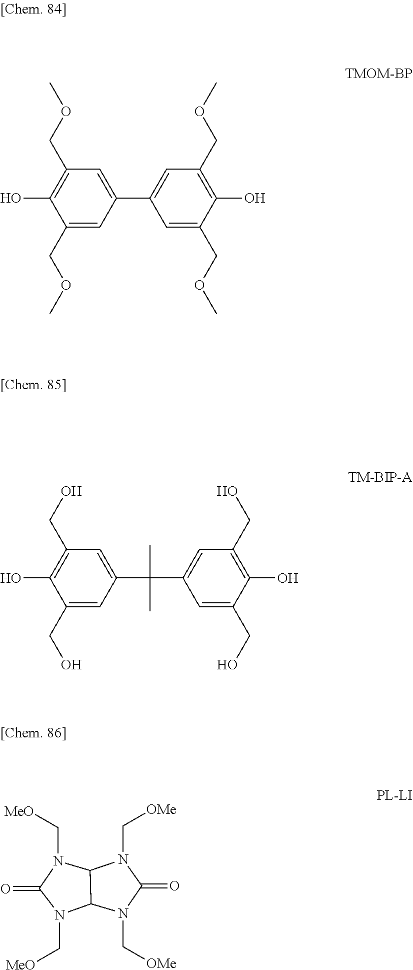 [SMILES: COCc1cc(-c2cc(COC)c(O)c(COC)c2)cc(COC)c1O ; CC(C)(c1cc(CO)c(O)c(CO)c1)c1cc(CO)c(O)c(CO)c1 ; COCN1C(=O)N(COC)C2C1N(COC)C(=O)N2COC]

### Synthesis Example 1

A flask was charged with 260.00 g of TMOM-BP (manufactured by Honshu Chemical Industry Co., Ltd.) and 1,430 g of propylene glycol monomethyl ether (hereinafter, referred to as PGME). Thereafter, the resultant mixture was heated under nitrogen to about 90° C., and 17.26 g of methanesulfonic acid (manufactured by Tokyo Chemical Industry Co., Ltd.) dissolved in 130.00 g of PGME was added thereto dropwise. After about 45 hours, the mixture was precipitated with methanol and water, and the mixture was dried, thereby obtaining a polymer (1-1). Note that, in an actual structural unit, some of the ROCH₂— groups including a methoxymethyl group are bonded to a hydroxy group to form a crosslink, and the other ROCH₂— groups are bonded to each other to form a crosslink; however, it would be extremely complicated to express this state by a chemical formula, and thus, only the structural unit is shown. The same applies hereinafter. The weight average molecular weight Mw measured in terms of polystyrene by GPC was about 4,500. Also, introduction of PGME into the polymer was confirmed by ¹H-NMR. The obtained resin was dissolved in PGMEA, and ion exchange treatment was performed using a cation exchange resin and an anion exchange resin for 4 hours, thereby obtaining the target polymer solution.

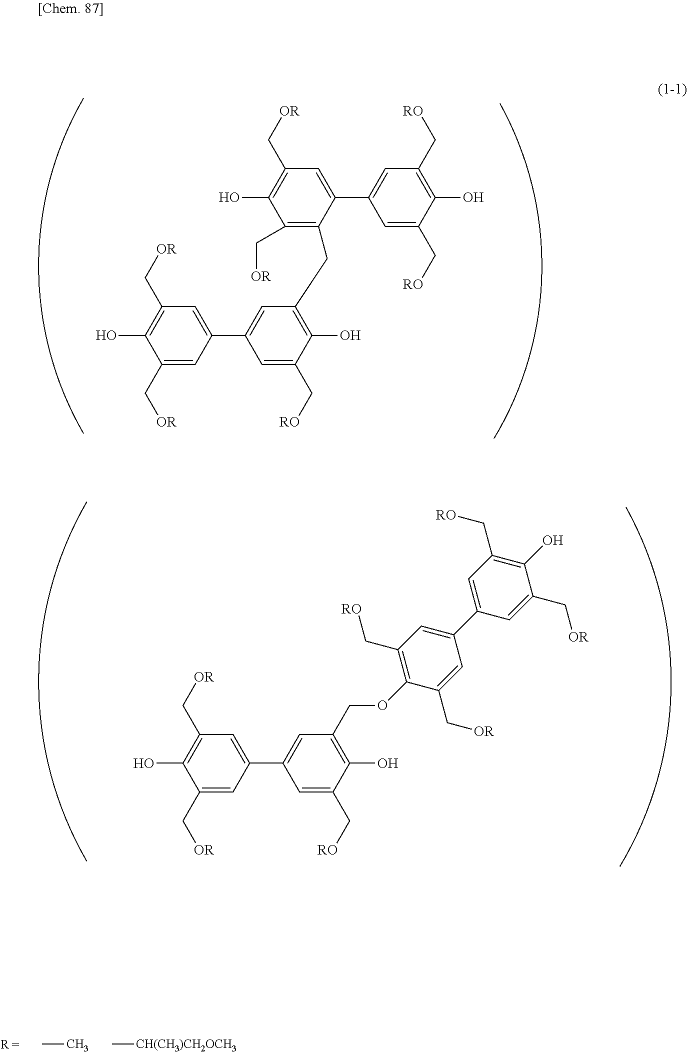

### Synthesis Example 2

A flask was charged with 68.99 g of TMOM-BP (manufactured by Honshu Chemical Industry Co., Ltd.) and 379.44 g of PGME. Thereafter, the resultant mixture was heated under nitrogen to about 90° C., 4.57 g of methanesulfonic acid (manufactured by Tokyo Chemical Industry Co., Ltd.) dissolved in 34.50 g of PGME was added thereto dropwise. After about 47.5 hours, the mixture was precipitated with methanol and water, and the mixture was dried, thereby obtaining a polymer (1-2). The weight average molecular weight Mw measured in terms of polystyrene by GPC was 5,400. Also, introduction of PGME into the polymer was confirmed by ¹H-NMR. The obtained resin was dissolved in PGMEA, and ion exchange treatment was performed using a cation exchange resin and an anion exchange resin for 4 hours, thereby obtaining the target polymer solution.

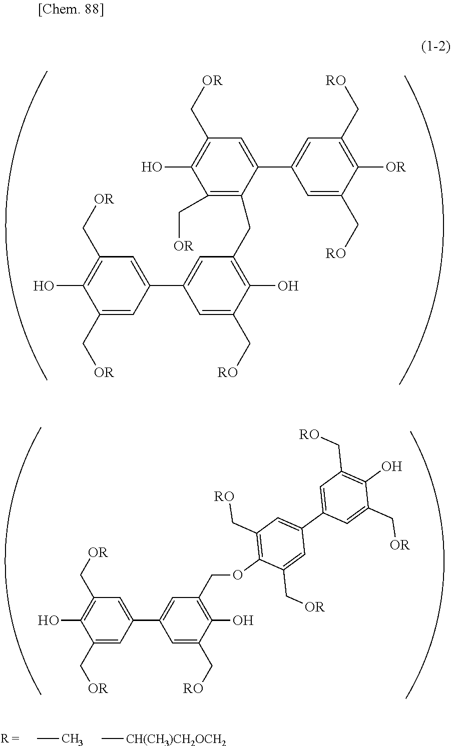

### Synthesis Example 3

A flask was charged with 30.00 g of TMOM-BP (manufactured by Honshu Chemical Industry Co., Ltd.) and 165.07 g of 1-butanol (manufactured by Tokyo Chemical Industry Co., Ltd.). Thereafter, the resultant mixture was heated under nitrogen to about 90° C., 1.99 g of methanesulfonic acid (manufactured by Tokyo Chemical Industry Co., Ltd.) dissolved in 15.05 g of 1-butanol was added thereto dropwise. After about 81.5 hours, the mixture was precipitated with methanol and water, and the mixture was dried, thereby obtaining a polymer (1-3). The weight average molecular weight Mw measured in terms of polystyrene by GPC was about 3,487. Also, introduction of a 1-butanol group into the polymer was confirmed by ¹H-NMR. The obtained resin was dissolved in PGME, and ion exchange treatment was performed using a cation exchange resin and an anion exchange resin for 4 hours, thereby obtaining the target polymer solution.

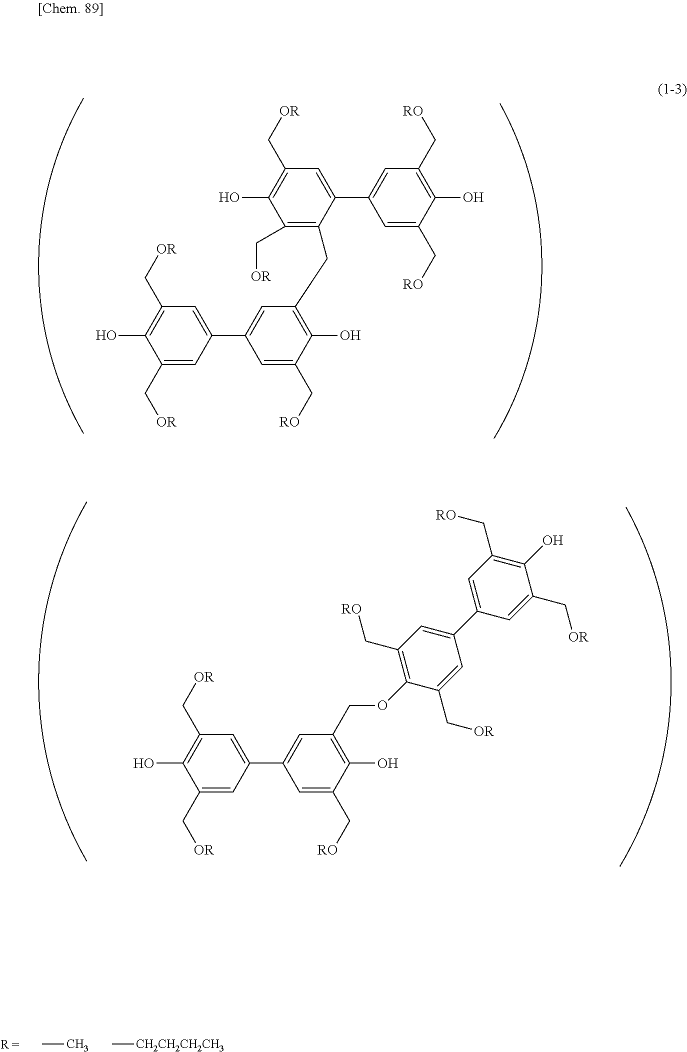

### Synthesis Example 4

A flask was charged with 34.50 g of TMOM-BP (manufactured by Honshu Chemical Industry Co., Ltd.), 33.16 g of TM-BIP-A, and 379.44 g of PGME. Thereafter, the resultant mixture was heated under nitrogen to about 90° C., 2.29 g of methanesulfonic acid (manufactured by Tokyo Chemical Industry Co., Ltd.) dissolved in 34.50 g of PGME was added thereto dropwise. After about 125.5 hours, the mixture was precipitated with methanol and water, and the mixture was dried, thereby obtaining a polymer (1-4). The weight average molecular weight Mw measured in terms of polystyrene by GPC was about 4,296. Also, introduction of PGME into the polymer was confirmed by ¹H-NMR. The obtained resin was dissolved in PGME, and ion exchange treatment was performed using a cation exchange resin and an anion exchange resin for 4 hours, thereby obtaining the target polymer solution.

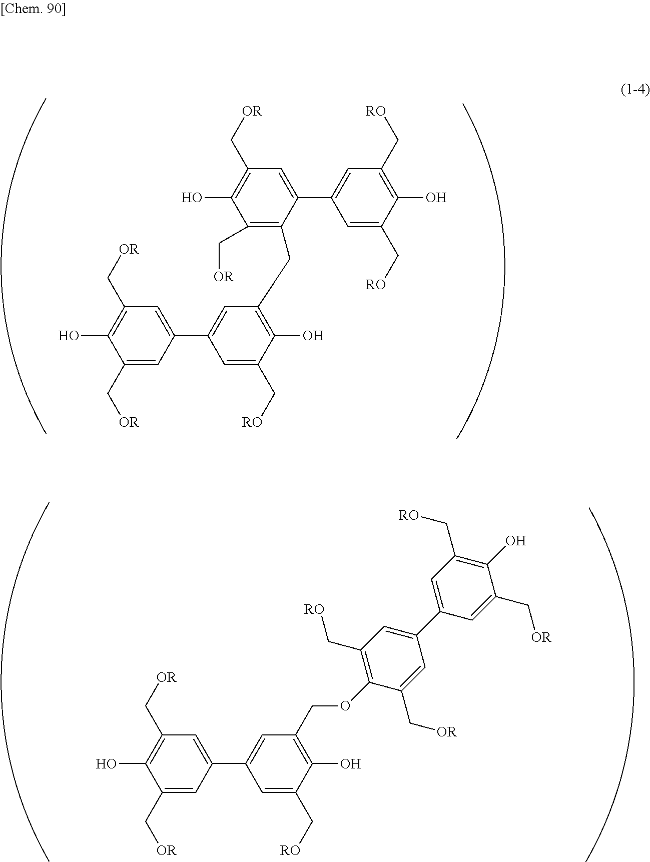

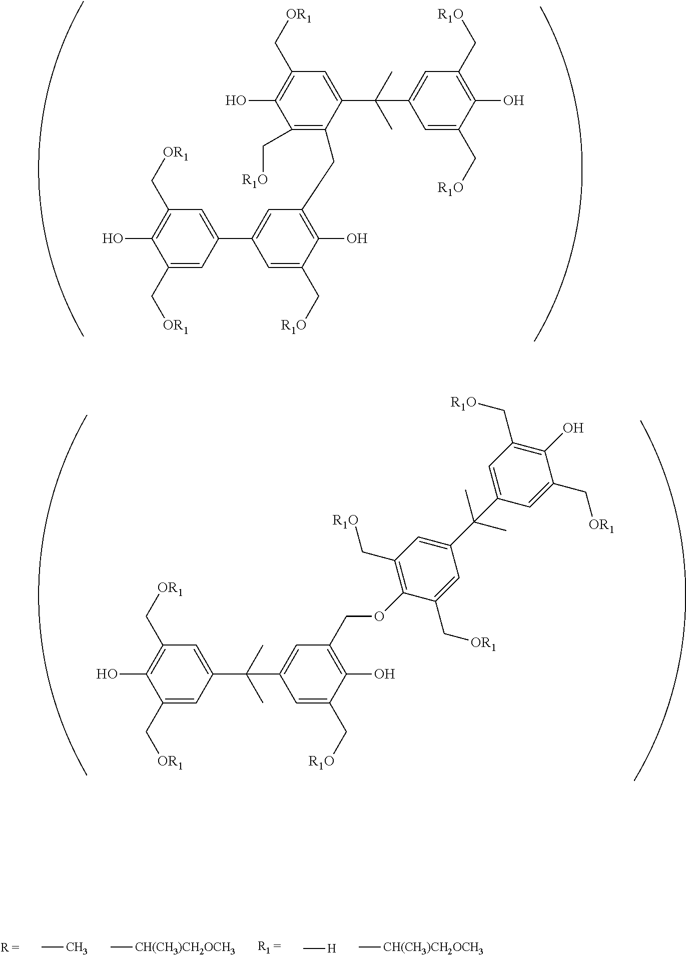

These four structures are further combined.

### Synthesis Example 5

A flask was charged with 34.50 g of TMOM-BP (manufactured by Honshu Chemical Industry Co., Ltd.), 0.31 g of PL-LI (manufactured by Midori Kagaku Co., Ltd.), and 189.73 g of PGME. Thereafter, the resultant mixture was heated under nitrogen to about 90° C., 2.29 g of methanesulfonic acid (manufactured by Tokyo Chemical Industry Co., Ltd.) dissolved in 17.25 g of PGME was added thereto dropwise. After about 48 hours, the mixture was precipitated with methanol and water, and the mixture was dried, thereby obtaining a polymer (1-5). The weight average molecular weight Mw measured in terms of polystyrene by GPC was about 3,978. Also, introduction of PGME into the polymer was confirmed by ¹H-NMR. The obtained resin was dissolved in PGME, and ion exchange treatment was performed using a cation exchange resin and an anion exchange resin for 4 hours, thereby obtaining the target polymer solution.

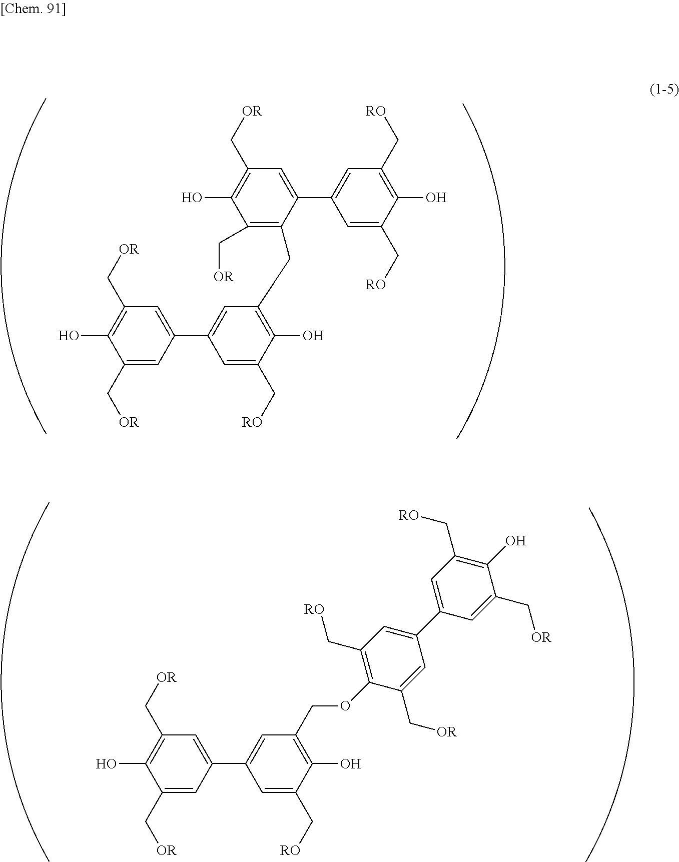

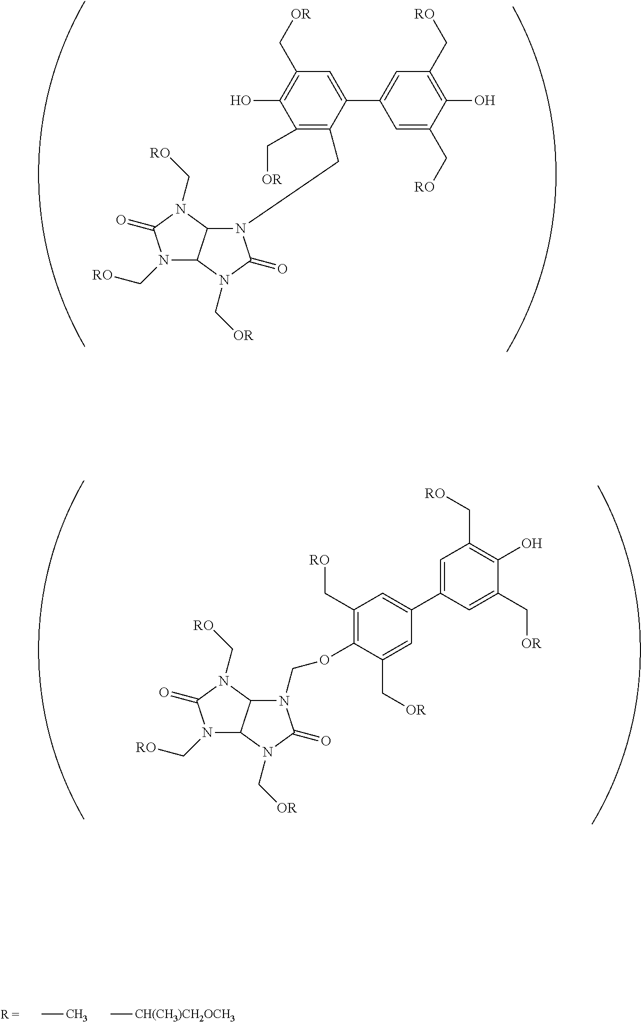

### Synthesis Example 6

A 100 mL flask was charged with 10.00 g of TMOM-BP (manufactured by Honshu Chemical Industry Co., Ltd.), 5.46 g of carbazole (manufactured by Tokyo Chemical Industry Co., Ltd.), and 58.72 g of PGME. Thereafter, the resultant mixture was heated under nitrogen to about 90° C., 0.47 g of methanesulfonic acid (manufactured by Tokyo Chemical Industry Co., Ltd.) dissolved in 5 g of PGME was added thereto dropwise. After about 2 hours, the mixture was precipitated with methanol, and the mixture was dried, thereby obtaining a polymer (1-6). The weight average molecular weight Mw measured in terms of polystyrene by GPC was about 4,000. Also, introduction of PGME into the polymer was confirmed by ¹H-NMR. The obtained resin was dissolved in PGMEA, and ion exchange treatment was performed using a cation exchange resin and an anion exchange resin for 4 hours, thereby obtaining the target polymer solution.

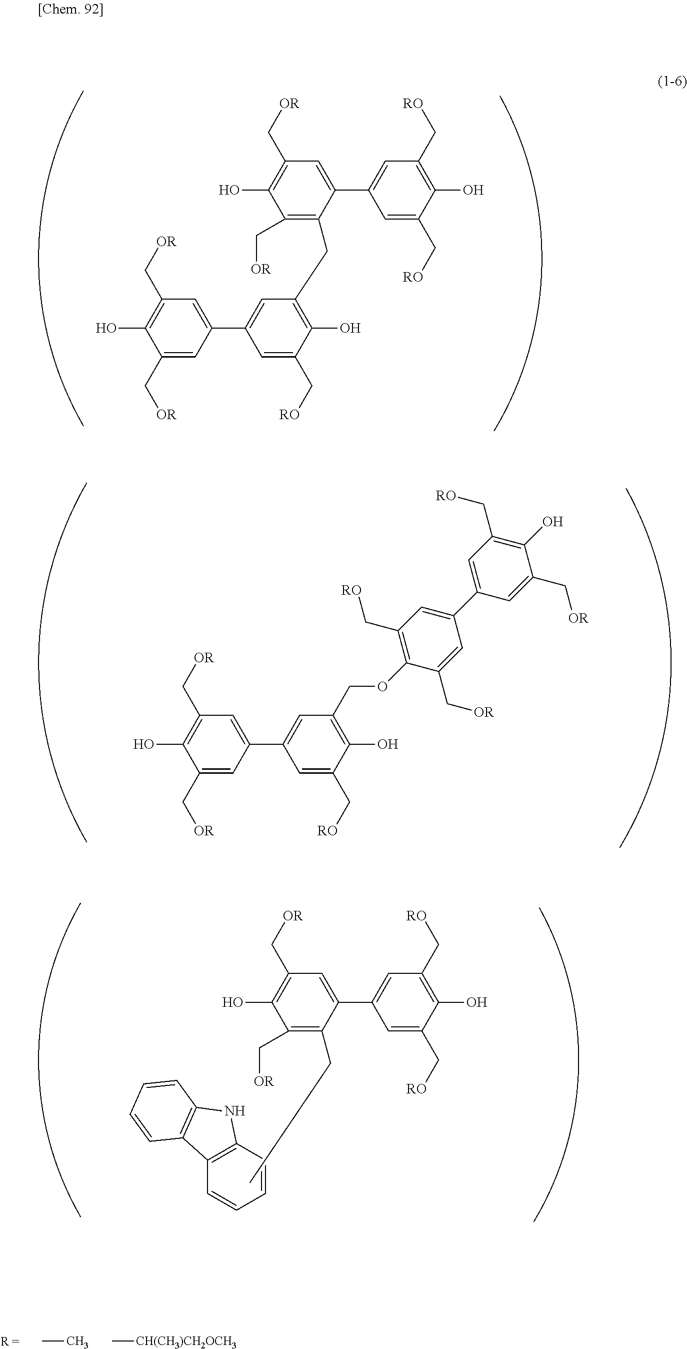

### Synthesis Example 7

A 100 mL flask was charged with 10.00 g of TMOM-BP (manufactured by Honshu Chemical Industry Co., Ltd.), 7.16 g of N-phenyl-1-naphthylamine (manufactured by Tokyo Chemical Industry Co., Ltd.), and 65.52 g of PGME. Thereafter, the resultant mixture was heated under nitrogen to about 90° C., 0.47 g of methanesulfonic acid (manufactured by Tokyo Chemical Industry Co., Ltd.) dissolved in 5 g of PGME was added thereto dropwise. After about 3 hours, the mixture was precipitated with methanol, and the mixture was dried, thereby obtaining a polymer (1-7). The weight average molecular weight Mw measured in terms of polystyrene by GPC was about 4,500. Also, introduction of PGME into the polymer was confirmed by ¹H-NMR. The obtained resin was dissolved in PGMEA, and ion exchange treatment was performed using a cation exchange resin and an anion exchange resin for 4 hours, thereby obtaining the target polymer solution.

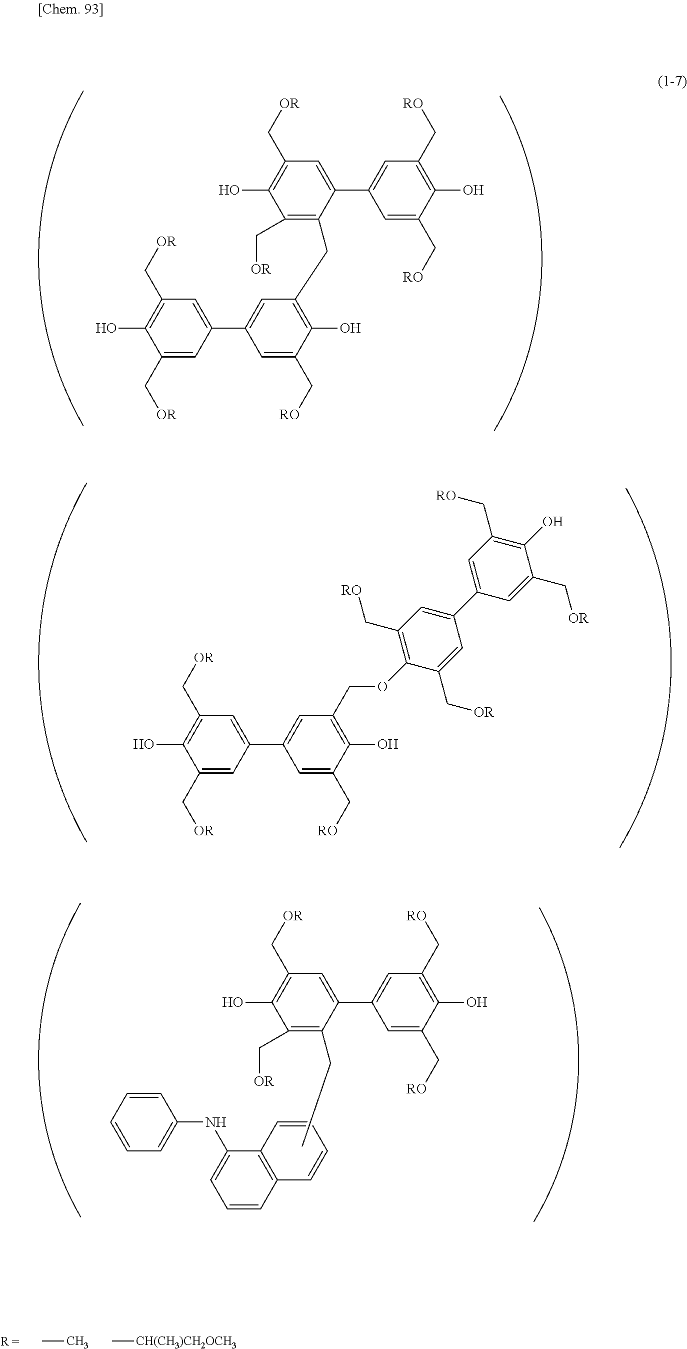

### Synthesis Example 8

A 100 mL flask was charged with 10.00 g of TMOM-BP (manufactured by Honshu Chemical Industry Co., Ltd.), 11.44 g of 9,9-bis(4-hydroxyphenyl)fluorene (manufactured by Tokyo Chemical Industry Co., Ltd.), and 60.73 g of PGME. Thereafter, the resultant mixture was heated under nitrogen until the mixture was refluxed, 0.47 g of methanesulfonic acid (manufactured by Tokyo Chemical Industry Co., Ltd.) dissolved in 5 g of PGME was added thereto dropwise. After about 4 hours, the mixture was precipitated with methanol and water, and the mixture was dried, thereby obtaining a polymer (1-8). The weight average molecular weight Mw measured in terms of polystyrene by GPC was about 4,100. Also, introduction of PGME into the polymer was confirmed by ¹H-NMR. The obtained resin was dissolved in PGMEA, and ion exchange treatment was performed using a cation exchange resin and an anion exchange resin for 4 hours, thereby obtaining the target polymer solution.

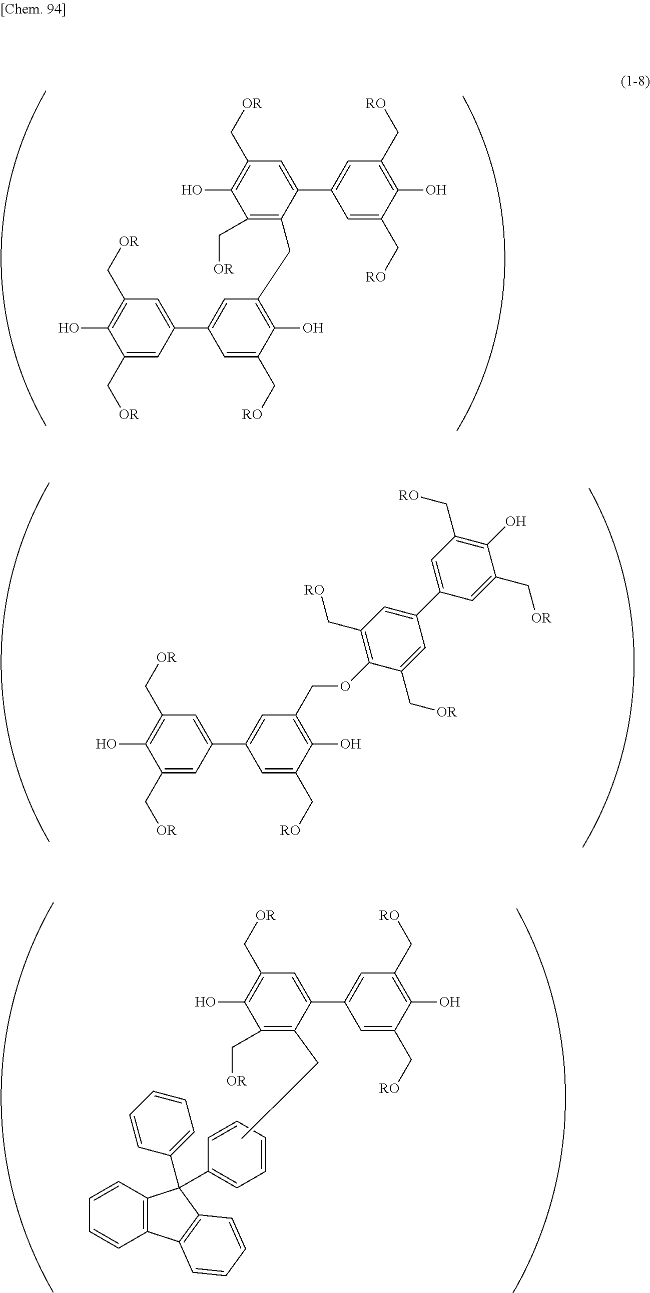

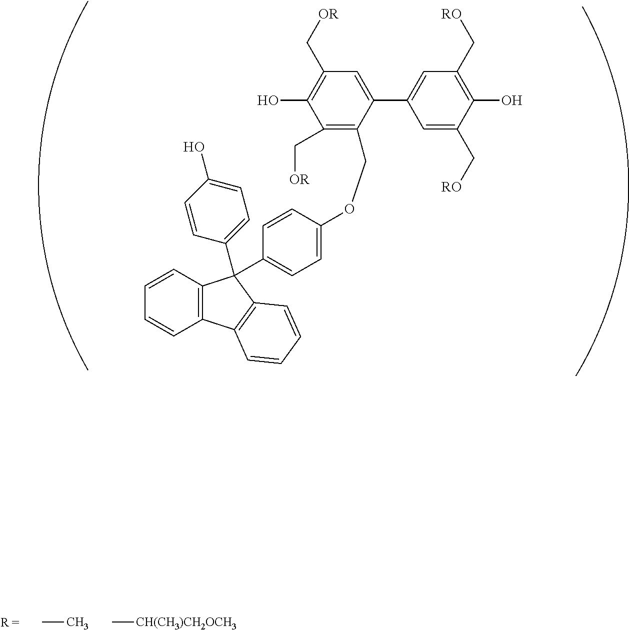

### Synthesis Example 9

A 100 mL flask was charged with 12.00 g of TMOM-BP (manufactured by Honshu Chemical Industry Co., Ltd.), 7.29 g of 2,2′-biphenol (manufactured by Tokyo Chemical Industry Co., Ltd.), and 54.58 g of PGME. Thereafter, the resultant mixture was heated under nitrogen until the mixture was refluxed, 0.56 g of methanesulfonic acid (manufactured by Tokyo Chemical Industry Co., Ltd.) dissolved in 5 g of PGME was added thereto dropwise. After about 1.5 hours, the mixture was precipitated with methanol and water, and the mixture was dried, thereby obtaining a polymer (1-9). The weight average molecular weight Mw measured in terms of polystyrene by GPC was about 3,700. Also, introduction of PGME into the polymer was confirmed by ¹H-NMR. The obtained resin was dissolved in PGMEA, and ion exchange treatment was performed using a cation exchange resin and an anion exchange resin for 4 hours, thereby obtaining the target polymer solution.

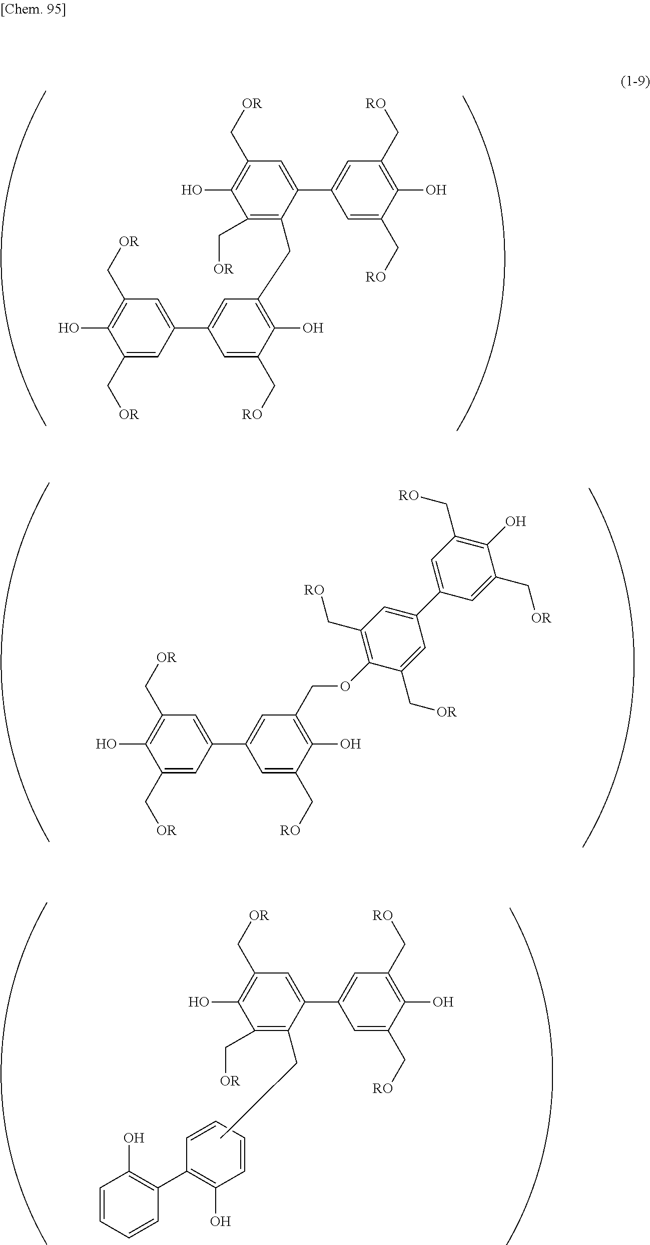

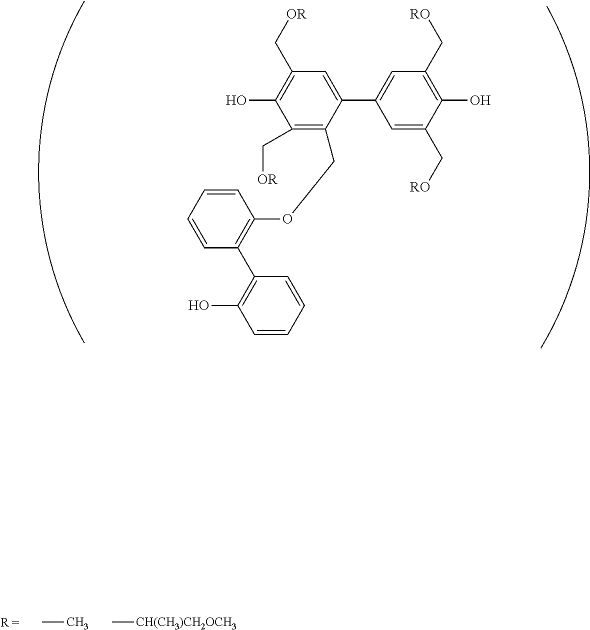

### Synthesis Example 10

A 100 mL flask was charged with 12.00 g of TMOM-BP (manufactured by Honshu Chemical Industry Co., Ltd.), 6.27 g of 1,5-dihydroxynaphthalene (manufactured by Tokyo Chemical Industry Co., Ltd.), and 70.36 g of PGME.

Thereafter, the resultant mixture was heated under nitrogen until the mixture was refluxed, 0.56 g of methanesulfonic acid (manufactured by Tokyo Chemical Industry Co., Ltd.) dissolved in 5 g of PGME was added thereto dropwise. After about 1 hour, the mixture was precipitated with methanol and water, and the mixture was dried, thereby obtaining a polymer (1-10). The weight average molecular weight Mw measured in terms of polystyrene by GPC was about 10,000. Also, introduction of PGME into the polymer was confirmed by ¹H-NMR. The obtained resin was dissolved in PGMEA, and ion exchange treatment was performed using a cation exchange resin and an anion exchange resin for 4 hours, thereby obtaining the target polymer solution.

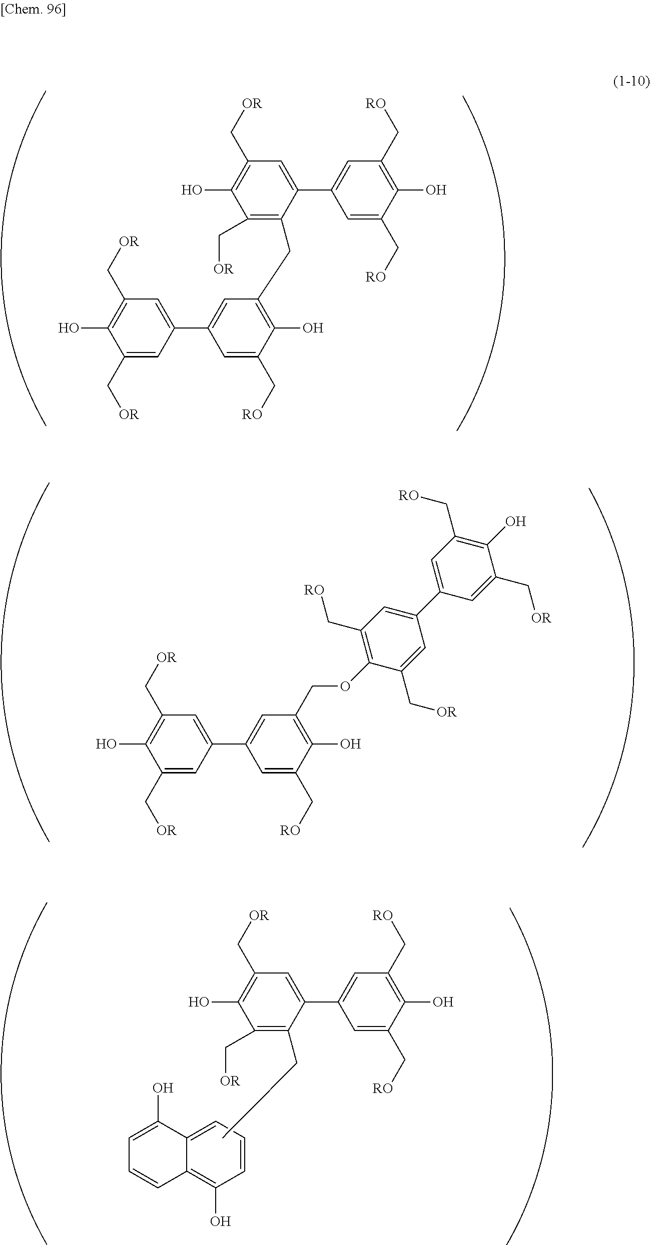

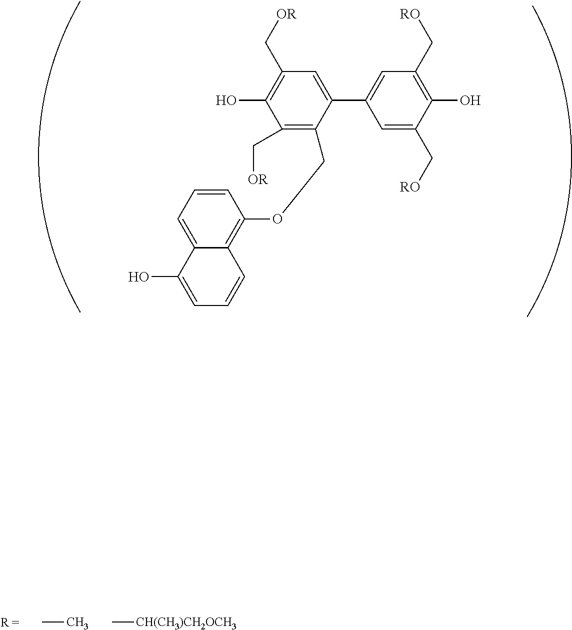

### Synthesis Example 11

A flask was charged with 68.99 g of TMOM-BP (manufactured by Honshu Chemical Industry Co., Ltd.), 40.00 g of trimesic acid (manufactured by Tokyo Chemical Industry Co., Ltd.), and 379.42 g of PGME. Thereafter, the resultant mixture was heated under nitrogen to about 90° C., 4.57 g of methanesulfonic acid (manufactured by Tokyo Chemical Industry Co., Ltd.) dissolved in 34.49 g of PGME was added thereto dropwise. After about 26.5 hours, the mixture was precipitated with methanol, water, and ammonia water, and the mixture was dried, thereby obtaining a polymer (1-11). The weight average molecular weight Mw measured in terms of polystyrene by GPC was about 4,200. Also, introduction of PGME into the polymer was confirmed by ¹H-NMR. The obtained resin was dissolved in PGME, and ion exchange treatment was performed using a cation exchange resin and an anion exchange resin for 4 hours, thereby obtaining the target polymer solution.

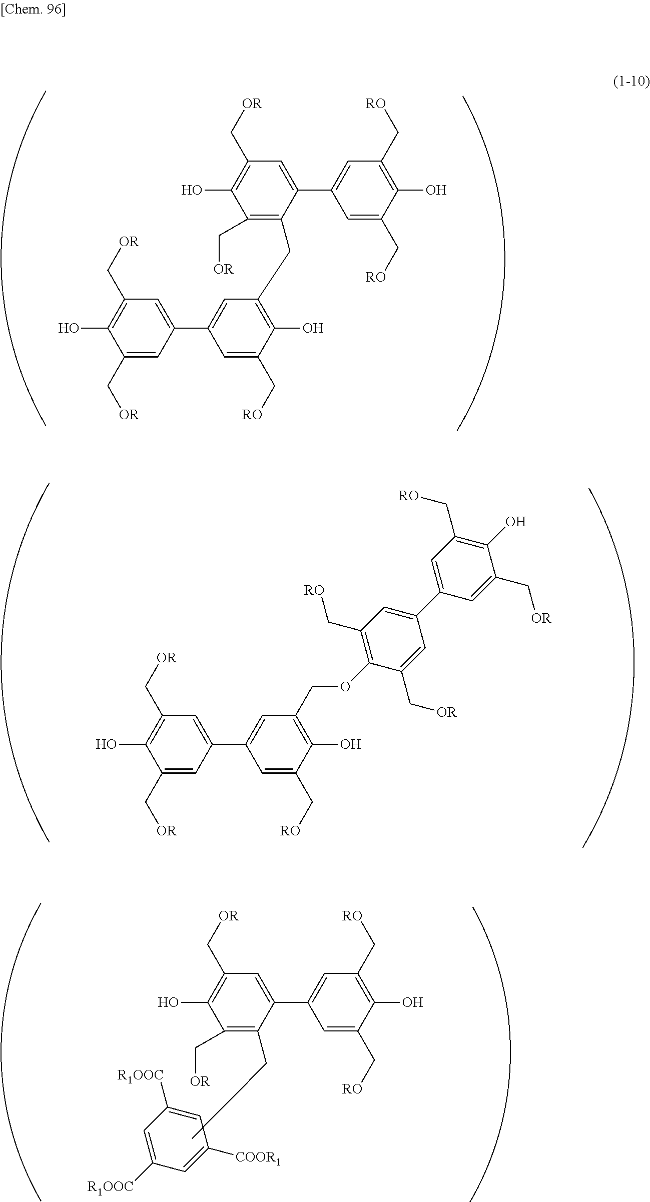

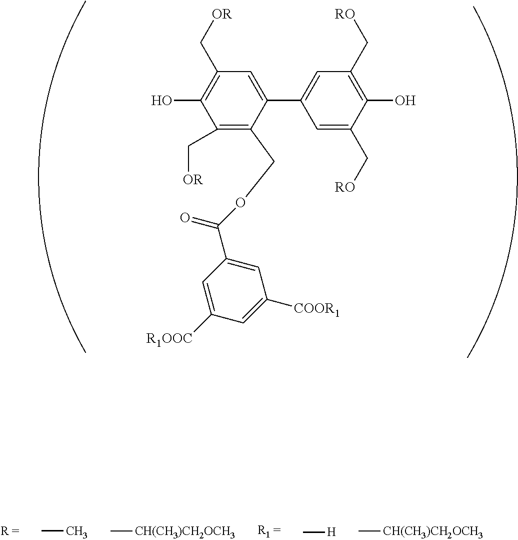

### Synthesis Example 12

A 100 mL flask was charged with 8.00 g of carbazole (manufactured by Tokyo Chemical Industry Co., Ltd.), 8.63 g of 9-fluorenone (manufactured by Tokyo Chemical Industry Co., Ltd.), 2.30 g of methanesulfonic acid (manufactured by Tokyo Chemical Industry Co., Ltd.), and 18.93 g of PGMEA. Thereafter, the resultant mixture was heated under nitrogen until the mixture was refluxed. After about 1.5 hours, the mixture was precipitated with methanol, and the mixture was dried, thereby obtaining a polymer (1-12). The weight average molecular weight Mw measured in terms of polystyrene by GPC was about 2,600. The obtained resin was dissolved in PGMEA, and ion exchange treatment was performed using a cation exchange resin and an anion exchange resin for 4 hours, thereby obtaining the target polymer solution.

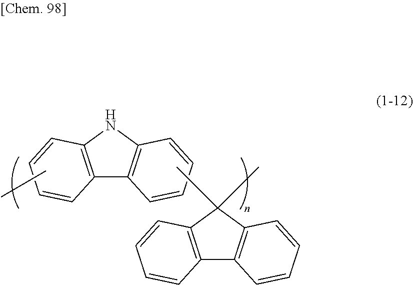

### Comparative Synthesis Example 1

A 100 mL flask was charged with 15.00 g of TMOM-BP (manufactured by Honshu Chemical Industry Co., Ltd.) and 35.55 g of 1,4-dioxane. Thereafter, the resultant mixture was heated under nitrogen to about 120° C., 0.24 g of methanesulfonic acid (manufactured by Tokyo Chemical Industry Co., Ltd.) dissolved in 5 g of 1,4-dioxane was added thereto dropwise. After about 6 hours, the mixture was precipitated with methanol, and the mixture was dried, thereby obtaining a polymer (2-1). The weight average molecular weight Mw measured in terms of polystyrene by GPC was about 4,600. The obtained resin was dissolved in PGMEA, and ion exchange treatment was performed using a cation exchange resin and an anion exchange resin for 4 hours, thereby obtaining the target polymer solution.

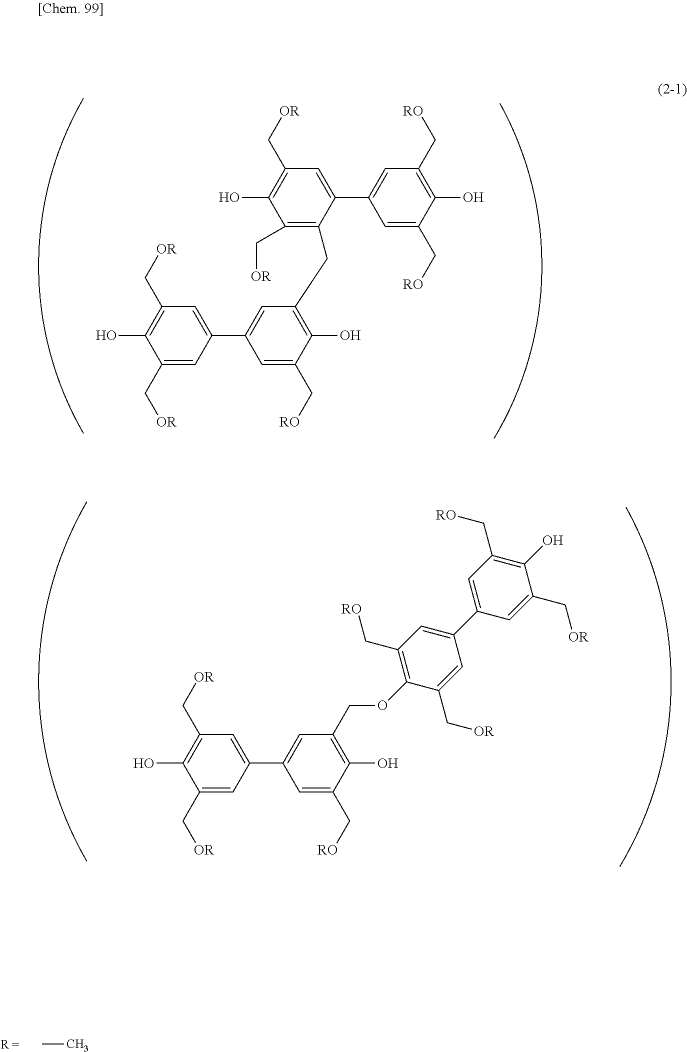

### Comparative Synthesis Example 2

A 100 mL flask was charged with 10.00 g of TMOM-BP (manufactured by Honshu Chemical Industry Co., Ltd.), 5.46 g of carbazole (manufactured by Tokyo Chemical Industry Co., Ltd.), and 18.70 g of 1,4-dioxane. Thereafter, the resultant mixture was heated under nitrogen to about 120° C., 0.16 g of methanesulfonic acid (manufactured by Tokyo Chemical Industry Co., Ltd.) dissolved in 5 g of 1,4-dioxane was added thereto dropwise. After about 1 hour, the mixture was precipitated with methanol, and the mixture was dried, thereby obtaining a polymer (2-2). The weight average molecular weight Mw measured in terms of polystyrene by GPC was about 3,200. The obtained resin was dissolved in PGMEA, and ion exchange treatment was performed using a cation exchange resin and an anion exchange resin for 4 hours, thereby obtaining the target polymer solution.

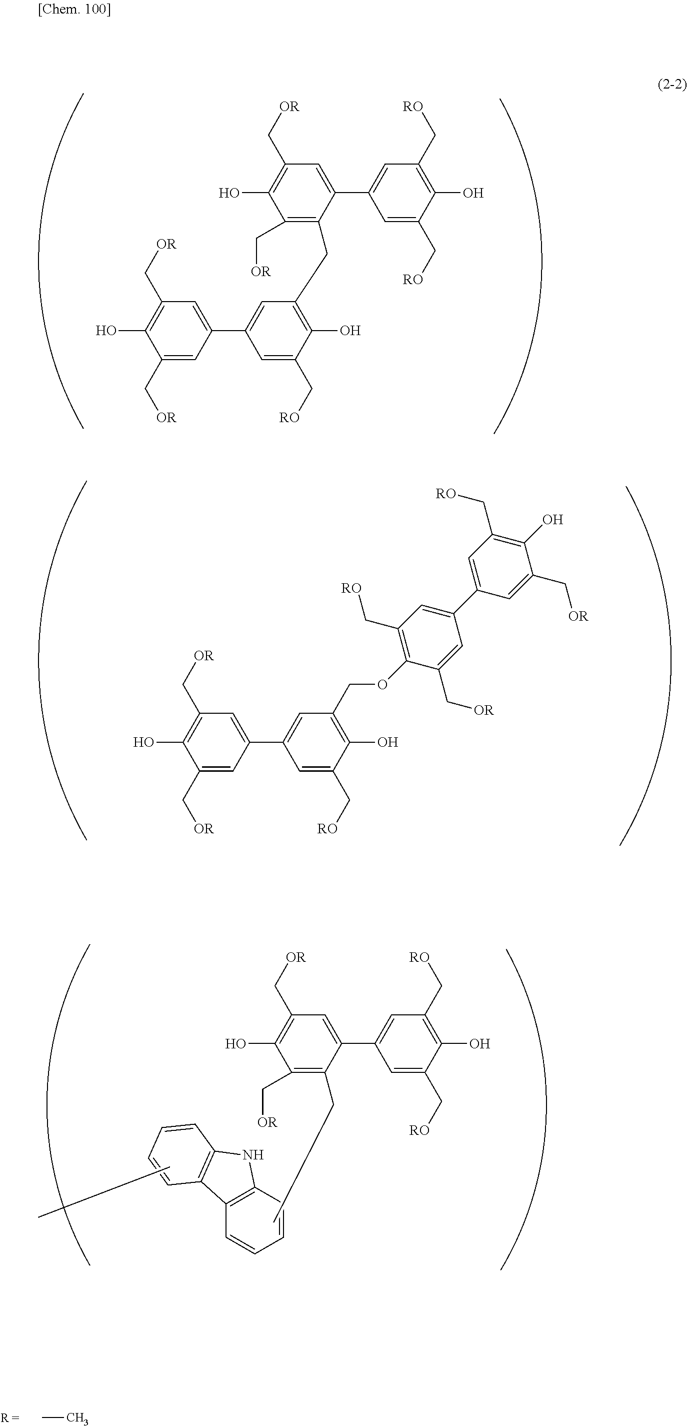

### Comparative Synthesis Example 3

A 100 mL flask was charged with 10.00 g of TMOM-BP (manufactured by Honshu Chemical Industry Co., Ltd.), 7.16 g of N-phenyl-1-naphthylamine (manufactured by Tokyo Chemical Industry Co., Ltd.), and 18.70 g of 1,4-dioxane. Thereafter, the resultant mixture was heated under nitrogen to about 120° C., 0.16 g of methanesulfonic acid (manufactured by Tokyo Chemical Industry Co., Ltd.) dissolved in 5 g of 1,4-dioxane was added thereto dropwise. After about 1 hour, the mixture was precipitated with methanol and water, and the mixture was dried, thereby obtaining a polymer (2-3). The weight average molecular weight Mw measured in terms of polystyrene by GPC was about 2,800. The obtained resin was dissolved in PGMEA, and ion exchange treatment was performed using a cation exchange resin and an anion exchange resin for 4 hours, thereby obtaining the target polymer solution.

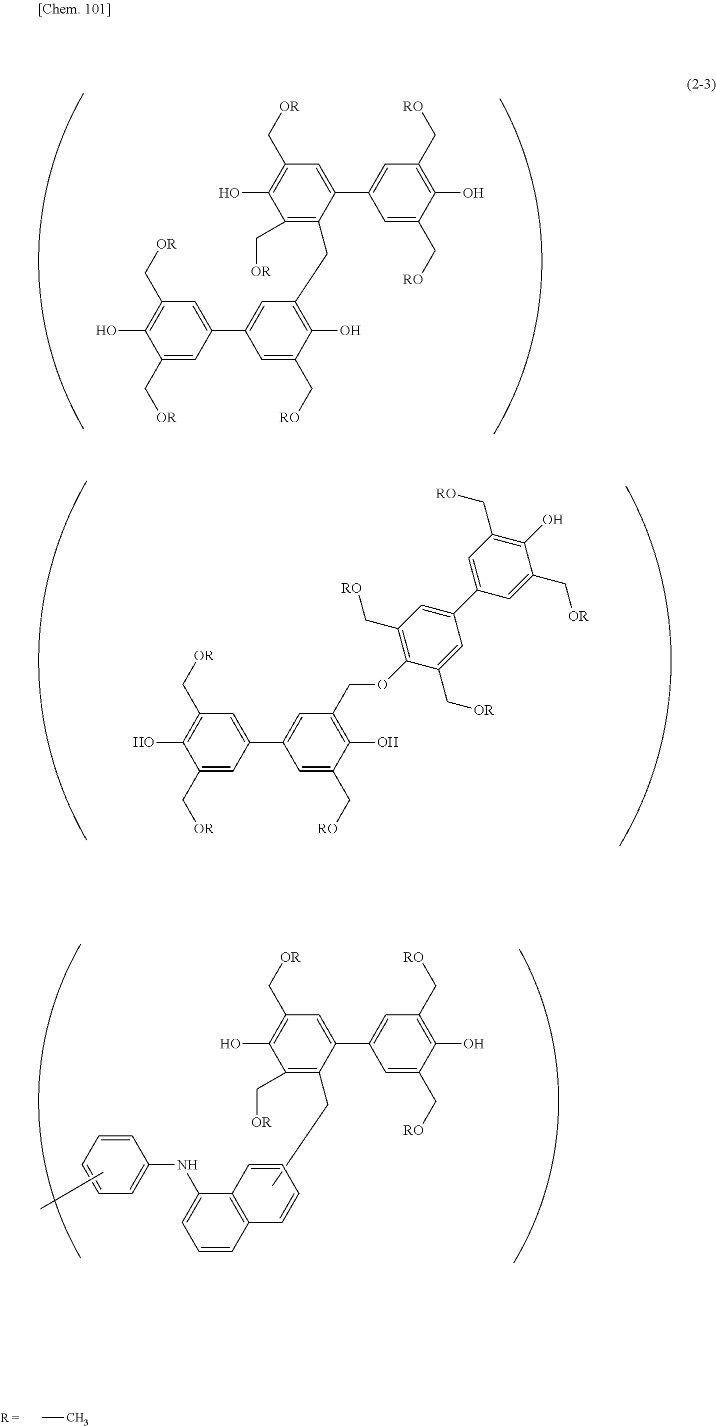

### Comparative Synthesis Example 4

A flask was charged with 12.00 g of TMOM-BP (manufactured by Honshu Chemical Industry Co., Ltd.), 8.23 g of trimesic acid (manufactured by Tokyo Chemical Industry Co., Ltd.), and 23.88 g of 1,4-dioxane. Thereafter, the resultant mixture was heated under nitrogen to about 120° C., 0.38 g of methanesulfonic acid (manufactured by Tokyo Chemical Industry Co., Ltd.) dissolved in 5 g of PGME was added thereto dropwise, which was allowed to react for about 5 hours.

### Comparative Synthesis Example 5

A 200 mL flask was charged with 69.92 g of N-phenyl-1-naphthylamine (manufactured by Tokyo Chemical Industry Co., Ltd.), 40.88 g of 2-ethylhexyl aldehyde (manufactured by Tokyo Chemical Industry Co., Ltd.), 9.19 g of methanesulfonic acid (manufactured by Tokyo Chemical Industry Co., Ltd.), and 80.00 g of propylene glycol monomethyl ether acetate (hereinafter, described as PGMEA). Thereafter, the resultant mixture was heated under nitrogen until the mixture was refluxed. After about 24 hours, the mixture was precipitated with methanol, and the mixture was dried, thereby obtaining a polymer (2-4). The weight average molecular weight Mw measured in terms of polystyrene by GPC was about 1,700. The obtained resin was dissolved in PGMEA, and ion exchange treatment was performed using a cation exchange resin and an anion exchange resin for 4 hours, thereby obtaining the target polymer solution.

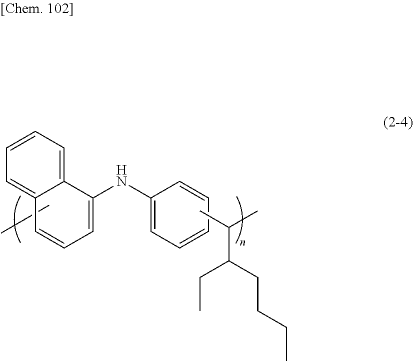

### Example 1

A resin solution (solid content: 21.38% by mass) was obtained in Synthesis Example 1. To 9.12 g of the resin solution were added 0.39 g of TMOM-BP (manufactured by Honshu Chemical Industry Co., Ltd.), 2.92 g of PGME containing 2% by mass of K-PURE TAG2689 (manufactured by King Industries Inc.), 0.20 g of PGMEA containing 1% by mass of a surfactant (manufactured by DIC Corporation, MEGAFACE R-40), 4.96 g of PGMEA, and 2.41 g of PGME and dissolved. The resultant mixture was filtered through a polytetrafluoroethylene microfilter having a pore size of 0.1 μm, thereby preparing a solution of the resist underlayer film-forming composition.

### Example 2

A resin solution (solid content: 26.93% by mass) was obtained in Synthesis Example 3. To 6.03 g of the resin solution were added 0.33 g of TMOM-BP (manufactured by Honshu Chemical Industry Co., Ltd.), 2.43 g of PGME containing 2% by mass of K-PURE TAG2689 (manufactured by King Industries Inc.), 0.16 g of PGMEA containing 1% by mass of a surfactant (manufactured by DIC Corporation, MEGAFACE R-40), 5.24 g of PGMEA, and 5.80 g of PGME and dissolved. The resultant mixture was filtered through a polytetrafluoroethylene microfilter having a pore size of 0.1 thereby preparing a solution of the resist underlayer film-forming composition.

### Example 3

A resin solution (solid content: 22.01% by mass) was obtained in Synthesis Example 4. To 7.38 g of the resin solution were added 0.33 g of TMOM-BP (manufactured by Honshu Chemical Industry Co., Ltd.), 2.43 g of PGME containing 2% by mass of K-PURE TAG2689 (manufactured by King Industries Inc.), 0.16 g of PGMEA containing 1% by mass of a surfactant (manufactured by DIC Corporation, MEGAFACE R-40), 5.24 g of PGMEA, and 4.46 g of PGME and dissolved. The resultant mixture was filtered through a polytetrafluoroethylene microfilter having a pore size of 0.1 thereby preparing a solution of the resist underlayer film-forming composition.

### Example 4

A resin solution (solid content: 20.12% by mass) was obtained in Synthesis Example 5. To 8.08 g of the resin solution were added 0.33 g of TMOM-BP (manufactured by Honshu Chemical Industry Co., Ltd.), 2.43 g of PGME containing 2% by mass of K-PURE TAG2689 (manufactured by King Industries Inc.), 0.16 g of PGMEA containing 1% by mass of a surfactant (manufactured by DIC Corporation, MEGAFACE R-40), 5.24 g of PGMEA, and 3.76 g of PGME and dissolved. The resultant mixture was filtered through a polytetrafluoroethylene microfilter having a pore size of 0.1 thereby preparing a solution of the resist underlayer film-forming composition.

### Example 5

A resin solution (solid content: 17.85% by mass) was obtained in Synthesis Example 6. To 10.92 g of the resin solution were added 0.39 g of TMOM-BP (manufactured by Honshu Chemical Industry Co., Ltd.), 2.92 g of PGME containing 2% by mass of K-PURE TAG2689 (manufactured by King Industries Inc.), 0.20 g of PGMEA containing 1% by mass of a surfactant (manufactured by DIC Corporation, MEGAFACE R-40), 3.15 g of PGMEA, and 2.41 g of PGME and dissolved. The resultant mixture was filtered through a polytetrafluoroethylene microfilter having a pore size of 0.1 thereby preparing a solution of the resist underlayer film-forming composition.

### Example 6

A resin solution (solid content: 16.62% by mass) was obtained in Synthesis Example 7. To 11.73 g of the resin solution were added 0.39 g of TMOM-BP (manufactured by Honshu Chemical Industry Co., Ltd.), 2.92 g of PGME containing 2% by mass of K-PURE TAG2689 (manufactured by King Industries Inc.), 0.20 g of PGMEA containing 1% by mass of a surfactant (manufactured by DIC Corporation, MEGAFACE R-40), 2.35 g of PGMEA, and 2.41 g of PGME and dissolved. The resultant mixture was filtered through a polytetrafluoroethylene microfilter having a pore size of 0.1 thereby preparing a solution of the resist underlayer film-forming composition.

### Example 7

A resin solution (solid content: 18.61% by mass) was obtained in Synthesis Example 8. To 10.48 g of the resin solution were added 0.39 g of TMOM-BP (manufactured by Honshu Chemical Industry Co., Ltd.), 2.92 g of PGME containing 2% by mass of K-PURE TAG2689 (manufactured by King Industries Inc.), 0.20 g of PGMEA containing 1% by mass of a surfactant (manufactured by DIC Corporation, MEGAFACE R-40), 3.61 g of PGMEA, and 2.41 g of PGME and dissolved. The resultant mixture was filtered through a polytetrafluoroethylene microfilter having a pore size of 0.1 thereby preparing a solution of the resist underlayer film-forming composition.

### Example 8

A resin solution (solid content: 16.88% by mass) was obtained in Synthesis Example 9. To 11.55 g of the resin solution were added 0.39 g of TMOM-BP (manufactured by Honshu Chemical Industry Co., Ltd.), 2.92 g of PGME containing 2% by mass of K-PURE TAG2689 (manufactured by King Industries Inc.), 0.20 g of PGMEA containing 1% by mass of a surfactant (manufactured by DIC Corporation, MEGAFACE R-40), 2.52 g of PGMEA, and 2.41 g of PGME and dissolved. The resultant mixture was filtered through a polytetrafluoroethylene microfilter having a pore size of 0.1 thereby preparing a solution of the resist underlayer film-forming composition.

### Example 9

A resin solution (solid content: 18.06% by mass) was obtained in Synthesis Example 10. To 10.80 g of the resin solution were added 0.39 g of TMOM-BP (manufactured by Honshu Chemical Industry Co., Ltd.), 2.92 g of PGME containing 2% by mass of K-PURE TAG2689 (manufactured by King Industries Inc.), 0.20 g of PGMEA containing 1% by mass of a surfactant (manufactured by DIC Corporation, MEGAFACE R-40), 3.28 g of PGMEA, and 2.41 g of PGME and dissolved. The resultant mixture was filtered through a polytetrafluoroethylene microfilter having a pore size of 0.1 thereby preparing a solution of the resist underlayer film-forming composition.

### Example 10

A resin solution (solid content: 17.62% by mass) was obtained in Synthesis Example 11. To 13.82 g of the resin solution were added 0.49 g of TMOM-BP (manufactured by Honshu Chemical Industry Co., Ltd.), 1.44 g of PGME containing 5% by mass of pyridinium p-hydroxybenzenesulfonate, 0.49 g of PGMEA containing 1% by mass of a surfactant (manufactured by DIC Corporation, MEGAFACE R-40), 6.12 g of PGMEA, and 2.64 g of PGME and dissolved. The resultant mixture was filtered through a polytetrafluoroethylene microfilter having a pore size of 0.1 thereby preparing a solution of the resist underlayer film-forming composition.

### Example 11

A resin solution (solid content: 21.38% by mass) was obtained in Synthesis Example 1. To 11.80 g of the resin solution were added 0.39 g of TMOM-BP (manufactured by Honshu Chemical Industry Co., Ltd.), 3.78 g of PGME containing 2% by mass of K-PURE TAG2689 (manufactured by King Industries Inc.), 0.25 g of PGMEA containing 1% by mass of a surfactant (manufactured by DIC Corporation, MEGAFACE R-40), 2.66 g of PGMEA, and 1.51 g of PGME and dissolved. The resultant mixture was filtered through a polytetrafluoroethylene microfilter having a pore size of 0.1 thereby preparing a solution of the resist underlayer film-forming composition.

### Example 12

A resin solution (solid content: 21.38% by mass) was obtained in Synthesis Example 1. To 12.15 g of the resin solution were added 0.26 g of PGMEA containing 1% by mass of a surfactant (manufactured by DIC Corporation, MEGAFACE R-40), 2.37 g of PGMEA, and 5.22 g of PGME and dissolved. The resultant mixture was filtered through a polytetrafluoroethylene microfilter having a pore size of 0.1 thereby preparing a solution of the resist underlayer film-forming composition.

### Example 13

A resin solution (solid content: 21.38% by mass) was obtained in Synthesis Example 1. To 14.02 g of the resin solution were added 0.30 g of PGMEA containing 1% by mass of a surfactant (manufactured by DIC Corporation, MEGAFACE R-40), 0.58 g of PGMEA, and 5.10 g of PGME and dissolved. The resultant mixture was filtered through a polytetrafluoroethylene microfilter having a pore size of 0.1 thereby preparing a solution of the resist underlayer film-forming composition.

### Example 14

A resin solution (solid content: 30.00% by mass) was obtained in Synthesis Example 12. To 4.33 g of the resin solution were added 1.22 g of the polymer solution (solid content: 21.38% by mass) obtained in Synthesis Example 1, 1.95 g of PGME containing 2% by mass of K-PURE TAG2689 (manufactured by King Industries Inc.), 0.13 g of PGMEA containing 1% by mass of a surfactant (manufactured by DIC Corporation, MEGAFACE R-40), 10.63 g of PGMEA, and 1.77 g of PGME and dissolved. The resultant mixture was filtered through a polytetrafluoroethylene microfilter having a pore size of 0.1 thereby preparing a solution of the resist underlayer film-forming composition.

### Comparative Example 1

A resin solution (solid content: 24.24% by mass) was obtained in Comparative Synthesis Example 5.

To 7.54 g of the resin solution were added 0.37 g of TMOM-BP (manufactured by Honshu Chemical Industry Co., Ltd.), 2.73 g of PGME containing 2% by mass of K-PURE TAG2689 (manufactured by King Industries Inc.), 0.18 g of PGMEA containing 1% by mass of a surfactant (manufactured by DIC Corporation, MEGAFACE R-40), 3.03 g of PGMEA, and 1.14 g of PGME and dissolved. The resultant mixture was filtered through a polytetrafluoroethylene microfilter having a pore size of 0.1 μm thereby preparing a solution of the resist underlayer film-forming composition.

### Comparative Example 2

A resin solution (solid content: 30.00% by mass) was obtained in Synthesis Example 12. To 4.33 g of the resin solution were added 0.26 g of TMOM-BP (manufactured by Honshu Chemical Industry Co., Ltd.), 1.95 g of PGME containing 2% by mass of K-PURE TAG2689 (manufactured by King Industries Inc.), 0.13 g of PGMEA containing 1% by mass of a surfactant (manufactured by DIC Corporation, MEGAFACE R-40), 11.56 g of PGMEA, and 1.77 g of PGME and dissolved. The resultant mixture was filtered through a polytetrafluoroethylene microfilter having a pore size of 0.1 thereby preparing a solution of the resist underlayer film-forming composition.

(Test of Solubility of Polymer)

At the time syntheses were carried out according to Synthesis Examples 2, 6, 7, and 11 and Comparative Synthesis Examples 1, 2, 3, and 4, whether the monomer and the polymer were dissolved in the reaction solvent was visually confirmed. Unsuspended solutions were rated as good, and a suspended solution was rated as poor. Also, each of the polymers obtained in Synthesis Examples 2, 6, 7, and 11 and those obtained in Comparative Synthesis Examples 1, 2, and 3 was dissolved in PGME or PGMEA so that the solution had a solid content of 20% by mass. Thereafter, an ion exchange treatment was performed according to Synthesis Examples and Comparative Examples, and the solubility of each of the polymers was judged. Solutions not suspended after the ion exchange treatment were rated as good, and solutions suspended after the ion exchange treatment were rated as poor. The results are shown in Table 1.

TABLE 1
Evaluation of solubility of polymer

| | | | Solubility | | |
|---|---|---|---|---|---|
| | | | in reaction | Solubility of | Solubility in PGME |
| | | | solvent | polymer in PGME | or PGMEA |
| | Molecular | Synthetic | during | or PGMEA | after ion |
| Sample | weight | solvent | reaction | after drying | exchange |
| Synthesis | 5400 | PGME | Good | Good | Good |
| Example 2 | | | | | |
| Comparative | 4600 | 1,4-Dioxane | Good | Good | Poor |
| Synthesis | | | | | |
| Example 1 | | | | | |
| Synthesis | 4000 | PGME | Good | Good | Good |
| Example 6 | | | | | |
| Comparative | 3200 | 1,4-Dioxane | Good | Good | Poor |
| Synthesis | | | | | |
| Example 2 | | | | | |
| Synthesis | 4500 | PGME | Good | Good | Good |
| Example 7 | | | | | |
| Comparative | 2800 | 1,4-Dioxane | Good | Good | Poor |
| Synthesis | | | | | |
| Example 3 | | | | | |
| Synthesis | 4200 | PGME | Good | Good | Good |
| Example 11 | | | | | |
| Comparative | — | 1,4-Dioxane | Poor | — | — |
| Synthesis | | | | | |
| Example 4 | | | | | |

By synthesizing a polymer in PGME having a non-phenolic hydroxy group in the molecule, a methoxypropoxy group is introduced into the side chain. Therefore, the polymer exhibits a higher solubility in PGME or PGMEA after the ion exchange treatment than a polymer synthesized in 1,4-dioxane having no non-phenolic hydroxy group in the molecule. Also, it is advantageous in that a polymer can be synthesized in PGME that is a solvent commonly used in the semiconductor industry, without using 1,4-dioxane that is a highly harmful solvent classified as a specific hazardous industrial waste. Moreover, as shown in Synthesis Example 11 and Comparative Synthesis Example 4, in a case where a monomer having a high polarity is used, the monomer is not dissolved in a low-polarity solvent such as 1,4-dioxane, and the polymerization does not proceed. In contrast, use of a highly polar alcohol solvent such as PGME is also advantageous in that the polymerization proceeds and a material having a high solubility can be obtained even after ion exchange treatment.

Subsequently, the properties of these polymers having the alcoholic structure substitution and the crosslinking agents were evaluated.

(Elution Test in Resist Solvent)

The solution of the resist underlayer film-forming composition prepared in each of Comparative Example 1-2 and Example 1-14 was applied onto a silicon wafer using a spin coater, and the applied film was baked on a hot plate at 240° C. for 60 seconds or at 350° C. for 60 seconds, thereby forming a resist underlayer film (film thickness: 200 nm). These resist underlayer films were immersed in a commonly used thinner PGME/PGMEA=7/3 to confirm the curability. It was confirmed that any of the resist underlayer films was insoluble in the thinner and had a sufficient curability.

(Measurement of Optical Constant)

The solution of the resist underlayer film-forming composition prepared in each of Comparative Example 1 and Example 1-13 was applied onto a silicon wafer using a spin coater. The applied film was baked on a hot plate at 240° C. for 60 seconds or at 350° C. for 60 seconds, to form a resist underlayer film (film thickness: 50 nm). The refractive index (n value) and optical absorption coefficient (also referred to as a k value or an attenuation coefficient) of each of the resist underlayer films at a wavelength of 193 nm were measured using a spectroscopic ellipsometer. The results are shown in Table 2.

TABLE 2
Refractive index n and optical absorption coefficient k

| | | n/k 193 nm |
|---|---|---|
| Comparative | Film obtained by baking at 240° C. | 1.42/0.35 |
| Example 1 | | |
| Example 1 | Film obtained by baking at 240° C. | 1.37/0.44 |
| Example 2 | Film obtained by baking at 240° C. | 1.38/0.42 |
| Example 3 | Film obtained by baking at 240° C. | 1.38/0.49 |
| Example 4 | Film obtained by baking at 240° C. | 1.37/0.44 |
| Example 5 | Film obtained by baking at 240° C. | 1.38/0.42 |
| Example 6 | Film obtained by baking at 240° C. | 1.37/0.52 |
| Example 7 | Film obtained by baking at 240° C. | 1.38/0.58 |
| Example 8 | Film obtained by baking at 240° C. | 1.37/0.52 |
| Example 9 | Film obtained by baking at 240° C. | 1.40/0.44 |
| Example 10 | Film obtained by baking at 240° C. | 1.37/0.44 |
| Example 11 | Film obtained by baking at 240° C. | 1.36/0.44 |
| Example 12 | Film obtained by baking at 240° C. | 1.38/0.39 |
| Example 13 | Film obtained by baking at 350° C. | 1.38/0.40 |

As seen above, by changing the type of the compound to be reacted, the optical constant of the resist underlayer film can be freely controlled.

[Measurement of Dry Etching Rate]

The etcher and etching gas used to measure a dry etching rate are as follows.

RIE-10NR (manufactured by SAMCO Inc.): CF₄

The solution of the resist underlayer film-forming composition prepared in each of Comparative Example 1 and Example 1-13 was applied onto a silicon wafer using a spin coater. The applied film was baked on a hot plate at 240° C. for 60 seconds or at 350° C. for 60 seconds, to form a resist underlayer film (film thickness: 200 μm). The dry etching rate was measured using CF₄ gas as the etching gas and the dry etching rate ratio in each of Comparative Example 1 and Example 1-13 was determined. The dry etching rate ratio is a ratio of (dry etching rate of resist underlayer film)/(dry etching rate of KrF photoresist). The results are shown in Table 3.

TABLE 3
Dry etching rate ratio

| | | Etching rate |
|---|---|---|
| Comparative | Film obtained by baking at 240° C. | 0.88 |
| Example 1 | | |
| Example 1 | Film obtained by baking at 240° C. | 1.08 |
| Example 2 | Film obtained by baking at 240° C. | 1.09 |
| Example 3 | Film obtained by baking at 240° C. | 1.04 |
| Example 4 | Film obtained by baking at 240° C. | 1.08 |
| Example 5 | Film obtained by baking at 240° C. | 0.99 |
| Example 6 | Film obtained by baking at 240° C. | 0.95 |
| Example 7 | Film obtained by baking at 240° C. | 0.98 |
| Example 8 | Film obtained by baking at 240° C. | 1.08 |
| Example 9 | Film obtained by baking at 240° C. | 1.10 |
| Example 10 | Film obtained by baking at 240° C. | 1.09 |
| Example 11 | Film obtained by baking at 240° C. | 1.07 |
| Example 12 | Film obtained by baking at 240° C. | 1.13 |
| Example 13 | Film obtained by baking at 350° C. | 1.11 |

As seen above, by changing the type of the compound to be reacted, the etching resistance of the resist underlayer film can be freely controlled.

(Measurement of Amount of Sublimate)

The measurement of the amount of the sublimate was performed using a sublimate amount measuring apparatus described in WO 2007/111147 A. Each of the resist underlayer film-forming compositions prepared in Comparative Example 1 and Example 1-13 was applied to a silicon wafer, and the amount of the sublimate when the film thickness reached 200 nm after baking at 240° C. for 60 seconds or 350° C. for 60 seconds was measured. The results are shown in Table 4. Note that the value shown in the table is a value of (amount of sublimate of Example 1-13)/(amount of sublimate of Comparative Example 1).

TABLE 4
Amount of sublimate

| | | Amount of |
|---|---|---|
| | | sublimate |
| Comparative | Film obtained by baking at 240° C. | 1.00 |
| Example 1 | | |
| Example 1 | Film obtained by baking at 240° C. | 0.11 |
| Example 2 | Film obtained by baking at 240° C. | 0.10 |
| Example 3 | Film obtained by baking at 240° C. | 0.07 |
| Example 4 | Film obtained by baking at 240° C. | 0.07 |
| Example 5 | Film obtained by baking at 240° C. | 0.07 |
| Example 6 | Film obtained by baking at 240° C. | 0.40 |
| Example 7 | Film obtained by baking at 240° C. | 0.10 |
| Example 8 | Film obtained by baking at 240° C. | 0.10 |
| Example 9 | Film obtained by baking at 240° C. | 0.09 |
| Example 10 | Film obtained by baking at 240° C. | 0.40 |
| Example 11 | Film obtained by baking at 240° C. | 0.04 |
| Example 12 | Film obtained by baking at 240° C. | 0.37 |
| Example 13 | Film obtained by baking at 350° C. | 0.29 |

As seen above, by using the materials with crosslinked structure, the amount of the sublimate of the resist underlayer film-forming composition can be significantly reduced, and the concern of contamination of the apparatus is reduced.

(Evaluation of Embeddability)

Embeddability of a 200 nm-thick SiO₂ substrate in a dense pattern area having a trench width of 50 nm and a pitch of 100 nm was confirmed. The resist underlayer film-forming composition prepared in each of Comparative Example 1 and Example 1-13 was applied onto the substrate, and the applied film was baked at 240° C. for 60 seconds or at 350° C. for 60 seconds, thereby forming a resist underlayer film having a thickness of about 200 nm. The flatness of the substrate was observed using a scanning electron microscope (S-4800) manufactured by Hitachi High-Technologies Corporation, to confirm the presence or absence of filling of the resist underlayer film-forming composition in the pattern. The results are shown in Table 5.

TABLE 5
Evaluation of embeddability

| | | Embeddability |
|---|---|---|
| Comparative | Film obtained by baking at 240° C. | ◯ |
| Example 1 | | |
| Example 1 | Film obtained by baking at 240° C. | ◯ |
| Example 2 | Film obtained by baking at 240° C. | ◯ |
| Example 3 | Film obtained by baking at 240° C. | ◯ |
| Example 4 | Film obtained by baking at 240° C. | ◯ |
| Example 5 | Film obtained by baking at 240° C. | ◯ |
| Example 6 | Film obtained by baking at 240° C. | ◯ |
| Example 7 | Film obtained by baking at 240° C. | ◯ |
| Example 8 | Film obtained by baking at 240° C. | ◯ |
| Example 9 | Film obtained by baking at 240° C. | ◯ |
| Example 10 | Film obtained by baking at 240° C. | ◯ |
| Example 11 | Film obtained by baking at 240° C. | ◯ |
| Example 12 | Film obtained by baking at 240° C. | ◯ |
| Example 13 | Film obtained by baking at 350° C. | ◯ |

Example 1-13 shows as high an embeddability as do the conventional materials.

(Hardness Test)

Each of the resist underlayer film-forming compositions prepared in Comparative Example 1 and Example 1-13 was applied onto a silicon wafer, and the applied film was performed at 240° C. for 60 seconds or at 350° C. for 60 seconds, thereby forming a resist underlayer film having a thickness of 200 nm. The hardness of the cured resist film was evaluated by TI-980 triboidentor manufactured by Bruker Corporation. The cured resist film having a hardness higher than that of Comparative Example 1 was evaluated as ∘. The results are shown in Table 6.

TABLE 6
Evaluation of hardness

| | | Hardness |
|---|---|---|
| Comparative | Film obtained by baking at 240° C. | x |
| Example 1 | | |
| Example 1 | Film obtained by baking at 240° C. | ○ |
| Example 2 | Film obtained by baking at 240° C. | ○ |
| Example 3 | Film obtained by baking at 240° C. | ○ |
| Example 4 | Film obtained by baking at 240° C. | ○ |
| Example 5 | Film obtained by baking at 240° C. | ○ |
| Example 6 | Film obtained by baking at 240° C. | ○ |
| Example 7 | Film obtained by baking at 240° C. | ○ |
| Example 8 | Film obtained by baking at 240° C. | ○ |
| Example 9 | Film obtained by baking at 240° C. | ○ |
| Example 10 | Film obtained by baking at 240° C. | ○ |
| Example 11 | Film obtained by baking at 240° C. | ○ |
| Example 12 | Film obtained by baking at 240° C. | ○ |
| Example 13 | Film obtained by baking at 350° C. | ○ |

As seen above, the hardness of the resist underlayer film can be significantly increased by using the materials with crosslinked structure in the polymer.

(Evaluation of Bending Resistance)

The solution of the resist underlayer film-forming composition prepared in each of Comparative Example 1 and Example 1-13 was applied onto a silicon wafer with a silicon oxide coating film using a spin coater. The applied film was baked on a hot plate at 240° C. for 60 seconds or at 350° C. for 60 seconds, to form a resist underlayer film (film thickness: 200 nm). A solution of silicon hard mask forming composition was applied onto the resist underlayer film and baked at 240° C. for 1 minute, to form a silicon hard mask layer (film thickness: 30 nm). A resist solution was applied thereon and baked at 100° C. for 1 minute, to form a resist layer (film thickness: 150 nm). Exposure was performed at a wavelength of 193 nm using a mask, and post-exposure heating PEB (at 105° C. for 1 minute) was performed followed by development, to obtain a resist pattern. Thereafter, dry etching was performed using a fluorine-based gas and an oxygen-based gas, the resist pattern was transferred to a silicon wafer with a silicon oxide coating film, and each pattern shape was observed with CG-4100 manufactured by Hitachi High-Technologies Corporation.

When a resist pattern is formed on a substrate to be processed through a lithography process and an etching process, irregular pattern bending is likely to occur as a formed pattern width becomes narrower. Specifically, in a resist underlayer film used as a mask material when the target processed substrate is etched, a phenomenon in which a pattern formed from an organic resin layer particularly is bent to the left and right occurs. This phenomenon occurs, such that processing of the substrate cannot be faithfully performed. Therefore, the lesser the bending is likely to occur, the finer the substrate processing can be performed. The results are shown in Table 7. The film having bending resistance higher than that of Comparative Example 1 was evaluated as ∘.

TABLE 7
Evaluation of bending resistance

| | | Bending resis- |
|---|---|---|
| | | tance test |
| Comparative | Film obtained by baking at 240° C. | x |
| Example 1 | | |
| Example 1 | Film obtained by baking at 240° C. | ○ |
| Example 2 | Film obtained by baking at 240° C. | ○ |
| Example 3 | Film obtained by baking at 240° C. | ○ |
| Example 4 | Film obtained by baking at 240° C. | ○ |
| Example 5 | Film obtained by baking at 240° C. | ○ |
| Example 6 | Film obtained by baking at 240° C. | ○ |
| Example 7 | Film obtained by baking at 240° C. | ○ |
| Example 8 | Film obtained by baking at 240° C. | ○ |
| Example 9 | Film obtained by baking at 240° C. | ○ |
| Example 10 | Film obtained by baking at 240° C. | ○ |
| Example 11 | Film obtained by baking at 240° C. | ○ |
| Example 12 | Film obtained by baking at 240° C. | ○ |
| Example 13 | Film obtained by baking at 350° C. | ○ |

As shown in the above results, Examples showed a higher bending resistance than Comparative Examples.

[Evaluation as Crosslinking Agent]

(Measurement of Amount of Sublimate of Resist Underlayer Film)

The measurement of the amount of the sublimate was performed using a sublimate amount measuring apparatus described in WO 2007/111147 A. Each of the resist underlayer film-forming compositions prepared in Comparative Example 2 and Example 14 was applied to a silicon wafer, and the amount of the sublimate when the film thickness reached 200 nm after baking at 240° C. for 60 seconds was measured. The results are shown in Table 7. Note that the value shown in the table is a value of (amount of sublimate of Example 14)/(amount of sublimate of Comparative Example 2).

TABLE 8
Table 7 Amount of sublimate

Amount of
sublimate

| | | |
|---|---|---|
| Comparative | Film obtained by baking at 240° C. | 1.00 |
| Example 2 | | |
| Example 14 | Film obtained by baking at 240° C. | 0.21 |

As seen above, by using a polymer type crosslinking agent, the amount of the sublimate of the resist underlayer film-forming composition can be significantly reduced in comparison to the conventional crosslinking agent, and thus, the concern of contamination of the apparatus is reduced.

(Test for Coating to Stepped Substrate)

For a test for coating to a stepped substrate, with the 200 nm-thick SiO₂ substrate, the coating thickness of the open area (OPEN) with no formed pattern was compared with the coating thickness of the dense area (DENSE) having a trench width of 50 nm and a pitch of 100 nm. The resist underlayer film-forming composition prepared in each of Comparative Example 2 and Example 14 was applied onto the substrate, and the applied film was baked at 240° C. for 60 seconds, thereby forming a resist underlayer film having a thickness of about 200 nm. The flatness of the substrate was observed using a scanning electron microscope (S-4800) manufactured by Hitachi High-Technologies Corporation. The difference in thickness (called as a bias, which was an application step between the trench area and the open area) between the trench area (pattern portion) and the open area (no pattern portion) of the stepped substrate was measured to evaluate the flatness. Here, the flatness means that the difference in thickness (Iso-dense bias) is small between the coating present above the portion, where the pattern is present (trench area (pattern portion)), and the coating present above the portion where the pattern is not present (open area (no pattern portion)). The results are shown in Table 8.

TABLE 9
Table 8 Evaluation of flatness
Flatness

| | | |
|---|---|---|
| Comparative Example 2 | Film obtained by baking at 240° C. | 79 nm |
| Example 14 | Film obtained by baking at 240° C. | 35 nm |

As seen above, the introduction of the alcohol compound into the side chain causes a decrease in the glass transition temperature and a decrease in the viscosity, such that the flatness of the resist underlayer film-forming composition is significantly improved.

### INDUSTRIAL APPLICABILITY

According to the present invention, there is provided a novel resist underlayer film-forming composition that does not use a harmful chemical substance in preparation of the resin, meets such requirements as improvement of solubility in PGME or PGMEA, reduction in amount of sublimate that contaminates a device, improvement of coating flatness for a stepped substrate and the like, as well as a high hardness of the obtained resist underlayer film, while maintaining other desirable properties.

1. A resist underlayer film-forming composition comprising: a solvent and a polymer (X) containing the same or different more than one structural unit and a linking group that links the more than one structural unit, each of the more than one structural unit having a methoxymethyl group and an ROCH₂— group other than the methoxymethyl group, in which R is a monovalent organic group, a hydrogen atom, or a mixture thereof.

2. The resist underlayer film-forming composition according to claim 1, wherein R is a hydrogen atom, a saturated or unsaturated, linear or branched C₂-C₂₀ aliphatic hydrocarbon or C₃-C₂₀ alicyclic hydrocarbon group optionally substituted with a phenyl group, a naphthyl group, or an anthracenyl group and optionally interrupted by an oxygen atom or a carbonyl group, or a mixture thereof.

3. The resist underlayer film-forming composition according to claim 1 or 2, wherein the linking group includes an alkylene group, an ether group, or a carbonyl group.

4. The resist underlayer film-forming composition according to any one of claims 1 to 3, wherein the more than one structural unit has an aromatic ring, a heterocyclic ring, or a fused ring, which optionally have a phenolic hydroxy group and optionally have a substituted or unsubstituted amino group.

5. The resist underlayer film-forming composition according to any one of claims 1 to 4, further comprising a film material (Y) capable of undergoing a crosslinking reaction with the polymer (X).

6. The resist underlayer film-forming composition according to any one of claims 1 to 5, further comprising a crosslinking agent.

7. The resist underlayer film-forming composition according to any one of claims 1 to 6, further comprising an acid and/or an acid generator.

8. The resist underlayer film-forming composition according to any one of claims 1 to 7, further comprising a surfactant.

9. The resist underlayer film-forming composition according to any one of claims 1 to 8, wherein the solvent includes a solvent having a boiling point of 160° C. or higher.

10. A resist underlayer film, which is a baked product of a coating film formed of the composition according to any one of claims 1 to 9.

11. A method of manufacturing a semiconductor device, the method comprising:
forming a resist underlayer film using the composition according to any one of claims 1 to 9 on a semiconductor substrate;
forming a resist film on the formed resist underlayer film;
irradiating the formed resist film with a light or electron beam and developing the resist film to form a resist pattern;
etching and patterning the resist underlayer film through the formed resist pattern; and
processing a semiconductor substrate through the patterned resist underlayer film.

12. A method of manufacturing a semiconductor device, the method comprising:
forming a resist underlayer film using the composition according to any one of claims 1 to 9 on a semiconductor substrate;
forming a hard mask on the formed resist underlayer film;
forming a resist film on the formed hard mask;
irradiating the formed resist film with a light or electron beam and developing the resist film to form a resist pattern;
etching and patterning the hard mask through the formed resist pattern;
etching and patterning the resist underlayer film through the patterned hard mask; and
processing a semiconductor substrate through the patterned resist underlayer film.

13. The method of manufacturing a semiconductor device according to claim 11 or 12, wherein the forming of the resist underlayer film is performed by a nanoimprint method.
